(19) United States
(12) Patent Application Publication
(10) Pub. No.: US 2025/0338398 A1
(43) Pub. Date: Oct. 30, 2025

(54) SYSTEMS, METHODS, AND DEVICES FOR PRODUCING DEFORMABLE ELECTRONIC DEVICES HAVING DEFORMABLE INTERCONNECTS

(71) Applicant: Meta Platforms Technologies, LLC, Menlo Park, CA (US)

(72) Inventor: Omar Awartani, Redmond, WA (US)

(21) Appl. No.: 19/188,801

(22) Filed: Apr. 24, 2025

Related U.S. Application Data
(60) Provisional application No. 63/639,466, filed on Apr. 26, 2024.

(51) Int. Cl. H05K 1/02; H05K 1/03; H05K 1/09; H05K 1/11; H05K 3/00

(52) U.S. Cl. CPC H05K 1/0283; H05K 1/0326; H05K 1/09; H05K 1/113; H05K 3/0047; H05K 3/0055; H05K 2201/09227; H05K 2201/0939; H05K 2201/09563; H05K 2203/095; H05K 2203/128; H05K 2203/143; H05K 2203/166

(57) ABSTRACT

A method for fabricating a deformable electronic device includes obtaining a first substrate having a plurality of circuit components, and a second substrate having a plurality of channels and a plurality of holes. The method also includes assembling the first and second substrates to form a stack, in which holes in the plurality of holes of the second substrate are aligned with circuit components in the plurality of circuit components of the first substrates. The method further includes filling the plurality of channels and the plurality of holes with a liquid metal material, thereby producing a plurality of deformable interconnects in the stack. The plurality of deformable interconnects electrically connects the plurality of circuit components to form one or more circuits.

### CROSS-REFERENCE TO RELATED APPLICATIONS

The present disclosure is related and claims priority under 35 USC § 119(e) to U.S. Provisional Patent Application No. 63/639,466, entitled “SYSTEMS, METHODS, AND DEVICES FOR PRODUCING DEFORMABLE ELECTRONIC DEVICES HAVING DEFORMABLE INTERCONNECTS,” filed on Apr. 26, 2024. Each application is hereby incorporated by reference in its entirety for all purposes.

### TECHNICAL FIELD

This disclosure relates to deformable electronic devices having deformable interconnects, and systems, methods, and devices for producing such deformable electronic devices.

### BACKGROUND

Flexible circuits have become a desirable product due to their ability for application with a wide variety of use capabilities for prolonged durations of time.

Conventional solutions for manufacturing interfacing conductive traces with either electronic devices or other traces are insufficient for use with flexible and stretchable electronics utilizing liquid metal. For instance, conventional solutions do not reliably deliver liquid metal into/through a via and/or throughout a channel in fluid communication with the via to enable multi-layer electrical communication. Moreover, conventional solutions fail product elastically deformable contacts or connections to prefabricated microelectronic devices.

### SUMMARY

The present disclosure addresses the above-identified and/or other shortcomings by providing systems, methods, and devices for producing deformable electronic devices having deformable interconnects that can maintain electrical communications when the deformable electronic devices are subjected to one or more certain conditions (e.g., strain, cycle, temperature, bending, etc.) and/or are physically deformed.

In various embodiments, the present disclosure provides a method for fabricating a deformable electronic device. The method generally includes obtaining a first substrate, obtaining a second substrate, assembling the first and second substrates to form a stack, and producing a plurality of deformable interconnects in the stack. In some embodiments, the first substrate includes a first surface, and a plurality of circuit components disposed at the first surface. The plurality of circuit components includes a first circuit component and a second circuit component separated from the first circuit component. The second substrate includes a second surface, a third surface, a plurality of channels, a plurality of holes and a plurality of ports. The plurality of channels is disposed between the second and third surfaces, and includes a first channel. The plurality of holes is open to the second surface, and includes a first hole in fluid communication with a first end portion of the first channel, and a second hole in fluid communication with a second end portion of the first channel. The plurality of ports is open to the third surface, and includes a first port in fluid communication with the first hole, the second hole and the first channel. To assemble the first and second substrates to form a stack, the first surface of the first substrate and the second surface of the second substrate are adjacent to each other, the first circuit component of the first substrate and the first hole of the second substrate are aligned with each other, and the second circuit component of the first substrate and the second hole of the second substrate are aligned with each other. To produce a plurality of deformable interconnects in the stack, the plurality of channels and the plurality of holes are filled, through the plurality of ports of the second substrate, with a liquid metal material. The plurality of deformable interconnects includes a first deformable interconnect produced by filling, through the first port of the second substrate, the first hole, the second hole and the first channel of the second substrate with the liquid metal material. The first deformable interconnect electrically connects the first and second circuit components.

In some embodiments, the first substrate is deformable. In some embodiments, the first substrate includes a first layer, and the plurality of circuit components is disposed on a first side of the first layer. In some embodiments, the first layer includes a polyimide (Pi) film. In some embodiments, the first layer is laminated on a second layer. In some embodiments, the second layer includes a polyethylene terephthalate (PET) film. In an exemplary embodiment, the first layer is laminated on the second layer using a double-sided dicing tape.

In some embodiments, the first or second circuit component is a contact pad.

In some embodiments, the liquid metal material includes a gallium-based low-melting-point alloy. In an exemplary embodiment, the gallium-based low-melting-point alloy is gallium-indium eutectic (EGaIn). In some embodiments, the first hole, the second hole, or the first channel is filled substantially completely by the liquid metal material. In some embodiments, the liquid metal material filled in the first or second hole forms a via, and the liquid metal material filled in the first channel forms a trace. In some embodiments, the via has a nominal diameter less than 300 μm, and/or the trace has a nominal thickness less than 200 μm.

In some embodiments, the first deformable interconnect is stretchable. In some such embodiments, the first deformable interconnect has a stretchability of at least 25%, at least 50%, at least 75%, or at least 100%. In some embodiments, the first deformable interconnect is free of degradation in conductivity when the first and second substrates are bent around a cylinder that has a radius of between 2 cm and 10 cm for a period of time between 10 seconds and 5 minutes and then released.

In some embodiments, the plurality of circuit components further includes a third circuit component and a fourth circuit component separated from the third circuit component. The plurality of channels further includes a second channel. The plurality of holes includes a third hole in fluid communication with a first end portion of the second channel and a fourth hole in fluid communication with a second end portion of the second channel. The plurality of ports further includes a second port in fluid communication with the third hole, the fourth hole, and the second channel. The assembly of the first and second substrate produces the stack, in which (i) the third circuit component of the first substrate and the third hole of the second substrate are aligned with each other, and (ii) the fourth circuit component of the first substrate and the fourth hole of the second substrate are aligned with each other. The filling of the channels and holes produces the plurality of deformable interconnects in the stack, in which (i) the plurality of deformable interconnects further includes a second deformable interconnect produced by filling, through the second port of the second substrate, the third hole, the fourth hole and the second channel of the second substrate with the liquid metal material, and (ii) the second deformable interconnect electrically connects the third and fourth circuit components.

In some embodiments, the third hole, the fourth hole, or the second channel is filled substantially completely by the liquid metal material. In some embodiments, the second deformable interconnect is stretchable. In some such embodiments, the second deformable interconnect has a stretchability of at least 25%, at least 50%, at least 75%, or at least 100%. In some embodiments, the second deformable interconnect is formed substantially concurrently as the first deformable interconnect. In an exemplary embodiment, the second deformable interconnect has a dimension substantially the same as the first deformable interconnect. In another exemplary embodiment, the second deformable interconnect has a dimension different than the first deformable interconnect.

In some embodiments, the obtaining of the first substrate includes: A.1) obtaining a first initial substrate including a first layer with the plurality of circuit components disposed on a first side of the first layer; A.2) dehydrating, optionally, the first layer; A.3) cleaning, optionally, the first initial substrate; A.4) salinizing, optionally, the first layer to improve a surface functionality of a second side of the first layer, where the second side is opposite to the first side of the first layer; A.5) laminating, optionally, the first initial substrate on a second layer with the second side of the first layer facing the second layer; A.6) applying, optionally, a coating material to at least a portion of the first initial substrate at a first thickness to encapsulate at least the portion of the first initial substrate; and A.7) curing, optionally, the coating material.

In some embodiments, the first layer includes a polyimide (Pi) film. In some embodiments, the dehydrating of the first layer is performed at a first temperature for a first period of time. In an exemplary embodiment, the first temperature is from about 110° C. to about 130° C., and/or the first period of time is from about 10 minutes to about 30 minutes.

In some embodiments, the cleaning of the first initial substrate includes exposing the first initial substrate to a first plasma at a first wattage for a second period of time. In an exemplary embodiment, the first wattage is from about 200 watts (W) to about 300 W, and/or the second period of time is from about 10 minutes to about 30 minutes. In some embodiments, the first plasma includes oxygen (O₂) plasma flown at about 12 standard cubic centimeters per minute (SCCM), tetrafluoromethane (CF₄) flown at about 3 SCCM, or a combination thereof.

In some embodiments, the salinizing of the first layer includes exposing at least the second side of the first layer to a first solution for a third period of time. In an exemplary embodiment, the first solution includes 1% (3-mercaptopropyl) trimethoxysilane (MPTMS), and/or the third period of time is from about 40 minutes to about 60 minutes.

In an exemplary embodiment, the laminating of the first initial substrate on a second layer is performed using a double-sided dicing tape.

In some embodiments, the coating material includes silicone; and/or the first thickness is from about 50 μm to about 150 μm. In an exemplary embodiment, the curing of the coating material is performed at a room temperature.

In some embodiments, the obtaining of the second substrate includes: B.1) obtaining a third layer including a first groove formed on a first side of the third layer, where the first groove includes a first end and a second end; B.2) forming the first and second holes by drilling first and second end portions of the first groove through a second side of the third layer that is opposite to the first side of the third layer; B.3) forming the first channel by placing a fourth layer on the first side of the third layer to seal the first groove formed on the first side of the third layer; and B.4) forming the first port by drilling a hole through the fourth layer.

In some embodiments, the obtaining of the third layer includes: B.1.1) obtaining a mold including a first ridge on a first side of the mold for creating the first groove; B.1.2) applying a release layer on the first side of the mold; B.1.3) applying a coating layer on the release layer; B.1.4) curing, optionally, the coating layer; B.1.5) applying, optionally, a carrier layer on the cured coating layer; and B.1.6) peeling off the coating layer from the mold, thereby producing the third layer with the first groove on the first side of the third layer.

In some embodiments, the mold is an SU-8 master mold. In some embodiments, the coating layer is applied by blade coating silicone on the release layer. In some embodiments, the coating layer has a thickness from about 150 μm to about 250 μm. In an exemplary embodiment, the carrier layer is a single-sided dicing tape.

In some embodiments, the third layer further includes one or more global fiducials, a plurality of first local fiducials adjacent to the first end portion of the first groove, and a plurality of second local fiducials adjacent to the second end portion of the first groove. In some such embodiments, the forming of the first and second holes includes: B.2.1) determining a first bounding box corresponding to the first hole and a second bounding box corresponding to the second hole, where the determining of the first bounding box is based at least in part on the one or more global fiducials and the plurality of first local fiducials, and the determining of the second bounding box is based at least in part on the one or more global fiducials and the plurality of second local fiducials; B.2.2) determining a first center point of the first bounding box and a second center point of the second bounding box; B.2.3) measuring one or more first distances from the first center point of the first bounding box to one or more edges of the first end portion of the first groove, and one or more second distances from the second center point of the second bounding box to one or more edges of the second end portion of the first groove; and B.2.4) quantifying alignment of the first hole with respect to the first groove based on the one or more first distances and alignment of the second hole with respect to the first groove based on the one or more second distances.

In some embodiments, the one or more first distances include a distance in a first direction measured from the first center point of the first bounding box to a first edge of the first end portion of the first groove and a distance in a second direction measured from the first center point of the first bounding box to a second edge of the first end portion of the first groove. Similarly, the one or more second distances include a distance in the first direction measured from the second center point of the second bounding box to a first edge of the second end portion of the first groove and a distance in the second direction measured from the second center point of the first bounding box to a second edge of the second end portion of the first groove.

In some embodiments, the forming of the first and second holes and/or the forming of the first port are performed using a laser.

In some embodiments, the fourth layer overlays on a fifth layer. In some embodiments, the fourth layer is a silicone layer, and/or the fifth layer is a PET film.

In some embodiments, the obtaining of the second substrate further includes: B.5) creating one or more posts on the fifth layer for use as a mechanical jig or fixture.

In some embodiments, the obtaining of the second substrate further includes: B.6) applying, prior to the forming B.3), a first metal material to form a wetting layer that overlays at least a portion of a wall of the first hole, a portion of a wall of the second hole, a portion of an interior surface of the first groove, or any combination thereof. In some embodiments, the first metal material includes copper, gold, nickel, silver, platinum, or a combination thereof.

In some embodiments, the assembling of the first and second substrates includes: C.1) exposing, optionally, the first substrate to a second plasma at a second wattage for a fourth period of time; C.2) salinizing, optionally, the first substrate to improve a surface functionality of the first surface of the first substrate; C.3) exposing, optionally, the second substrate to a third plasma at a third wattage for a fifth period of time; C.4) salinizing, optionally, the second substrate to improve a surface functionality of the second surface of the second substrate; C.5) aligning the first and second substrates with each other; and C.6) bonding the first and second substrates with each other.

In an exemplary embodiment, the second plasma includes O₂ plasma, the second wattage is from about 150 W to about 250 W, and/or the fourth period of time is from about 2 minutes to about 4 minutes.

In some embodiments, the first substrate is salinized in a 1% MPTMS bath for about a sixth period of time. In an exemplary embodiment, the sixth period of time is from about 0.5 hours to about 1.5 hours.

In an exemplary embodiment, the third plasma includes O₂ plasma, the third wattage is from about 25 W to about 75 W, and/or the fifth period of time is from about 0.5 minutes to about 1.5 minutes.

In some embodiments, the second substrate is salinized in a 0.5% to 3% (3-Glycidyloxypropyl)trimethoxysilane (GPTMS) bath for a seventh period of time. In an exemplary embodiment, the seventh period of time is from about 20 minutes to about 60 minutes.

In some embodiments, the first and second substrates are aligned with each other using one or more mechanical jigs or fixtures. In some embodiments, the first and second substrates are bonded in a pressure pot at a second temperature and a first pressure for an eighth period of time. In an exemplary embodiment, the second temperature is from about 60° C. to about 100° C., the first pressure is from about 40 pounds per square inch (psi) to about 80 psi, and/or the eighth period of time is from about 12 hours to about 36 hours.

In some embodiments, the filling of the channels and holes to produce the plurality of deformable interconnects includes: D.1) placing a droplet of the liquid metal material on top of the first port of the second substrate; D.2) degassing the first hole, the second hole, and the first channel of the second substrate to allow the liquid metal material to fill the first hole, the second hole, and the first channel; D.3) cleaning, optionally, excess liquid metal material; and D.4) sealing, optionally, the first port.

In some embodiments, the degassing of the first hole, the second hole, and the first channel of the second substrate includes: D.2.1) placing the assembled first and second substrates with the droplet of the liquid metal material on top of the first port of the second substrate in a chamber at a second pressure that is below about 1 psi for a ninth period of time, thereby removing gas from the first hole, the second hole, and the first channel of the second substrate; and D.2.2) exposing, subsequent to the placing D.2.1), the assembled first and second substrates with the droplet of the liquid metal material on top of the first port of the second substrate to a third pressure that is higher than the second pressure, thereby pushing the liquid metal material to fill the first hole, the second hole, and the first channel of the second substrate.

In an exemplary embodiment, the chamber is a vacuum chamber, and/or the D.2.2) exposing includes opening the vacuum chamber to expose the assembled first and second substrates with the droplet of the liquid metal material on top of the first port of the second substrate to an ambient pressure.

In some embodiments, the first port is sealed with silicone.

In some embodiments, the method of the present disclosure further includes: adding one or more connectors to the stack, where each connector is electrically connected to a circuit component in the plurality of circuit components, a deformable interconnect in the one or more interconnects, or both. In an exemplary embodiment, the adding of one or more connectors is performed by low temperature soldering.

In various embodiments, the present disclosure provides a deformable electronic device including a first substrate and a second substrate bonded with the first substrate. The first substrate includes a first surface, a plurality of circuit components disposed at the first surface and including a first circuit component and a second circuit component separated from the first circuit component. The second substrate includes a plurality of deformable interconnects made of a liquid metal material and including a first deformable interconnect that electrically connects the first and second circuit components.

In some embodiments, the first deformable interconnect is stretchable. In some embodiments, the first deformable interconnect is free of degradation in conductivity when the first and second substrates are bent around a cylinder that has a radius of between 2 cm and 10 cm for a period of time between 10 seconds and 5 minutes and then released.

In some embodiments, the second substrate includes a second surface adjacent to the first surface of the first substrate, and a third surface away from the first surface of the first substrate. In some such embodiments, the first deformable interconnect includes a first trace disposed between the second and third surfaces, a first via electrically connecting the first circuit component with a first end portion of the first trace, and a second via electrically connecting the second circuit component with a second end portion of the first trace.

In some embodiments, the plurality of circuit components further includes a third circuit component and a fourth circuit component separated from the third circuit component, and/or the plurality of deformable interconnects further includes a second deformable interconnect that electrically connects the third and fourth circuit components.

In some embodiments, the liquid metal material includes a gallium-based low-melting-point alloy.

In some embodiments, the deformable electronic device further includes one or more connectors, each electrically connected to a circuit component in the plurality of circuit components, a deformable interconnect in the plurality of deformable interconnects, or both.

The systems, methods and devices of the present disclosure have other features and advantages that will be apparent from, or are set forth in more detail in, the accompanying drawings, which are incorporated herein, and the following Detailed Description, which together serve to explain certain principles of exemplary embodiments of the present disclosure.

### BRIEF DESCRIPTION OF THE DRAWINGS

The implementations disclosed herein are illustrated by way of example, and not by way of limitation, in the figures of the accompanying drawings. Like reference numerals refer to corresponding parts throughout the drawings.

FIG. 1 illustrates an exemplary distributed additive manufacture system topology including a computer system and an additive manufacturing system in accordance with some embodiments of the present disclosure.

FIG. 2 illustrates various modules and/or components of a computer system in accordance with some embodiments of the present disclosure.

FIG. 3A illustrates an exemplary deformable electronic device in accordance with some embodiments of the present disclosure.

FIG. 3B illustrates a cross-sectional view of the deformable electronic device taken along the plane 3B-3B of FIG. 3A in accordance with some embodiments of the present disclosure.

FIG. 3C illustrates a cross-sectional view of the deformable electronic device taken along the plane 3C-3C of FIG. 3A in accordance with some embodiments of the present disclosure.

FIG. 4 illustrates an exemplary implementation of the deformable electronic device in the form of a glove in accordance with some embodiments of the present disclosure.

FIGS. 5A, 5B, 5C, 5D, 5E, 5F and 5G collectively provide a flow chart illustrating exemplary methods for forming deformable electrical devices, in which optional elements of embodiments are indicated by dashed boxes and/or lines, in accordance with some embodiments of the present disclosure.

FIGS. 6A, 6B, 6C, 6D, and 6E collectively provide exemplary processes for forming a substrate in accordance with some embodiments of the present disclosure.

FIG. 7A illustrates an exemplary substrate in accordance with some embodiments of the present disclosure.

FIG. 7B is a cross-sectional view of the exemplary substrate taken along the line 7B-7B of FIG. 7A in accordance with some embodiments of the present disclosure.

FIG. 7C is a cross-sectional view of the exemplary substrate taken along the line 7C-7C of FIG. 7A in accordance with some embodiments of the present disclosure.

FIGS. 8A, 8B, 8C, 8D, 8E, 8F, 8G, 8H, 8I, 8J, 8K and 8L collectively provide exemplary processes for forming the substrate illustrated in FIGS. 7A, 7B and 7C in accordance with some embodiments of the present disclosure.

FIGS. 9A, 9B, 9C and 9D collectively provide exemplary quality control processes for forming the substrate illustrated in FIGS. 7A, 7B and 7C in accordance with some embodiments of the present disclosure.

FIGS. 10A, 10B, 10C, 10D and 10E collectively provide exemplary processes for assembling substrates to produce a stack in accordance with some embodiments of the present disclosure.

FIGS. 11A, 11B, 11C, 11D and 11E collectively illustrate exemplary processes for producing deformable interconnects in accordance with some embodiments of the present disclosure.

FIG. 11F is an image showing a portion of deformable interconnects produced by an exemplary method in accordance with some embodiments of the present disclosure.

FIG. 11G is an image showing another portion of deformable interconnects produced by an exemplary method in accordance with some embodiments of the present disclosure.

FIG. 11H provides an additional or optional process for producing deformable interconnects in accordance with some embodiments of the present disclosure.

FIG. 12A illustrates an exemplary stack made by an exemplary method in accordance with some embodiments of the present disclosure.

FIG. 12B illustrates test samples cut from the exemplary stack of FIG. 12A in accordance with some embodiments of the present disclosure.

FIG. 12C illustrates a shape of test samples in accordance with some embodiments of the present disclosure.

FIG. 12D illustrates test samples cut from the exemplary stack of FIG. 12A in accordance with some embodiments of the present disclosure.

FIG. 12E provides simulation results showing the effects of sample shapes on stress distribution under various strains in accordance with some embodiments of the present disclosure.

FIG. 12F is a cross-sectional view of samples taken along the line 12F-12F in FIG. 12E in accordance with some embodiments of the present disclosure.

FIG. 12G provides testing results showing the effects of liquid metal materials and sample shapes on tensile fatigue of test samples under various strains in accordance with some embodiments of the present disclosure.

### DETAILED DESCRIPTION

### 1. INTRODUCTION

The present disclosure provides systems, methods, and devices for producing deformable electronic devices having deformable interconnects that can maintain electrical communications when the deformable electronic devices are subjected to one or more certain conditions (e.g., strain, cycle, temperature, bending, etc.) and/or are physically deformed. A method for fabricating a deformable electronic device generally includes obtaining a first substrate having a plurality of circuit components, and obtaining a second substrate having a plurality of channels, a plurality of holes and a plurality of ports. The method also includes assembling the first and second substrates to form a stack, in which holes in the plurality of holes of the second substrate are aligned with circuit components in the plurality of circuit components of the first substrate. The method further includes filling, through the plurality of ports of the second substrate, the plurality of channels and the plurality of holes with a liquid metal material, thereby producing a plurality of deformable interconnects in the stack. Once the plurality of deformable interconnects is formed, separated circuit components in the plurality of circuit components of the first substrate are electrically connected by one or more deformable interconnects in the plurality of deformable interconnects. In some embodiments, the deformable interconnects are flexible, bendable, and/or stretchable. In some embodiments, the deformable interconnects are free of degradation in conductivity when the first and second substrates are subject to one or more certain conditions (e.g., strain, cycle, temperature, bending, etc.). As such, electronic devices of the present disclosure can be configured in various forms, shapes and/or sizes, and for use in various fields.

Reference will now be made in detail to embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

Plural instances may be provided for components, operations or structures described herein as a single instance. Finally, boundaries between various components, operations, and data stores are somewhat arbitrary, and particular operations are illustrated in the context of specific illustrative configurations. Other forms of functionality are envisioned and may fall within the scope of the implementation(s). In general, structures and functionality presented as separate components in the example configurations may be implemented as a combined structure or component. Similarly, structures and functionality presented as a single component may be implemented as separate components. These and other variations, modifications, additions, and improvements fall within the scope of the implementation(s).

It will also be understood that, although the terms “first,” “second,” etc. may be used herein to describe various elements, these elements should not be limited by these terms. These terms are only used to distinguish one element from another. For example, a first layer could be termed a second layer, and, similarly, a second layer could be termed a first layer, without departing from the scope of the present disclosure. The first layer and the second layer are both layers, but they are not the same layer.

The terminology used herein is for the purpose of describing particular implementations only and is not intended to be limiting of the claims. As used in the description of the implementations and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specifies the presence of stated features, integers, steps, operations, elements, and/or components, but does not preclude the presence or addition of one or more other features, integers, steps, operations, elements, components, and/or groups thereof.

The foregoing description included example systems, methods, techniques, instruction sequences, and computing machine program products that embody illustrative implementations. For purposes of explanation, numerous specific details are set forth in order to provide an understanding of various implementations of the inventive subject matter. It will be evident, however, to those skilled in the art that implementations of the inventive subject matter may be practiced without these specific details. In general, well-known instruction instances, protocols, structures and techniques have not been shown in detail.

The foregoing description, for purpose of explanation, has been described with reference to specific implementations. However, the illustrative discussions below are not intended to be exhaustive or to limit the implementations to the precise forms disclosed. Many modifications and variations are possible in view of the above teachings. The implementations are chosen and described in order to best explain the principles and their practical applications, to thereby enable others skilled in the art to best utilize the implementations and various implementations with various modifications as are suited to the particular use contemplated.

In the interest of clarity, not all of the routine features of the implementations described herein are shown and described. It will be appreciated that, in the development of any such actual implementation, numerous implementation-specific decisions are made in order to achieve the designer's specific goals, such as compliance with use case constraints, and that these specific goals will vary from one implementation to another and from one designer to another. Moreover, it will be appreciated that such a design effort might be complex and time-consuming, but nevertheless be a routine undertaking of engineering for those of ordering skill in the art having the benefit of the present disclosure.

For convenience in explanation and accurate definition in the appended claims, the terms “upper,” “lower,” “up,” “down,” “upwards,” “downwards,” “laterally,” “longitudinally,” “inner,” “outer,” “inside,” “outside,” “inwardly,” “outwardly,” “interior,” “exterior,” “front,” “rear,” “back,” “forwards,” and “backwards” are used to describe features of the exemplary embodiments with reference to the positions of such features as displayed in the figures.

Furthermore, when a reference number is given an “i^{th}” denotation, the reference number refers to a generic component, set, or embodiment. For instance, a circuit component “circuit component i” refers to the i^{th} circuit component in a plurality of circuit components (e.g., a circuit component 330-i in a plurality of circuit components 330).

As used herein, the term “about” or “approximately” can mean within an acceptable error range for the particular value as determined by one of ordinary skill in the art, which can depend in part on how the value is measured or determined, e.g., the limitations of the measurement system. For example, “about” can mean within 1 or more than 1 standard deviation, per the practice in the art. “About” can mean a range of ±20%, ±10%, ±5%, or ±1% of a given value. Where particular values are described in the application and claims, unless otherwise stated, the term “about” means within an acceptable error range for the particular value. The term “about” can have the meaning as commonly understood by one of ordinary skill in the art. The term “about” can refer to ±10%. The term “about” can refer to ±5%.

### 2. EXEMPLARY DISTRIBUTED ADDITIVE MANUFACTURE SYSTEM

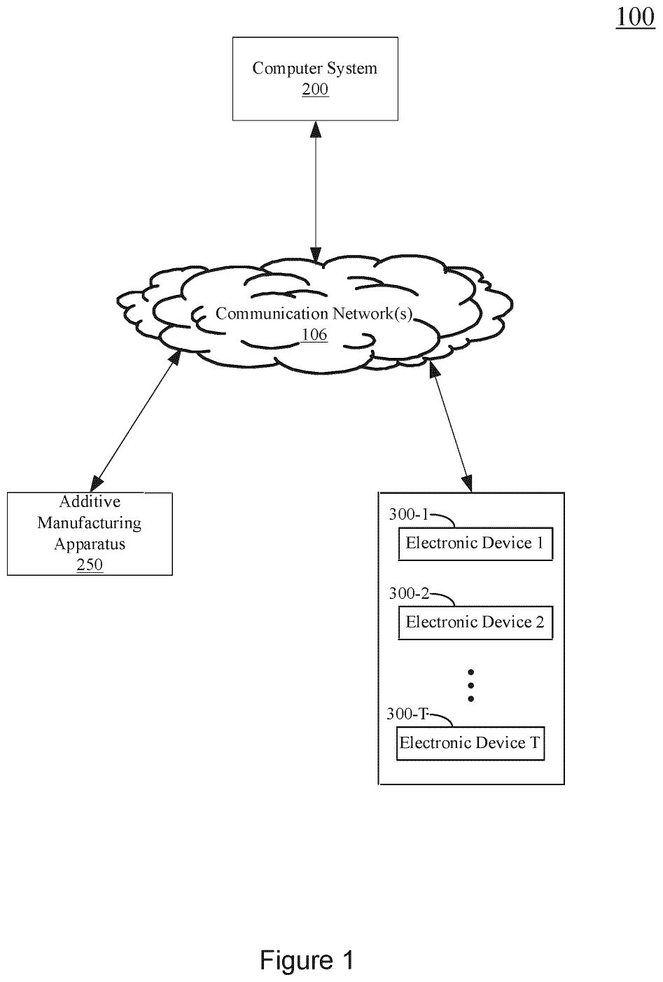

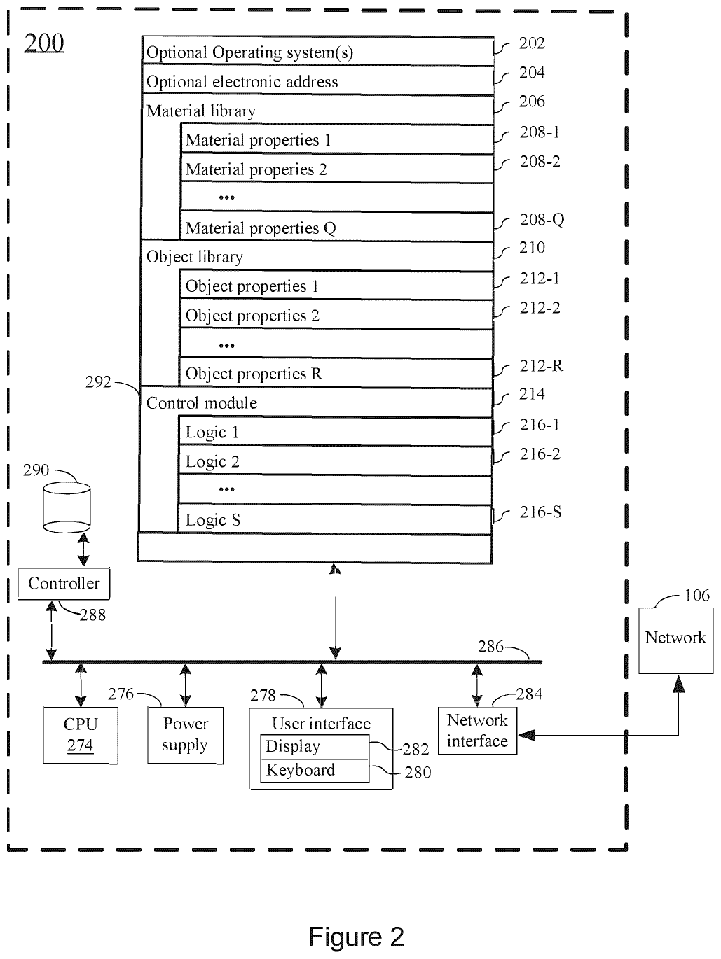

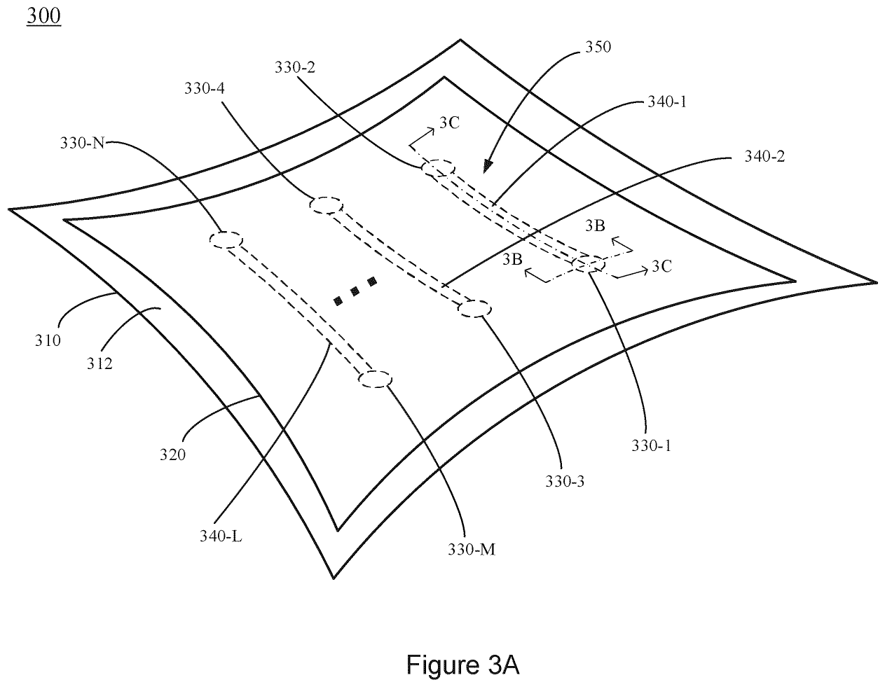

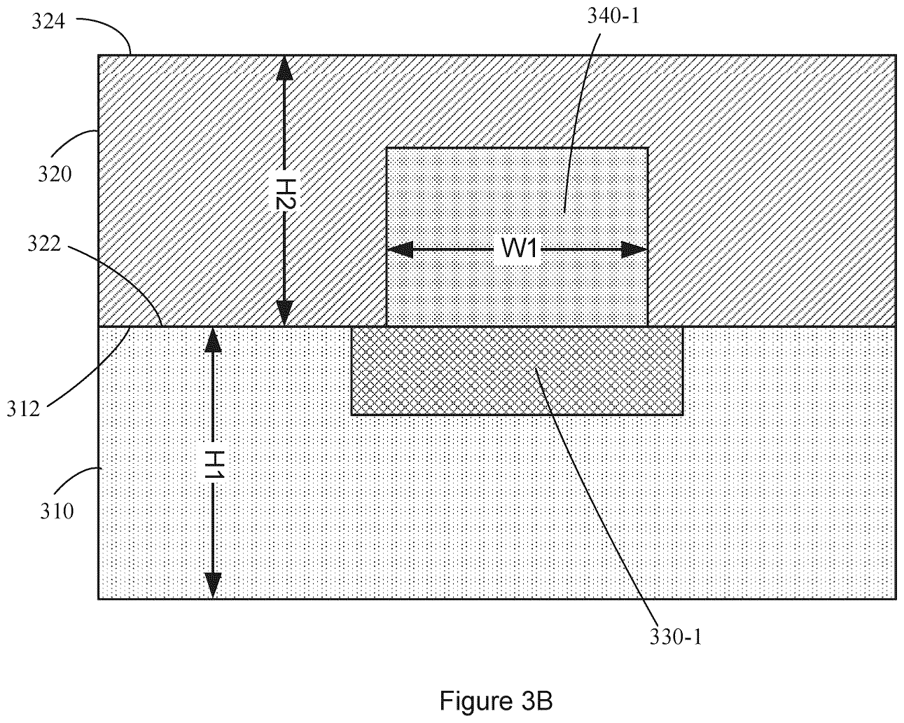

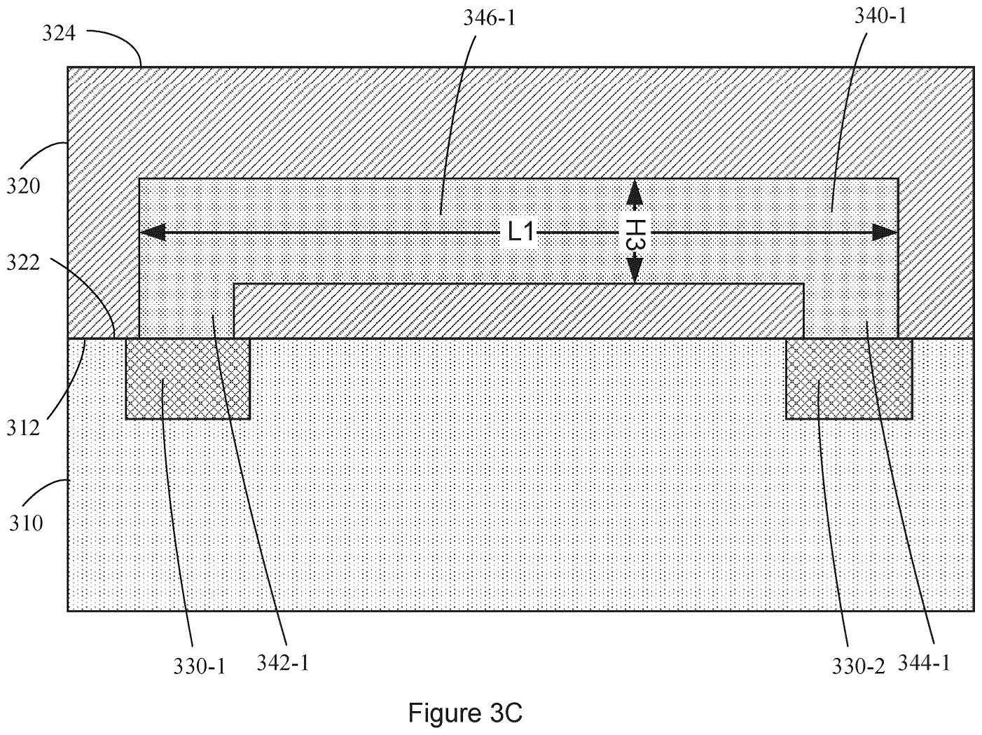

Referring to FIG. 1, a system for producing an interconnect of a circuit is provided. More specifically, FIG. 1 depicts a block diagram of a distributed additive manufacture system (e.g., distributed additive manufacture system 100) according to some embodiments of the present disclosure. In some embodiments, the system 100 facilitates the manufacture, at least in part, of an electronic device (e.g., electronic device 300-1 of FIG. 1, electronic device 300 of FIG. 3A, etc.) at a computer system (e.g., computer system 200 of FIG. 1, computer system 200 of FIG. 2, etc.).

Of course, other topologies of the system 100 are possible. For instance, in some embodiments, any of the illustrated devices and systems can in fact constitute several computer systems that are linked together in a network or be a virtual machine and/or container in a cloud-computing environment. Moreover, rather than relying on a physical communication network 106, the illustrated devices and systems may wirelessly transmit information between each other. As such, the exemplary topology shown in FIG. 1 merely serves to describe the features of an embodiment of the present disclosure in a manner that will be readily understood to one skilled in the art.

Referring to FIG. 1, in some embodiments, a distributed additive manufacture system 100 includes a computer system 200 that facilitates manufacture of an electronic device 300 in response to one or more instructions for manufacturing the electronic device 300. In some embodiments, the computer system 200 and an additive manufacture apparatus (e.g., additive manufacture apparatus 250 of FIG. 1, etc.) are in a single monolithic casing without a communication network 106. In other embodiments, the computer system 200 and the additive manufacture apparatus 250 are separated by some distance and are in electrical communication with each other over the communication network as illustrated in FIG. 1.

In some embodiments, the communication networks 106 optionally include the Internet, one or more local area networks (LANs), one or more wide area networks (WANs), other types of networks, or a combination of such networks.

Examples of communication networks 106 include the World Wide Web (WWW), an intranet and/or a wireless network, such as a cellular telephone network, a wireless local area network (LAN) and/or a metropolitan area network (MAN), and other devices by wireless communication. The wireless communication optionally uses any of a plurality of communications standards, protocols and technologies, including Global System for Mobile Communications (GSM), Enhanced Data GSM Environment (EDGE), high-speed downlink packet access (HSDPA), high-speed uplink packet access (HSUPA), Evolution, Data-Only (EV-DO), HSPA, HSPA+, Dual-Cell HSPA (DC-HSPDA), long term evolution (LTE), near field communication (NFC), wideband code division multiple access (W-CDMA), code division multiple access (CDMA), time division multiple access (TDMA), Bluetooth, Wireless Fidelity (Wi-Fi) (e.g., IEEE 802.11a, IEEE 802.11ac, IEEE 802.11ax, IEEE 802.11b, IEEE 802.11g and/or IEEE 802.11n), voice over Internet Protocol (VoIP), Wi-MAX, a protocol for e-mail (e.g., Internet message access protocol (IMAP) and/or post office protocol (POP)), instant messaging (e.g., extensible messaging and presence protocol (XMPP), Session Initiation Protocol for Instant Messaging and Presence Leveraging Extensions (SIMPLE), Instant Messaging and Presence Service (IMPS)), and/or Short Message Service (SMS), or any other suitable communication protocol, including communication protocols not yet developed as of the filing date of this document.

Now that a distributed additive manufacture system 100 has generally been described, an exemplary computer system 200 for controlling an additive manufacture apparatus 250 by providing one or more instructions, such as one or more non-transitory logics (e.g., logics of FIG. 2, etc.), for manufacture of an electronic device 300 will be described with reference to FIG. 2.

In various embodiments, the computer system 200 includes one or more processing units (CPUs) 274, a network or other communications interface 284, and memory 292.

The memory 292 includes high-speed random access memory, such as DRAM, SRAM, DDRRAM, or other random access solid state memory devices, and optionally also includes non-volatile memory, such as one or more magnetic disk storage devices, optical disk storage devices, flash memory devices, or other non-volatile solid state storage devices. The memory 292 may optionally include one or more storage devices remotely located from the CPU(s) 274. The memory 292, or alternatively the non-volatile memory device(s) within memory 292, includes a non-transitory computer-readable storage medium. Access to memory 292 by other components of the computer system 200, such as the CPU(s) 274, is, optionally, controlled by a controller. In some embodiments, the memory 292 can include mass storage that is remotely located with respect to the CPU(s) 274. In other words, some data stored in the memory 292 may in fact be hosted on devices that are external to the computer system 200, but that can be electronically accessed by the computer system 200 over an Internet, intranet, or other form of communication network 106 or electronic cable using communication interface 284.

In some embodiments, the memory 292 of the computer system 200 for controlling an additive manufacture apparatus 250 to manufacture an electronic device 300 stores:
an optional operating system 202 (e.g., ANDROID, iOS, DARWIN, RTXC, LINUX, UNIX, OSX, WINDOWS, or an embedded operating system such as VxWorks) that includes procedures for handling various basic system services;
an electronic address 204 associated with the computer system 200 that identifies the computer system 200;
a material library 206 that stores a plurality of material properties 208 associated with a corresponding material that is utilized by the additive manufacture apparatus 250;
an object library 210 that stores a plurality of object properties 212 for manufacturing a corresponding object, such as a circuit (e.g., a layer of the circuit) and/or a circuit component at the additive manufacture apparatus 250; and
a control module 214 that stores one or more non-transitory logics 216 that instruct a control of a manufacture of the corresponding object at the additive manufacture apparatus 250.

In some embodiments, an electronic address 204 is associated with the computer system 200. The electronic address 204 is utilized to identify the computer system 200 at least uniquely from other devices and components of the distributed additive manufacture system 100 (e.g., uniquely identify computer system 200 from additive manufacture apparatus 250 of FIG. 1).

In some embodiments, a material library 206 is configured to store at least a plurality of material properties 208 that is associated with a corresponding material (e.g., first plurality of material properties 208-1 is associated with a corresponding first material, second plurality of material properties 208-2 is associated with a corresponding second material, etc.). Each corresponding material associated with a respective plurality of material properties 208 is found at or produced by the additive manufacture apparatus 250. For instance, in some embodiments, the corresponding material associated with the plurality of material properties 208 is the resin accommodated by the resin enclosure of the additive manufacture apparatus 250. In some embodiments, the corresponding material associated with the plurality of material properties 208 is a media of the additive manufacture apparatus 250. Moreover, in some embodiments, the corresponding material associated with the plurality of material properties 208 is a material of the resin enclosure or a different component of the 3D printer system (e.g., outer glass container, temperature control system, etc.). For instance, in some such embodiments, the corresponding material associated with the plurality of material properties 208 is a coolant of a thermal control system associated with an additive manufacture apparatus 250.

In some embodiments, a respective material property 208 in the plurality of material properties 208 is associated with a physical property of the corresponding material. As a non-limiting example, in some such embodiments, the physical property of the corresponding material associated with the respective material property is a first model of a phase diagram of the corresponding material that includes an evaluation of a boiling point of the corresponding material, an evaluation of a melting point of the corresponding material, an evaluation of a critical point of the corresponding material, an evaluation of a supercritical fluidic phase region of the corresponding material, an evaluation of a glass transition temperature, or a combination thereof. As another non-limiting example, in some embodiments, the physical property of the corresponding material associated with the respective material property 208 is a second model of a viscosity of the corresponding material, a third model of an index of refraction of the corresponding material, a fourth model of an evaluation of a depth of curing of the corresponding material volumetric shrinkage of the corresponding material, a fifth model of a flexural strength of the corresponding material, or a combination thereof. In some embodiments, the physical property of the corresponding material is a thermal property, such as a sixth model of a thermal conductivity of the corresponding material, a seventh model of a thermal diffusivity of the corresponding material, an eight model of a specific heat capacity, a ninth model of a thermal effusivity of the corresponding model, a tenth model of a material density of the corresponding material, an eleventh model of a conductivity of the corresponding material, or a combination thereof.

In some embodiments, from the plurality of material properties 208 associated with the physical property of the corresponding material, a manufacture of an object, such as an interconnect of the present disclosure, is dynamically modifiable based on one or more material properties in the plurality of material properties 208, such as by changing a mass of the material deposited by an additive manufacture apparatus 250 when manufacturing the object.

For instance, in some embodiments, the respective material property in the plurality of material properties 208 is associated with the supply of the corresponding material at an additive manufacture apparatus 250, such as the amount (e.g., a weight, a volume, etc.) of a reservoir of the corresponding material at the additive manufacture apparatus 250. One skilled in the art of the present disclosure will appreciate that a wide domain of material properties 208 are applicable to the systems, methods, and devices of the present disclosure.

In some embodiments, the plurality of material properties 208 stored by the material library 206 includes between 5 material properties and 10,000 material properties, between 5 material properties and 5,000 material properties, between 5 material properties and 1,000 material properties, between 5 material properties and 700 material properties, between 5 material properties and 500 material properties, between 5 material properties and 400 material properties, between 5 material properties and 100 material properties, between 50 material properties and 10,000 material properties, between 50 material properties and 5,000 material properties, between 50 material properties and 1,000 material properties, between 50 material properties and 700 material properties, between 50 material properties and 500 material properties, between 50 material properties and 400 material properties, between 50 material properties and 100 material properties, between 350 material properties and 10,000 material properties, between 350 material properties and 5,000 material properties, between 350 material properties and 1,000 material properties, between 350 material properties and 700 material properties, between 350 material properties and 500 material properties, between 350 material properties and 400 material properties, between 1,250 material properties and 10,000 material properties, between 1,250 material properties and 5,000 material properties, or between 6,250 material properties and 10,000 material properties. In some embodiments, the plurality of material properties 208 stored by the material library 206 includes at least 5 material properties, at least 20 material properties, at least 50 material properties, at least 200 material properties, at least 500 material properties, at least 1,000 material properties, at least 3,000 material properties, at least 8,000 material properties, or at least 10,000 material properties. In some embodiments, the plurality of materials properties 208 stored by the material library 206 includes at most 5 material properties, at most 20 material properties, at most 50 material properties, at most 200 material properties, at most 500 material properties, at most 1,000 material properties, at most 3,000 material properties, at most 8,000 material properties, or at most 10,000 material properties.

Additional details and information regarding certain material properties is found at Standard Handbook for Mechanical Engineers, twelfth edition, 2018, McGraw-Hill, Inc., print, which is hereby incorporated by reference in its entirety for all purposes.

In some embodiments, the object library 210 is configured to store at least a plurality of object properties 212 that is associated with a corresponding object (e.g., first plurality of object properties 212-1 is associated with a corresponding first object, second plurality of material properties 212-2 is associated with a corresponding second object, etc.). In some embodiments, a respective object property 212 in the plurality of object properties 212 includes a set of non-transitory instructions for manufacturing the corresponding object at an additive manufacture apparatus 250 by way of one or more additive manufacturing techniques. For instance, in some embodiments, the first object property in a first plurality of object properties 212-1 includes a first set of non-transitory instructions for manufacturing a corresponding second object at a direct writing additive manufacture apparatus 250, the second object property in the first plurality of object properties 212-1 includes a second set of non-transitory instructions for manufacturing the corresponding second object at a screen printing additive manufacture apparatus 250, and the like.

In some embodiments, the plurality of object properties 212 stored by the object library 210 includes between 5 object properties and 10,000 object properties, between 5 object properties and 5,000 object properties, between 5 object properties and 1,000 object properties, between 5 object properties and 700 object properties, between 5 object properties and 500 object properties, between 5 object properties and 400 object properties, between 5 object properties and 100 object properties, between 50 object properties and 10,000 object properties, between 50 object properties and 5,000 object properties, between 50 object properties and 1,000 object properties, between 50 object properties and 700 object properties, between 50 object properties and 500 object properties, between 50 object properties and 400 object properties, between 50 object properties and 100 object properties, between 350 object properties and 10,000 object properties, between 350 object properties and 5,000 object properties, between 350 object properties and 1,000 object properties, between 350 object properties and 700 object properties, between 350 object properties and 500 object properties, between 350 object properties and 400 object properties, between 1,250 object properties and 10,000 object properties, between 1,250 object properties and 5,000 object properties, or between 6,250 object properties and 10,000 object properties. In some embodiments, the plurality of material properties 208 stored by the material library 206 includes at least 5 object properties, at least 20 object properties, at least 50 object properties, at least 200 object properties, at least 500 object properties, at least 1,000 object properties, at least 3,000 object properties, at least 8,000 object properties, or at least 10,000 object properties. In some embodiments, the plurality of material properties 208 stored by the material library 206 includes at most 5 object properties, at most 20 object properties, at most 50 object properties, at most 200 object properties, at most 500 object properties, at most 1,000 object properties, at most 3,000 object properties, at most 8,000 object properties, or at most 10,000 object properties.

In some embodiments, the control module 214 stores one or more non-transitory logics 216 (e.g., first non-transitory logic 216-1, second non-transitory logic 216-2, . . . , non-transitory logic S 216-S of FIG. 2). In some embodiments, each of the non-transitory logics 216 is configured to control an aspect of an additive manufacture apparatus 250 by one or more instructions for the additive manufacture apparatus 250. For instance, in some embodiments, a respective non-transitory logic 216 includes one or more instructions to modify a flow rate of a material disposed (e.g., extruded) by the additive manufacture apparatus 250, and the like. As another non-limiting example, in some embodiments, a respective non-transitory logic 216 is configured to switch the power state of the 3D printer system, such as the respective powered state (e.g., switch to/from a powered state, an unpowered state, etc.) of a power supply of the additive manufacture apparatus 250, the respective powered state of a temperature control system of the additive manufacture apparatus 250, or a combination thereof.

In some embodiments, the object library 210 is subsumed by, or in communication with, the control module 214. For instance, in some embodiments, the non-transitory logic 216 of the control module 214 includes a geometric slicer for translating slicing of a corresponding object for manufacture at an additive manufacture apparatus 250.

Each of the above identified modules and applications correspond to a set of executable instructions for performing one or more functions described above and the methods described in the present disclosure. These modules (e.g., sets of instructions) need not be implemented as separate software programs, procedures or modules, and thus various subsets of these modules are, optionally, combined or otherwise re-arranged in various embodiments of the present disclosure. In some embodiments, the memory 292 optionally stores a subset of the modules and data structures identified above. Furthermore, in some embodiments, the memory 292 stores additional modules and data structures not described above.

It should be appreciated that the computer system 200 of FIG. 2 is only one example of a computer system 200, and that the computer system 200 optionally has more or fewer components than shown, optionally combines two or more components, or optionally has a different configuration or arrangement of the components. The various components shown in FIG. 2 are implemented in hardware, software, firmware, or a combination thereof, including one or more signal processing and/or application specific integrated circuits.

### 3. EXEMPLARY DEFORMABLE ELECTRONIC DEVICES

Referring to FIGS. 3A-3C, there is depicted a deformable electronic device, generally designated 300, in accordance with some embodiments of the present disclosure. The deformable electronic device 300 generally includes a first substrate 310, a second substrate 320, a plurality of circuit components (e.g., circuit components 330-1, 330-2, . . . 330-N) and a plurality of deformable interconnects (e.g., deformable interconnects 340-1, 340-2, . . . , 340-L). Collectively, the plurality of circuit components and the plurality of deformable interconnects form a circuit 350 of the electronic device 300. In some embodiments, the deformable electronic device 300 includes one or more additional, optional and/or alternative components (not shown for clarity purposes). For instance, in an exemplary embodiment, the deformable electronic device 300 includes one or more connectors, each electrically connected to a circuit component in the plurality of circuit components, a deformable interconnect in the plurality of deformable interconnects, or both.

### 3.1. Substrates

The first substrate 310 and the second substrate 320 are bonded with each other. For instance, in some embodiments, the first substrate 310 has a first surface 312 and the second substrate 320 has a second surface 322 adjacent to the first surface 312 of the first substrate 310 as illustrated in FIGS. 3B and 3C. The first surface 312 of the first substrate 310 and the second surface 322 of the second substrate 320 may be treated and then bonded together, for example, by chemical reactions. In some embodiments, the second substrate 320 has a third surface 324 facing away from the first surface 312 of the first substrate 310. In some embodiments, the third surface 324 is substantially parallel to the second surface 322. In some embodiments, the third surface 324 has a size and/or shape similar to the second surface 322.

In some embodiments, the first substrate 310, the second substrate 320, or each of the first substrate 310 and the second substrate 320 is a deformable substrate. As used herein, the term “deformable substrate” refers to a substrate or a portion of it (e.g., a layer) capable of altering its shape subject to pressure or stress. For instance, in some embodiments, a deformable substrate (e.g., the first substrate 310 or the second substrate 320) or at least a portion of it is flexible, bendable, stretchable, inflatable, or the like. In some embodiments, a deformable substrate (e.g., the first substrate 310 or the second substrate 320) or at least a portion of it (e.g., a layer) is made with a material having a Young's Modulus lower than about 0.5 Giga-Pascals (GPa), lower than about 0.4 GPa, lower than about 0.3 GPa, or lower than about 0.2 GPa. Such a material allows a deformable substrate (e.g., the first substrate 310 or the second substrate 320) or a portion of it to deform (e.g., bend, stretch or the like) under pressure or strain. In some embodiments, a deformable substrate (e.g., the first substrate 310 or the second substrate 320) or at least a portion of it is made of a material having Young's Modulus lower than about 0.1 GPa to provide enhanced flexibility and trackability. Examples of materials with low Young's Modulus include, but are not limited to, elastomeric materials, viscoelastic polymeric materials, synthetic resins having low sliding performance, high corrosion resistance and high strength, such as silicone, medical grade polyurethane, polyethylene terephthalate (PET), polyimide (PI), polyphenylene sulfide (PPS) or fluorine-containing resin.

In some embodiments, a deformable substrate (e.g., the first substrate 310 or the second substrate 320) includes a layer or a portion made of a relatively rigid material. For instance, in some embodiments, a deformable substrate (e.g., the first substrate 310 or the second substrate 320) includes a layer or a portion made of a material having Young's Modulus higher than about 0.5 GPa, higher than about 1.0 GPa, higher than about 2.0 GPa, higher than about 3.0 GPa, higher than 4.0 GPa, or higher than about 5.0 GPa. Examples of materials with relatively higher Young's Modulus include, but are not limited to, polyethylene, PEEK, polyester, aramid, composite, glass epoxy, and polyethylene naphthalate.

In some embodiments, a deformable substrate (e.g., the first substrate 310 or the second substrate 320) includes a supporting material upon or within an object is fabricated or attached to or on. In some embodiments, a deformable substrate (e.g., the first substrate 310 or the second substrate 320) or a portion of the deformable substrate is processed (e.g., patterned) during manufacture of the object. In some embodiments, a deformable substrate (e.g., the first substrate 310 or the second substrate 320) remains substantially unchanged when the object is formed upon or within the deformable substrate. In some embodiments, a deformable substrate (e.g., the first substrate 310 or the second substrate 320) includes a planar surface, a substantially planar surface, a curved surface, a round surface (e.g., an edge having a radius of curvature greater than zero), one or more sharp edges, or any combination thereof.

In some embodiments, a deformable substrate (e.g., the first substrate 310 or the second substrate 320) is a monolayer substrate consisting of a single layer. In some embodiments, the deformable substrate includes two, three, four, five, or more than five layers. In some embodiments, a deformable substrate (e.g., the first substrate 310 or the second substrate 320) includes one or more layers that are removable, e.g., functioning as a sacrificial layer that can be at least partially removed when desired or needed.

A deformable substrate (e.g., the first substrate 310 or the second substrate 320) can be of any suitable shapes and sizes. For instance, in some embodiments, a deformable substrate has a thickness, e.g., the first substrate 310 has a thickness “H1,” and the second substrate 320 has a thickness “H2” as illustrated in FIG. 3A. The first substrate 310 and the second substrate 320 can have a same thickness, or different thicknesses. In some embodiments, the thickness of a deformable substrate is less than 5 mm, less than 4 mm, less than 3 mm, less than 2 mm, or less than 1 mm. In some embodiments, the thickness of at least a portion of a deformable substrate is less than 1000 μm, less than 900 μm, less than 800 μm, less than 700 μm, less than 600 μm, less than 500 μm, less than 400 μm, less than 300 μm, or less than 200 μm. In some embodiments, the thickness of at least a portion of a deformable substrate is more than 100 μm, more than 125 μm, more than 150 μm, more than 175 μm, more than 200 μm, more than 225 μm, more than 250 μm, more than 275 μm, more than 300 μm, more than 325 μm, more than 350 μm, more than 375 μm, more than 400 μm, more than 425 μm, more than 450 μm, more than 475 μm, or more than 500 μm.

A surface of a deformable substrate can be of any suitable shapes and sizes. For instance, a surface of a deformable substrate (e.g., the first surface 312 or the second surface 322) can be a planar surface, a substantially planar surface, a curved surface, a round surface, or any combination thereof. A surface of a deformable substrate (e.g., the first surface 312 or the second surface 322) can have an area within a range from about 1 square millimeters (mm2) to about 100 square meters (m2) or greater.

The first surface 312 of the first substrate 310 and the second surface 322 of the second substrate 320 can be the same as each other (e.g., the second surface 322 completely overlays the first surface 312 and vice versa) or different from each other (e.g., at least a portion of the first surface 312 is not covered by the second surface 322, or at least a portion of the second surface 322 is not covered by the first surface 312). In some embodiments, the first surface 312 or the second surface 322 has an area of from about 1 square centimeters (cm2) to about 1 square decimeters (dm2), from about 1 dm2 to about 1 m2, or from about 1 m2 to 100 m2. In some embodiments, the first surface 312 or the second surface 322 has an area of not less than about 1 cm2, not less than about 2 cm2, not less than about 3 cm2, not less than about 4 cm2, not less than about 5 cm2, not less than about 6 cm2, not less than about 7 cm2, not less than about 8 cm2, not less than about 9 cm2, or not less than about 10 cm2. In some embodiments, the first surface 312 or the second surface 322 has an area of not more than about 0.1 m2, not more than about 0.2 m2, not more than about 0.3 m2, not more than about 0.4 m2, not more than about 0.5 m2, not more than about 0.6 m2, not more than about 0.7 m2, not more than about 0.8 m2, not more than about 0.9 m2, or not more than about 1 m2.

### 3.2. Circuit Components

The plurality of circuit components (e.g., circuit components 330-1, 330-2, . . . , 330-M) is disposed at the first surface 312 of the first substrate 310. Among the plurality of circuit components, at least some circuit components are separated from each other (e.g., there is a gap or span between two circuit components that requires carrying electrical communication therethrough between the two separated circuit components). As a non-limiting example, FIG. 3A illustrates that the circuit component 330-1, the circuit component 330-2, the circuit component 330-3, and the circuit component 330-4 are separated from each other.

The deformable electronic device 300 can include a variety of numbers of circuit components 330. For instance, in some embodiments, the electronic device 300 includes between 2 and 10 million circuit components, between 2 and 1 million, between 2 and 100,000, between 2 and 10,000, between 2 and 1,000, or between 2 and 100 circuit components. In some embodiments, the electronic device 300 includes between 5 and 10 million, between 5 and 1 million, between 5 and 100,000, between 5 and 10,000, between 5 and 1,000, or between 5 and 100 circuit components. In some embodiments, the electronic device 300 includes at least 10, at least 50, at least 100, at least 500, at least 1,000, at least 5,000, at least 10,000, at least 25,000, at least 40,000, at least 100,000, at least 250,000, at least 500,000, at least 1 million, at least 5 million, or at least 10 million circuit components. In some embodiments, the electronic device 300 includes at most 100, at most 500, at most 1,000, at most 5,000, at most 10,000, at most 25,000, at most 40,000, at most 100,000, at most 250,000, at most 500,000, at most 1 million, at most 5 million, or at most 10 million circuit components.

In some embodiments, circuit components in at least a subset of the plurality of circuit components are components of one or more flexible printed circuits (FPC). By utilizing one or more FPCs, the deformable electronic device 300 of the present disclosure is capable of incorporating one or more conventional FPC components that benefit from the additional stretchability (e.g., elastic elongation) gained through interfacing with the deformable substrate(s) and deformable interconnects of the present disclosure.

In some embodiments, a circuit component (e.g., the circuit component 330-1) includes a terminal, an energy source (e.g., power supply), an interconnect (e.g., a line interconnect, such as a wire), a load (e.g., a device, a sensor, etc.), a controller (e.g., switch), or a combination thereof. In some embodiments, a circuit component (e.g., the circuit component 330-1) includes a terminal, a resistor, a transistor, a capacitor, an inductor, a transformer, a diode, a sensor or a combination thereof. In some embodiments, a circuit component (e.g., the circuit component 330-1) is the same type of component (e.g., a load, a conductor, etc.) as another circuit component (e.g., the circuit component 330-2).

In some embodiments, some circuit components (e.g., the circuit component 330-1 and the circuit component 330-2) form part of an active-matrix array. For instance, in some embodiments, one of the first circuit component 330-1 and the second circuit component 330-2 is a transistor, an electrode, or a capacitor disposed on the first substrate 310, and the other of the circuit component 330-1 and the circuit component 330-2 is a component other than the transistor, the electrode, or the capacitor. In some embodiments, some circuit components (e.g., the circuit component 330-1 and the circuit component 330-2) are part of a transistor switch configured to control an electronical communication through the circuit 350 using a logic function, such as an OR logic function based on either a cutoff or saturation of the electronical communication. In some embodiments, two or more transistor switches are arranged (e.g., in series and/or parallel) in order to implement a logic function.

### 3.3. Deformable Interconnects

The plurality of deformable interconnects (e.g., deformable interconnects 340-1, 340-2, . . . , 340-L) is disposed at the second substrate 320. As used herein, the term “deformable interconnect” refers to an interconnect or a portion of it capable of altering its shape subject to force, pressure, or stress. For instance, in some embodiments, a deformable interconnect (e.g., the interconnect 340-1, 340-2, or 340-L) or at least a portion of it is flexible, bendable, stretchable, or the like.

The plurality of deformable interconnects (e.g., deformable interconnects 340-1, 340-2, . . . , 340-L) electrically connects some circuit components to other circuit components. For instance, as a non-limiting example, FIG. 3A illustrates the deformable interconnect 340-1 electrically connecting the circuit component 330-1 and the circuit component 330-2, the deformable interconnect 340-2 electrically connecting the circuit component 330-3 and the circuit component 330-4, and the deformable interconnect 340-L electrically connecting the circuit component 330-M and the circuit component 330-N. However, the present disclosure is not limited thereto. The electronic device 300 can have other configurations. For instance, a circuit component (e.g., the circuit component 330-3) can be electrically connected to multiple circuit components (e.g., two or more of the circuit components 330-1, 330-2 and 330-4) by multiple deformable interconnects in the plurality of deformable interconnects. Also, two circuit components (e.g., the circuit components 330-1 and 330-2) can be electrically connected to each other by two, three, four or more than four deformable interconnects in the plurality of deformable interconnects. In addition, deformable interconnects in the plurality of deformable interconnects can be but do not have to be identical in shape, size, orientation, and/or other configurations.

The electronic device 300 can include any suitable number of deformable interconnects. For instance, in some embodiments, the electronic device 300 includes between 2 and 10 million deformable interconnects, between 2 and 1 million, between 2 and 100,000, between 2 and 10,000, between 2 and 1,000, or between 2 and 100 deformable interconnects. In some embodiments, the electronic device 300 includes between 5 and 10 million, between 5 and 1 million, between 5 and 100,000, between 5 and 10,000, between 5 and 1,000, or between 5 and 100 deformable interconnects. In some embodiments, the electronic device 300 includes at least 10, at least 50, at least 100, at least 500, at least 1,000, at least 5,000, at least 10,000, at least 25,000, at least 40,000, at least 100,000, at least 250,000, at least 500,000, at least 1 million, at least 5 million, or at least 10 million deformable interconnects. In some embodiments, the electronic device 300 includes at most 100, at most 500, at most 1,000, at most 5,000, at most 10,000, at most 25,000, at most 40,000, at most 100,000, at most 250,000, at most 500,000, at most 1 million, at most 5 million, or at most 10 million deformable interconnects.

In some embodiments, a deformable interconnect (e.g., the interconnect 340-1, 340-2, or 340-L) is made of a liquid metal material. As used herein, the term “liquid metal material” generally refers to a material including a liquid metal (LM) that makes the composition electrically conductive once it is printed, dried, or cured. As used herein, the term “liquid metal” or “LM” generally refers to any metal or metal alloy that has a relatively low melting temperature under normal pressure and atmospheric conditions. For instance, a liquid metal can have a relatively low melting temperature that is at or below about 100° C., at or below about 80° C., at or below about 60° C., at or below about 40° C., at or below about 20° C., at or below about 10° C., at or below about 0° C., at or below about −10° C., at or below about −20° C., or at or below about −30° C. In certain embodiments, a liquid metal is liquid at or near room temperature (e.g., from about 0° C. to about 40° C., or from about 10° C. to about 30° C.) in stressed or unstressed, deformed, or undeformed state.

As used herein, the term “alloy” refers to a mixture of two or more substances, with at least one substance being metal. For instance, an alloy can be a mixture of two or more metals, or a mixture of one or more metals and one or more non-metals. In certain embodiments, an alloy is a eutectic mixture, e.g., a mixture of two or more substances at specific proportions such that the mixture changes phase to liquid at a eutectic point relatively lower than a melting point of the pure substances. For instance, a eutectic gallium indium mixture (EGaIn) is composed of 75.5% Ga and 24.5% In by weight. EGaIn changes phase to liquid at about 15.7° C., which is lower than the gallium's melting point of about 29.8° C. and the indium's melting point of about 156.6° C.

In some embodiments, the liquid metal includes a pure substance, such as elemental indium (In), tin (Sn), bismuth (Bi), zinc (Zn), lead (Pb), gallium (Ga), aluminum (Al), lithium (Li) or the like. In other embodiments, the liquid metal includes an alloy made of at least one metal (e.g., In, Sn, Bi, Zn, Pb, Ga, Al, and/or Li) and at least one non-metal. Examples of non-metals include, but are not limited to, silicon (Si), germanium (Ge), tellurium (Te), arsenic (As), or the like. In some embodiments, the liquid metal includes an alloy made of two or more metals. In some embodiments, the liquid metal includes an alloy made of two or more metals and one or more non-metals.

In certain embodiments, the liquid metal includes a gallium-based (Ga-based) alloy. For instance, in an embodiment, the liquid metal is a gallium indium alloy (e.g., eutectic GaIn), a gallium tin alloy, a gallium indium tin alloy (e.g., Galinstan), a gallium indium tin zinc alloy, or any combination thereof. In some embodiments, the gallium in the liquid metal is between about 75 and 95 percent by weight, between about 50 and 75 percent by weight, between about 25 and 50 percent by weight, or less than about 25 percent by weight of the liquid metal. In an embodiment, the gallium-based alloy is Ga75.5In24.5, Ga67In20.5Sn12.5, Ga75.5In24.5, Ga61In25Sn13Zn1, or any combination thereof. Ga75.5In24.5 has a melting point of about 15.5° C., Ga67In20.5Sn12.5 has a melting point of about 10.5° C., and Ga61In25Sn13Zn1 has a melting point of about 7.6° C.

In certain embodiments, the liquid metal includes a bismuth-based alloy. For instance, in an embodiment, the liquid metal is a bismuth indium alloy, a bismuth indium tin alloy, or a bismuth indium tin zinc alloy. The bismuth in the liquid metal may be between about 75 and 95 percent by weight, between about 50 and 75 percent by weight, between about 25 and 50 percent by weight, or less than about 25 percent by weight of the liquid metal.

In some embodiments, the liquid metal includes more than one alloy. For instance, in an embodiment, the liquid metal includes both eutectic GaIn and Galinstan. In some embodiments, the liquid metal includes one or more other additional, optional or alternative substances. For instance, in an embodiment, the liquid metal includes a metal alloy made of copper along with one or more of gallium, indium, and/or tin.

The liquid metal material can have any suitable amount of the LM. For instance, in some embodiments, the liquid metal material includes the LM (e.g., a Ga-based alloy) at an amount from about 50% to about 60%, from about 60% to about 70%, from about 70% to about 80%, or from about 80% to about 90% by weight of the liquid metal material. In certain embodiments, the Ga-based alloy includes at least one of gallium indium alloy, gallium tin alloy, gallium indium tin alloy, or gallium indium tin zinc alloy. In some embodiments, the Ga-based alloy includes gallium at an amount of from about 50 wt % to about 55 wt %, from about 55 wt % to about 60 wt %, from about 60 wt % to about 65 wt %, from about 65 wt % to about 70 wt %, from about 70 wt % to about 80 wt %, or from about 80 wt % to about 85 wt % of the liquid metal material.

A deformable interconnect (e.g., the interconnect 340-1, 340-2, or 340-L) can be of any suitable shapes and sizes. For instance, a deformable interconnect (e.g., the interconnect 340-1, 340-2, or 340-L) or a portion of it can be straight, curved, bent, and/or twisted. In some embodiments, a deformable interconnect (e.g., the interconnect 340-1, 340-2, or 340-L) includes a first end portion in contact with a corresponding first circuit component, a second end portion in contact with a corresponding second circuit component, and a middle portion connecting the first and second end portions. For instance, as a non-limiting example, FIG. 3C illustrates the deformable interconnect 340-1 includes a first portion 342-1 (also referred herein as a first via), a second portion 344-1 (also referred herein as a second via), and a third portion 346-1 (also referred herein as a trace) between the first portion 342-1 and the second portion 344-1. The first via 342-1 is in contact with the circuit component 330-1 and electrically connects the circuit component 330-1 with a first end portion of the trace 346-1. The second via 344-1 is in contact with the circuit component 330-2 and electrically connects the circuit component 330-2 with a second end portion of the trace 346-1. In some embodiments, the trace 346-1 is embedded in the second substrate 320, e.g., disposed between the second surface 322 and the third surface 324 of the second substrate 320.

In some embodiments, a deformable interconnect (e.g., the interconnect 340-1, 340-2, or 340-L) has a thickness, e.g., “H3” in FIG. 3C, that is between 1 μm and 600 μm, between 1 μm and 550 μm, between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, or between 1 μm and 10 μm. In some embodiments, the thickness of a deformable interconnect is between 1 μm and 50 μm, between 10 μm and 100 μm, between 50 μm and 200 μm, between 100 μm and 350 μm, between 150 μm and 400 μm, or between 200 μm and 500 μm. In some embodiments, the thickness of a deformable interconnect is at least 1 μm, at least 5 μm, at least 10 μm, at least 20 μm, at least 50 μm, at least 100 μm, at least 150 μm, at least 200 μm, at least 300 μm, at least 400 μm, or at least 500 μm. In some embodiments, the thickness of the interconnect is at most 20 μm, at most 50 μm, at most 100 μm, at most 150 μm, at most 200 μm, at most 300 μm, at most 400 μm, or at most 500 μm.

In some embodiments, a deformable interconnect (e.g., the interconnect 340-1, 340-2, or 340-L) has a width, e.g., “W1” in FIG. 3B, that is between 1 μm and 600 μm, between 1 μm and 550 μm, between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, or between 1 μm and 10 μm. In some embodiments, the width of a deformable interconnect is between 1 μm and 50 μm, between 10 μm and 100 μm, between 50 μm and 200 μm, between 100 μm and 350 μm, between 150 μm and 400 μm, or between 200 μm and 500 μm. In some embodiments, the width of a deformable interconnect is at least 1 μm, at least 5 μm, at least 10 μm, at least 20 μm, at least 50 μm, at least 100 μm, at least 150 μm, at least 200 μm, at least 300 μm, at least 400 μm, or at least 500 μm. In some embodiments, the width of the interconnect is at most 10 μm, at most 20 μm, at most 50 μm, at most 100 μm, at most 150 μm, at most 200 μm, at most 300 μm, at most 400 μm, or at most 500 μm.

In some embodiments, a deformable interconnect (e.g., the interconnect 340-1, 340-2, or 340-L) has a length, e.g., “L1” in FIG. 3C, that is between 0.1 mm and 50 mm, between 0.1 mm and 45 mm, between 0.1 mm and 40 mm, between 0.1 mm and 35 mm, between 0.1 mm and 30 mm, between 0.1 mm and 25 mm, between 0.1 mm and 20 mm, between 0.1 mm and 15 mm, between 0.1 mm and 10 mm, between 0.1 mm and 5 mm, or between 0.1 mm and 1 mm. In some embodiments, the length of a deformable interconnect is between 0.1 mm and 5 mm, between 1 mm and 10 mm, between 5 mm and 20 mm, between 10 mm and 35 mm, between 15 mm and 40 mm, or between 20 mm and 50 mm. In some embodiments, the length of a deformable interconnect is at least 0.1 mm, at least 0.5 mm, at least 1 mm, at least 2 mm, at least 5 mm, at least 10 mm, at least 15 mm, at least 20 mm, at least 30 mm, at least 40 mm, at least 50 mm, at least 60 mm, at least 70 mm, or at least 80 mm. In some embodiments, the length of the interconnect is at most 0.1 mm, at most 0.5 mm, at most 1 mm, at most 2 mm, at most 5 mm, at most 10 mm, at most 15 mm, at most 20 mm, at most 30 mm, at most 40 mm, or at most 50 mm.

In some embodiments, the thickness of a deformable interconnect changes as a function of length and/or depth of the interconnect. For instance, in some embodiments, the width of the interconnect is at least 1, 2, 3, 5, 10, 15, 20, or 25 percent larger at one point in the length of the interconnect as it is at a second point in the length of the interconnect. In some embodiments, the first point in the length of the interconnect is the first point at which the interconnect has the largest cross-section, and the second point is the point at which the interconnect has the smallest cross-section. In some embodiments, the thickness of the interconnect does not appreciably or measurably change as a function of length and/or depth of the interconnect.

In some embodiments, the width of the interconnect changes as a function of length and/or depth of the interconnect. For instance, in some embodiments, the width of the interconnect is at least 1, 2, 3, 5, 10, 15, 20, or 25 percent larger at one point in the length of the interconnect as it is at a second point in the length of the interconnect. In some embodiments, the first point in the length of the interconnect is the first point at which the interconnect has the largest cross-section, and the second point is the point at which the interconnect has the smallest cross-section. In some embodiments, the width of the interconnect does not appreciably or measurably change as a function of length and/or depth of the interconnect.

### 3.4. Exemplary Characteristics

The deformable substrates and deformable interconnects provide deformable electronic devices of the present disclosure with several advantages. For instance, they allow for configuring electronic devices that can function properly even when the devices are physically deformed. They allow for configuring electronic devices in various forms, shapes and/or sizes, with high complexity, and for use in various fields. In some embodiments, with the deformable substrates and deformable interconnects disclosed herein, the circuit 350 can maintain conductivity with a resistance under a resistance threshold (e.g., a threshold that allows the deformable electronic device 300 to function properly) when the deformable electronic device 300 is subjected to one or more certain conditions (e.g., strain, cycle, temperature, bending, etc.). The resistance threshold may be at most 50 Ohms per cm (Ω/cm), at most 100 (Ω/cm, or at most 150 Ω/cm.

In some embodiments, the circuit 350 maintains conductivity with a resistance under the resistance threshold when the deformable electronic device 300 is subject to a strain. As used herein, a strain (ε) is defined as a function of a change in a gauge length (δ) against an original gauge length (L), such as:

$$ε = \frac{δ}{L} .$$

For instance, in some embodiments, a strain of X % means a change in length of a deformable substrate (e.g., the first substrate 310 or the second substrate 320) as a function of an original length of the deformable substrate, where X is a number between 0 and 100. In some embodiments, the strain of X % means a change in width of the deformable substrate as a function of an original width of the deformable substrate. In some embodiments, the strain of X % means a change in depth of the deformable substrate as a function of an original depth of the deformable substrate. As a non-limiting example, if a deformable substrate has an original length of 10 cm and is subjected to 100% strain, the deformable substrate is to stretch to a new length of 20 cm. In some embodiments, the circuit 350 maintains conductivity with a resistance under the resistance threshold when the deformable electronic device 300 is subject to a strain of from about 20% to about 100%, from about 30% to about 120%, from about 40% to about 150%, or from about 50% to about 200%.

In some embodiments, the circuit 350 maintains conductivity with a resistance under the resistance threshold when the deformable electronic device 300 is subject to strain cycles. As used herein, a strain cycle refers to a process in which a strain is applied to the first substrate 310 or the second substrate 320 in the first half of the cycle to stretch the first substrate 310 or the second substrate 320 and then the strain is released in the second half of the cycle. For instance, a strain cycle of 100% cyclic strain and 5 second per cycle (e.g., a 5 second cycle under 100% strain) refers to a process in which a strain is applied in the first half of 5 seconds (2.5 seconds) to stretch the first substrate 310 or the second substrate 320 to double its length or width and then the strain is released in the second half of 5 seconds. In some embodiments, the circuit 350 maintains conductivity with a resistance under the resistance threshold when the deformable electronic device 300 is subject to at least 10 strain cycles, at least 50 strain cycles, at least 100 strain cycles, at least 200 strain cycles, at least 500 strain cycles, at least 1,000 strain cycles, at least 5,000 strain cycles, at least 10,000 strain cycles, at least 15,000 strain cycles, at least 20,000 strain cycles, at least 25,000 strain cycles, or at least 30,000 strain cycles of 100% strain.

In some embodiments, the circuit 350 maintains conductivity with a resistance under the resistance threshold when the deformable electronic device 300 is subject to a temperature (e.g., the deformable electronic device 300 is used or placed in an environment at the temperature). In some embodiments, the temperature is within a range of from about −30° C. to about 50° C., from about −20° C. to about 60° C., from about −10° C. to about 70° C., or from about 0° C. to about 80° C. In some embodiments, the temperature is at least −30° C., at least −20° C., at least −10° C., at least 0° C., at least 10° C., at least 20° C., at least 30° C., at least 40° C., or at least 50° C. In some embodiments, the temperature is at most 10° C., at most 20° C., at most 30° C., at most 40° C., at most 50° C., at most 60° C., at most 70° C., or at most 80° C.

In some embodiments, when the deformable electronic device 300 is subjected to one or more certain conditions (e.g., strain, cycle, temperature, bending, etc.), the circuit 350 maintains conductivity with a resistance of from about 0.1 Ω/cm to about 10 Ω/cm, from about 1 Ω/cm to about 50 Ω/cm, from about 25 Ω/cm to about 100 Ω/cm, or from about 50 Ω/cm to about 150 Ω/cm. In some embodiments, when the deformable electronic device 300 is subjected to one or more certain conditions, the circuit 350 maintains conductivity with a resistance of at least 0.1 Ω/cm, at least 1 Ω/cm, at least 5 Ω/cm, at least 10 Ω/cm, at least at least 20 Ω/cm, at least 30 Ω/cm, at least 40 Ω/cm, at least 50 Ω/cm, at least 60 Ω/cm, at least 70 Ω/cm, at least 80 Ω/cm, at least 90 ΩΩ/cm, or at least 100 Ω/cm. In some embodiments, when the deformable electronic device 300 is subjected to one or more certain conditions, the circuit 350 maintains conductivity with a resistance of at most 1 Ω/cm, at most 5 Ω/cm, at most 10 Ω/cm, at most at most 20 Ω/cm, at most 30 Ω/cm, at most 40 Ω/cm, at most 50 Ω/cm, at most 60 Ω/cm, at most 70 Ω/cm, at most 80 Ω/cm, at most 90 Ω/cm, at most 100 Ω/cm, at most 120 Ω/cm, or at most 140 Ω/cm.

In some embodiments, the circuit 350 is free of degradation in conductivity when the first substrate 310 and the second substrate 320 are bent, such as bent around a cylinder. In some embodiments, the circuit 350 is free of degradation in conductivity when the first substrate 310 and the second substrate 320 are bent, e.g., around a cylinder, for a period of time and released. In some embodiments, the bending radius is from about 1 cm to about 10 cm, from about 5 cm to about 15 cm, from about 10 cm to about 20 cm, or from about 15 cm to about 25 cm. In some embodiments, the bending radius is similar or substantially similar to a size of a human wrist (e.g., from about 4 cm to about 10 cm). The period of time may be seconds, minutes, hours, days, weeks, or months.

In some embodiments, a deformable interconnect (e.g., the interconnect 340-1, 340-2, or 340-L) is free of degradation in conductivity when the first substrate 310 and the second substrate 320 are bent, e.g., around a cylinder or the like, for a period of time and then released. In some embodiments, each deformable interconnect (e.g., the interconnect 340-1, 340-2 and 340-L) of the circuit 350 is free of degradation in conductivity when the first substrate 310 and the second substrate 320 are bent, e.g., around a cylinder or the like, for a period of time and then released. In some embodiments, the bending radius is from about 2 cm to about 10 cm. In some embodiments, the period of time is about 10 seconds to about 5 minutes, or about 1 minute to 10 minutes.

### 3.5. Exemplary Implementations

As disclosed herein, the deformable substrates and deformable interconnects of the present disclosure allow for configuring highly complex electronic devices that can function properly even when the devices are physically deformed. Accordingly, the electronic device 300 can be implemented in various forms, shapes and/or sizes and can be used in a number of fields, such as medical robots, augmented reality (AR), and virtual reality (VR). For instance, the electronic device 300 can be implemented as a wearable device worn by a subject (e.g., a human or a robot) or attached to a subject. Examples of such a wearable device include but are not limited to a garment worn by a subject around a wrist, a hand, a finger, or a combination thereof of the subject.

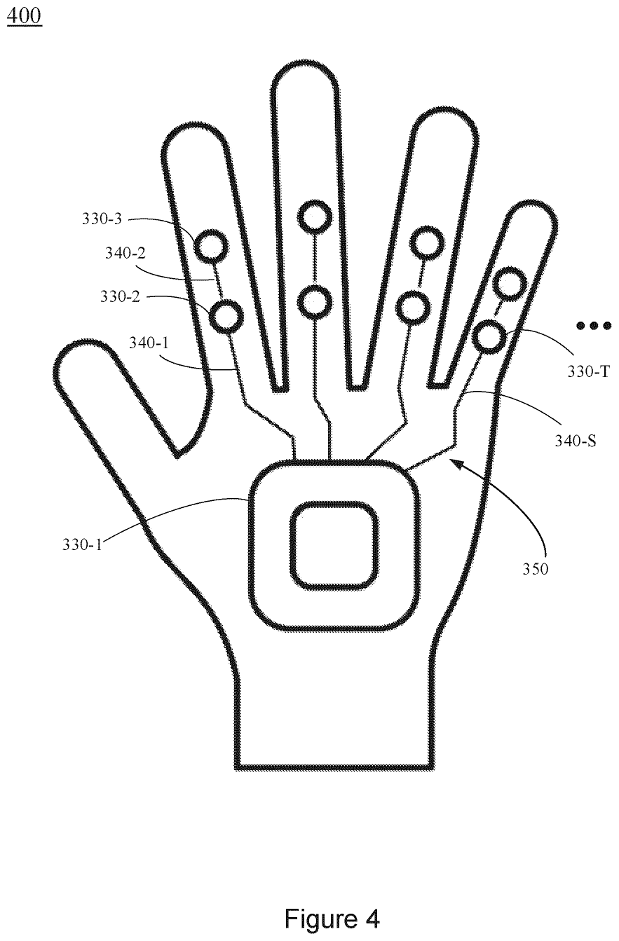

As a non-limiting example, FIG. 4 illustrates an exemplary implementation of the electronic device 300 in the form of a glove, generally designated 400, in accordance with some embodiments of the present invention. In some embodiments, the glove 400 includes a plurality of circuit components (e.g., the circuit components 330-1, 330-2, 330-3 . . . 330-T) and a plurality of deformable interconnects (e.g., the deformable interconnects 340-1, 340-2, . . . 340-S). The deformable interconnect 340-1 electrically connects the circuit component 330-1 and the circuit component 330-2, and the deformable interconnect 340-2 electrically connects the circuit component 330-2 and the circuit component 330-3. While FIG. 4 illustrates that the circuit components 330 and the deformable interconnects 340 are disposed at four figures and the palm, it should be noted that this is by way of illustration, and it is non-limiting. The glove 400 can include any suitable number of circuit components and any suitable number of deformable interconnects, which can be disposed anywhere in the glove, such as a finger, the palm or a place other than a finger/palm.

In some embodiments, the glove 400 has at least 2, at least 5, at least 10, at least 20, at least 30, at least 40, at least 50, at least 60, at least 70, at least 80, at least 90, at least 100, at least 150, at least 200, at least 250, at least 300, at least 350, at least 400, at least 450, at least 500, at least 600, at least 700, at least 800, at least 900, or at least 1000 circuit components. In some embodiments, the plurality of circuit components includes one or more terminals, one or more resistors, one or more transistors, one or more capacitors, one or more inductors, one or more transformers, one or more diodes, one or more sensors, or any combination thereof. In some embodiments, the glove 400 has at least 2, at least 5, at least 10, at least 20, at least 30, at least 40, at least 50, at least 60, at least 70, at least 80, at least 90, at least 100, at least 150, at least 200, at least 250, at least 300, at least 350, at least 400, at least 450, at least 500, at least 600, at least 700, at least 800, at least 900, or at least 1000 deformable interconnects.

In some embodiments, the first substrate 310 and the second substrate 320 of the electronic device 300 form the base of the glove, e.g., the substrates of the electronic device 300 itself is shaped as the glove. In some embodiments, the base of the glove is formed of a material, to which the electronic device 300 is attached or with which the electronic device 300 is integrated. Examples of the material for the base include but are not limited to fabric, leather, textiles, fibers, vinyl, silicone, and plastic. The base made of such a material can conform to the shape of a user's hand and allow the substrates of the electronic device 300 to deform (e.g., expand, contract, bend, twist).

### 4. EXEMPLARY METHODS

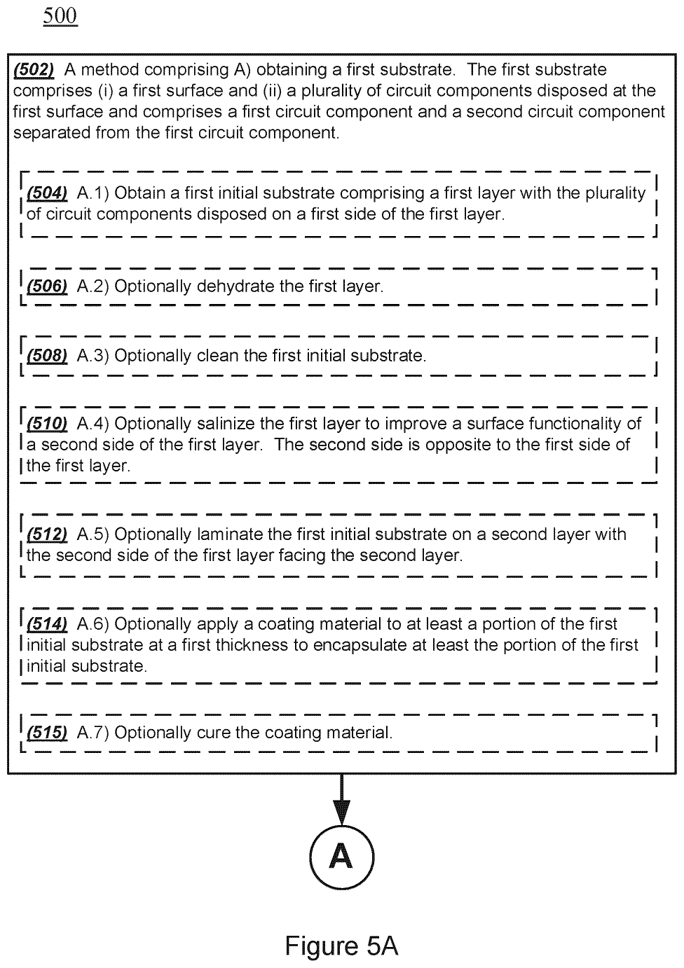

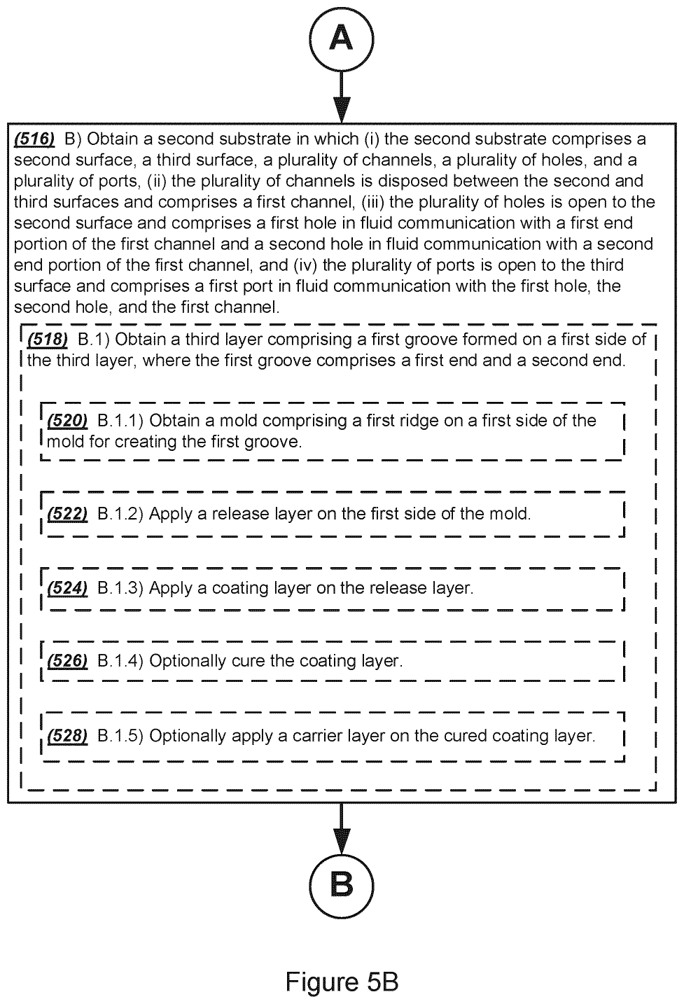

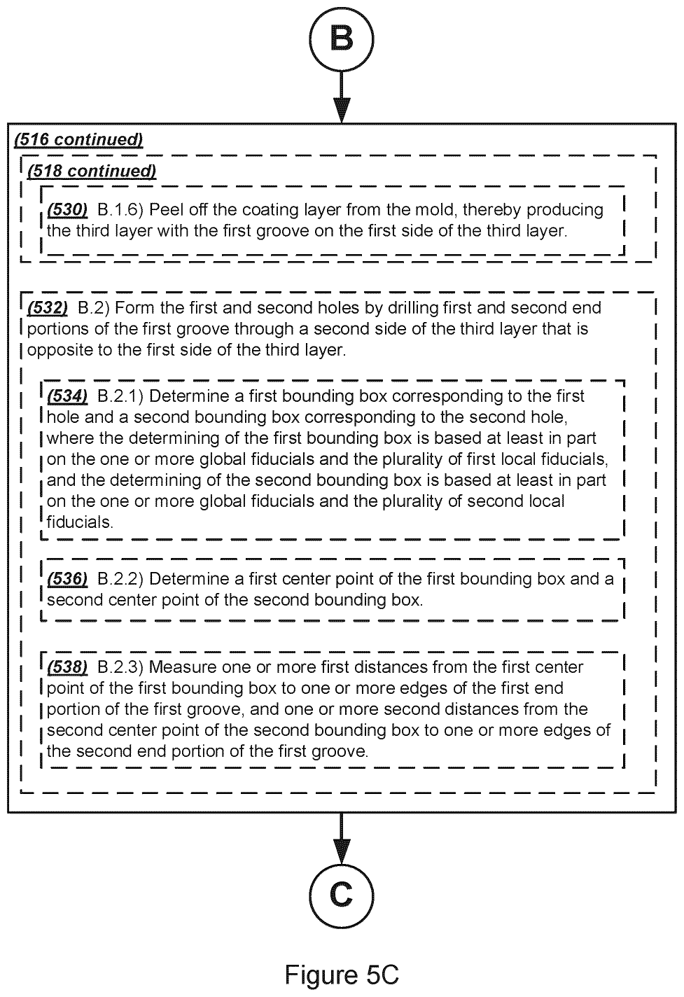

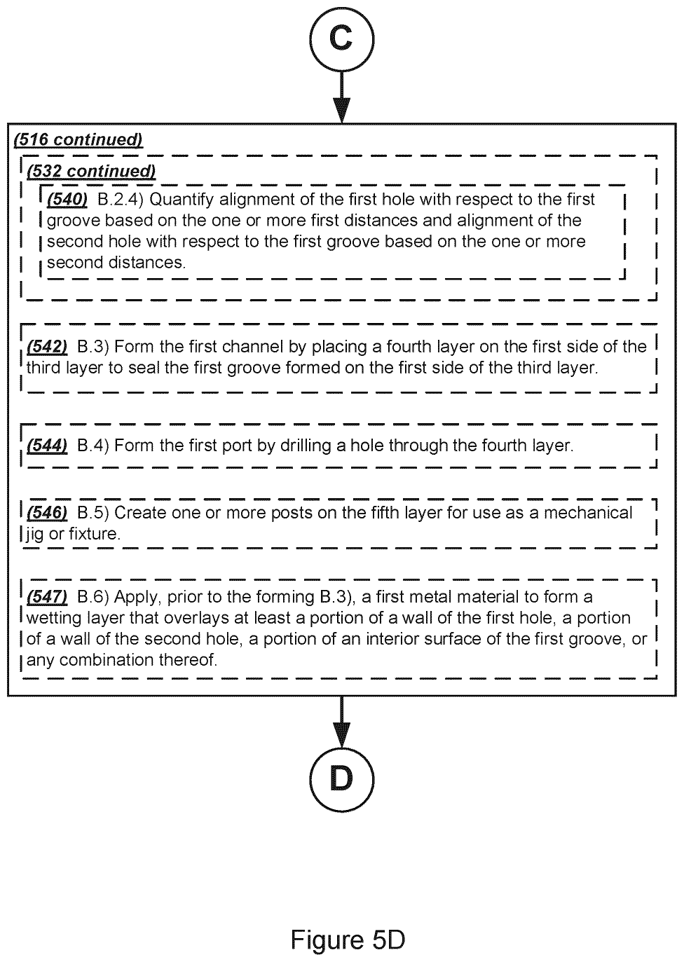

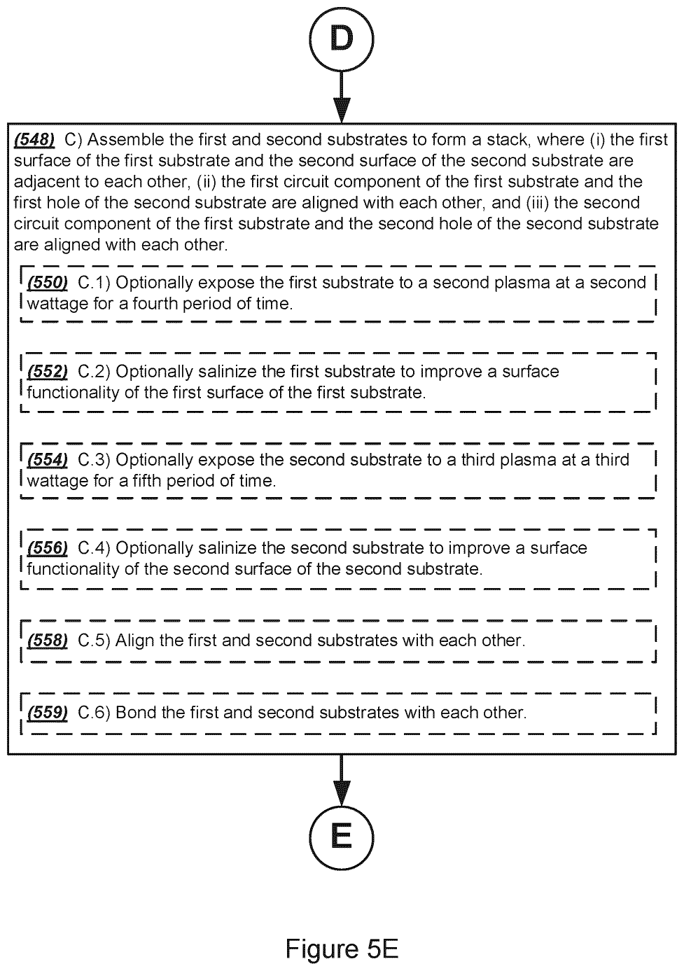

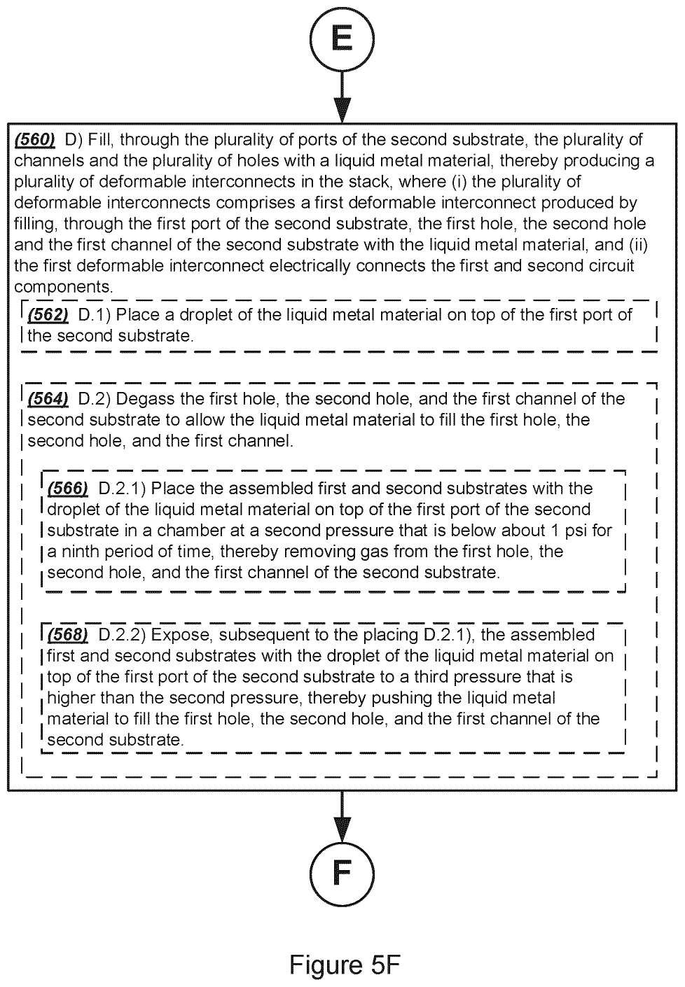

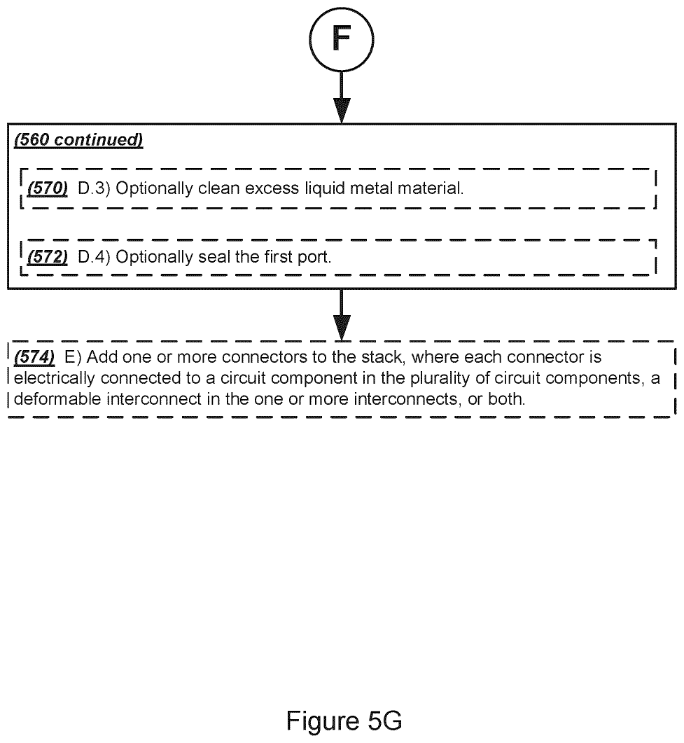

FIGS. 5A-5G collectively provides a flowchart illustrating a method, generally designated 500, in accordance with some embodiments of the present disclosure. The method 500 is configured for fabricating a deformable electronic device, such as the deformable electronic device 300 of the present disclosure. The method 500 includes: A) obtaining a first substrate (e.g., the first substrate 310 of FIG. 3A) having a plurality of circuit components, B) obtaining a second substrate having a plurality of channels and a plurality of holes, C) assembling the first and second substrates to form a stack, and D) filling the plurality of channels and the plurality of holes with a liquid metal material, thereby producing a plurality of deformable interconnects (e.g., the deformable interconnects 340 in FIG. 3A) in the stack. The plurality of deformable interconnects electrically connects the plurality of circuit components to form one or more circuits.

The method 500 can include optional or alternative processes, such as those indicated by dashed boxes in the flow chart. The method 500 can be carried out in full or in part. Moreover, the method 500 can be carried out in the order of events recited or in any other order that is logically possible. Further, one or more processes of the method 500 may be performed or controlled by the distributed additive manufacture system 100 or the computer system 200 of the present disclosure. For instance, one or more processes of the method 500 may be encoded in a single module or multiple modules of the present disclosure (e.g., one or more modules in the memory 292 of the computer system 200).

Block 502. Referring to block 502 of FIG. 5A, the method 500 includes A) obtaining a first substrate, where the first substrate includes (i) a first surface and (ii) a plurality of circuit components disposed at the first surface and including a first circuit component and a second circuit component separated from the first circuit component. For instance, in some embodiments, the method 500 obtains a first substrate 310 of the present disclosure disclosed herein with respect to the deformable electronic device 300. The first substrate 310 has a first surface 312 and a plurality of circuit components (e.g., the circuit components 330-1, 330-2, 330-3, 330-4, . . . ). The first substrate 310 can be of any shape and/or size. The circuit component 330-1 and the circuit component 330-2 are separated from each other, and the circuit component 330-3 and the circuit component 330-4 are separated from each other. Examples of a circuit component include but are not limited to a terminal, an energy source (e.g., power supply), an interconnect (e.g., a line interconnect, such as a wire), a load (e.g., a device, a sensor, etc.), a controller (e.g., switch), a resistor, a transistor, a capacitor, an inductor, a transformer, a diode, a contact pad or a combination thereof.

The first substrate 310 can be of a single layer or composed of multiple layers. In some embodiments, the first substrate 310 includes a first layer, where the plurality of circuit components is disposed on a first side of the first layer. In an exemplary embodiment, the first layer includes a polyimide (Pi) film. In some embodiments, the first layer is laminated on a second layer. In an exemplary embodiment, the second layer includes a polyethylene terephthalate (PET) film. In some embodiments, the first layer is laminated on the second layer using a double-sided dicing tape.

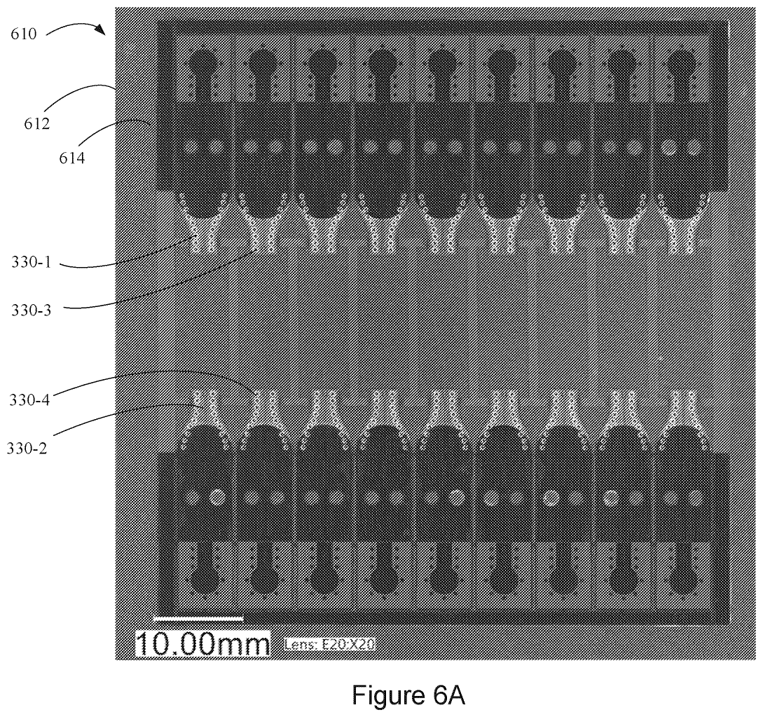

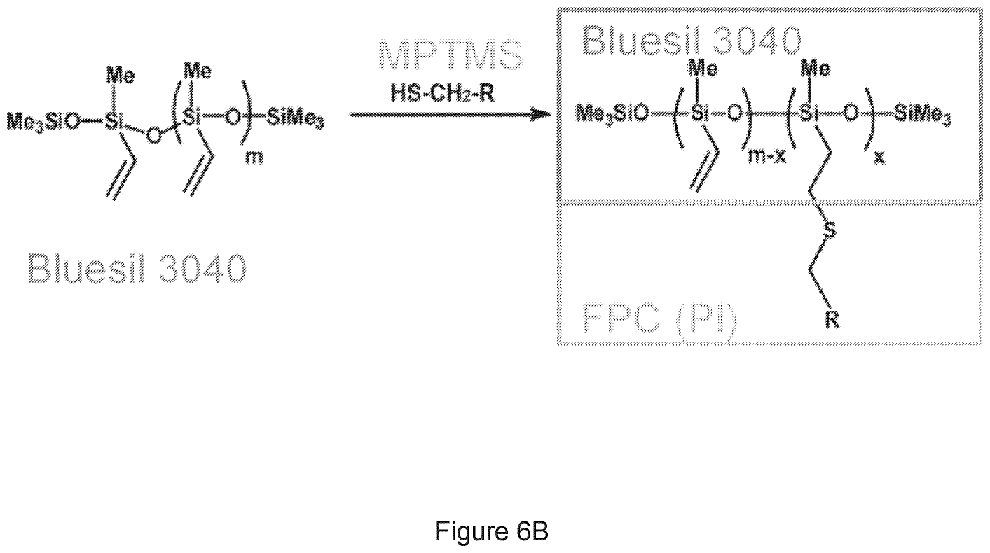

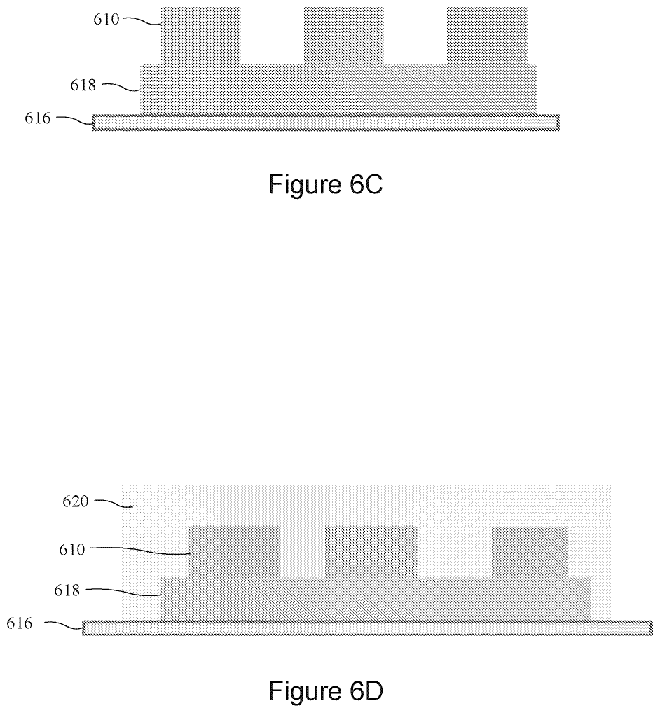

The first substrate 310 can be a commercial substrate available in the market or made by the method 500 or modified by the method 500. As a non-limiting example, blocks 504-515 and FIGS. 6A-6E present some exemplary processes for fabricating or modifying a first substrate.

Block 504. Referring to block 504 of FIG. 5A, in some embodiments, the obtaining A) of the first substrate includes A.1) obtaining a first initial substrate including a first layer with the plurality of circuit components disposed on a first side of the first layer. For instance, as a non-limiting example, FIG. 6A illustrates a first initial substrate 610 of a rectangular shape. The first initial substrate 610 includes a first layer 612, where a plurality of circuit components (e.g., the circuit components 330-1, 330-2, 330-3, 330-4, . . . ) is disposed on a first side 614 of the first layer 612. The circuit component 330-1 and the circuit component 330-2 are separated from each other, and the circuit component 330-3 and the circuit component 330-4 are separated from each other. In some embodiments, one or more circuit components in the plurality of circuit components are components of one or more FPCs. In an exemplary embodiment, the first layer 612 includes a polyimide (Pi) film.

Block 506. Referring to block 506 of FIG. 5A, in some embodiments, the obtaining A) of the first substrate includes A.2) dehydrating, optionally, the first layer. For instance, in some embodiments, the first layer (e.g., Pi film) is dehydrated for a first period of time at a first temperature. In some embodiments, the first period of time is from about 5 minutes to about 20 minutes, from about 10 minutes to about 30 minutes, from about 20 minutes to about 45 minutes, or from about 30 minutes to about an hour. In some embodiments, the first temperature is from about 100° C. to about 130° C., from about 110° C. to about 140° C., from about 120° C. to about 150° C., or from about 130° C. to about 160° C. In an exemplary embodiment, the first period of time is about 20 minutes, and the first temperature is about 130° C.

Block 508. Referring to block 508 of FIG. 5A, in some embodiments, the obtaining A) of the first substrate includes A.3) cleaning, optionally, the first initial substrate. For instance, in some embodiments, the dehydrated polyimide is exposed to plasma. In some embodiments, the dehydrated polyimide is exposed to a plasma oven mechanism that is configured to expel plasma at a first wattage for a second period of time at a first flow rate. In some embodiments, the first wattage is between 100 watts (W) and 500 W. In an exemplary embodiment, the first wattage is about 250 W. In some embodiments, the second period of time is between 5 minutes and 20 minutes. In an exemplary embodiment, the second period of time is about 10 minutes. In some embodiments, the first flow rate is from about 1 standard cubic centimeters per minute (SCCM) to about 5 SCCM, from about 2 SCCM to about 5 SCCM, from about 5 SCCM to about 10 SCCM, from about 10 SCCM to about 15 SCCM, or from about 15 SCCM to about 20 SCCM. In some embodiments, the plasma includes oxygen (O2), tetrafluoromethane (CF4), or a combination thereof. In an exemplary embodiment, the dehydrated polyimide is exposed to the plasma oven mechanism that is configured to expel plasma including O2 at about 12 SCCM and CF4 at about 3 SCCM at a first wattage of about 250 W for a second period of time of about 10 minutes, which forms an exposed PI.

Block 510. Referring to block 510 of FIG. 5A, in some embodiments, the obtaining of the first substrate includes A.4) salinizing, optionally, the first layer to improve a surface functionality of a second side of the first layer, where the second side is opposite to the first side of the first layer. For instance, in some embodiments, some or all of the exposed PI is submerged in a solution for a third period of time in order for salinization of a surface of the exposed PI. In some embodiments, the solution includes (3-mercaptopropyl) trimethoxysilane (MPTMS) as illustrated in FIG. 6B. In some embodiments, the solution includes a concentration of 1% of MPTMS. In some embodiments, the third period of time is from about 30 minutes to about 70 minutes. In an exemplary embodiment, the third period of time is about 50 minutes. In some embodiments, the submerging of the exposed PI forms a salinized PI.

Block 512. Referring to block 512 of FIG. 5A, in some embodiments, the obtaining A) of the first substrate includes A.5) laminating, optionally, the first initial substrate on a second layer with the second side of the first layer facing the second layer. For instance, as a non-limiting example, FIG. 6C illustrates laminating the first initial substrate 610 on a second layer 616 with the second side (e.g., the side opposite of the first side 614) of the first layer 614 of the first initial substrate 610 facing the second layer 616. In some embodiments, the second side of the first layer 614 of the first initial substrate 610 is the salinized PI. In some embodiments, the second side (e.g., the salinized PI) of the first layer 614 of the first initial substrate 610 is laminated on the second layer 616 using a double-sided dicing tape 618. Examples of such a double-sided dicing tape include but are not limited to UC-228W-110 double dicing tape provided by Furukawa Electric Co., LTD, Chiyoda City, Tokyo, Japan.

Block 514. Referring to block 514 of FIG. 5A, in some embodiments, the obtaining A) of the first substrate includes A.6) applying, optionally, a coating material to at least a portion of the first initial substrate at a first thickness to encapsulate at least the portion of the first initial substrate. For instance, as a non-limiting example, FIG. 6D illustrates a coating material is applied to at least a portion of the first initial substrate 610 at a first thickness, thereby forming a coating layer 620 that encapsulates at least the portion of the first initial substrate 610. While FIG. 6D illustrates the complete encapsulation of the first initial substrate 610, it should be noted that the coating layer 620 can but does not have to encapsulate the entire first initial substrate 610. Moreover, while FIG. 6D illustrates a single coating layer, it should be noted that multiple coating layers or materials can be used. In some embodiments, the coating material includes silicone (e.g., Bluesil™ from Elkem Silicones). In some embodiments, the coating layer 620 has a thickness of from about 50 μm to about 100 μm, from about 75 μm to about 125 μm, or from about 100 μm to about 150 μm. In some embodiments, the coating layer 620 has a thickness of from about 50 μm to about 150 μm. In an exemplary embodiment, the coating layer 620 is about 100 μm thick. In some embodiments, the coating material includes silicone.

Block 515. Referring to block 515 of FIG. 5A, in some embodiments, the obtaining of the first substrate includes A.7) curing, optionally, the coating material. In some embodiments, the coating material (e.g., the coating layer 620) is cured for a sixth period of time at a second temperature. In some embodiments, the second temperature is room temperature or ambient temperature (e.g., from about 20° C. to about 30° C.). In some embodiments, the sixth period of time is a number of minutes, hours or days.

As a non-limiting example, FIG. 6E shows a first substrate 310 resulted from the initial first substrate 610 after the coating and curing processes.

Block 516. Referring to block 516 of FIG. 5B, the method 500 includes B) obtaining a second substrate, where (i) the second substrate includes a second surface, a third surface, a plurality of channels, a plurality of holes, and a plurality of ports, (ii) the plurality of channels is disposed between the second and third surfaces and includes a first channel, (iii) the plurality of holes is open to the second surface and includes a first hole in fluid communication with a first end portion of the first channel and a second hole in fluid communication with a second end portion of the first channel, and (iv) the plurality of ports is open to the third surface and includes a first port in fluid communication with the first hole, the second hole, and the first channel.

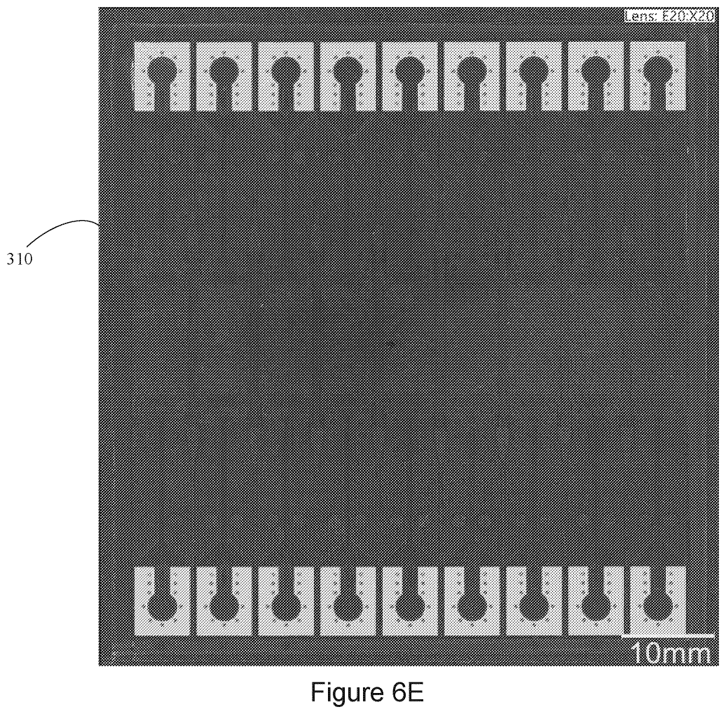

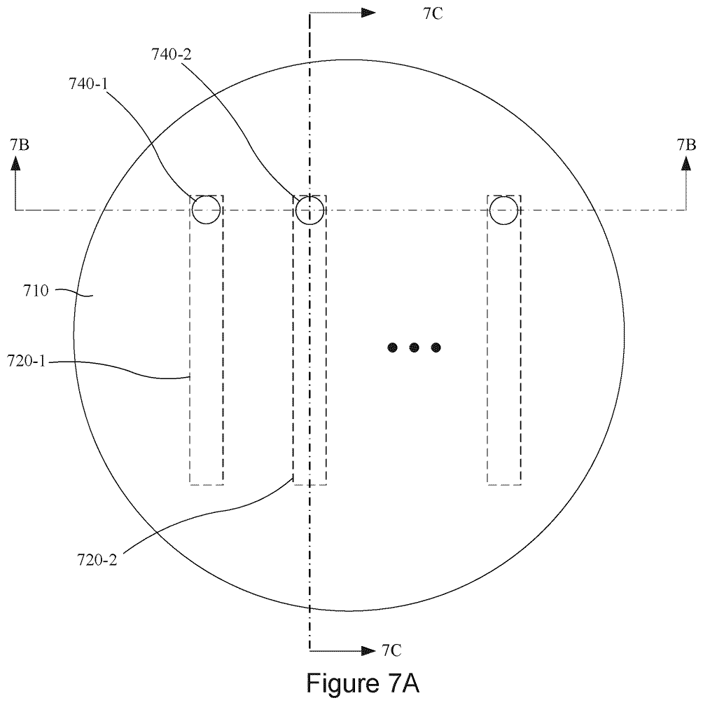

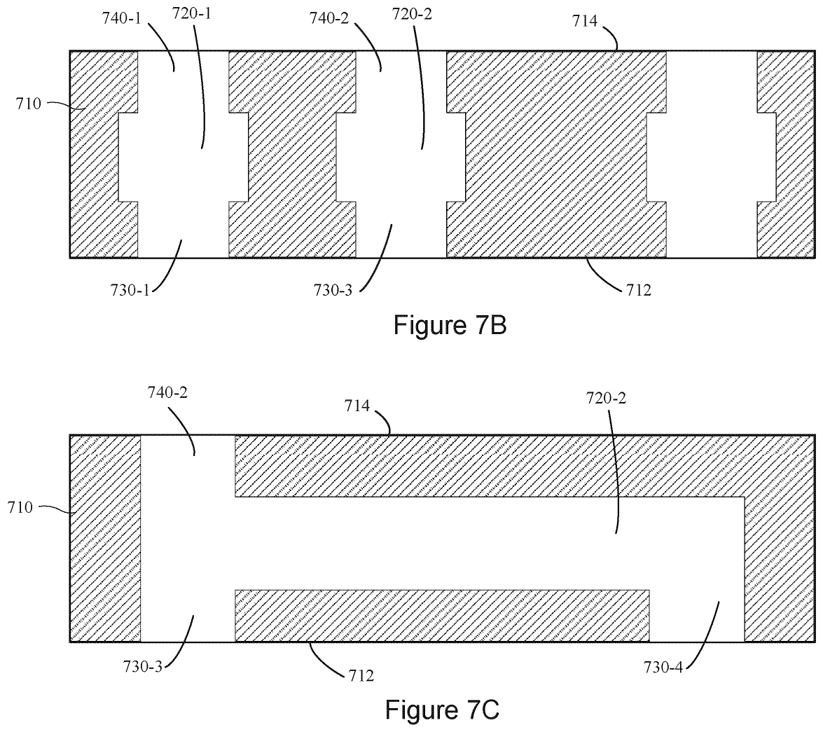

For instance, as a non-limiting example, FIGS. 7A-7C illustrate a second substrate 710 obtained by the method 500 in accordance with some embodiments of the present disclosure. The second substrate 710 includes a second surface 712, a third surface 714, a plurality of channels (e.g., the channels 720-1, 720-2, . . . ), a plurality of holes (e.g., the holes 730-1, 730-2, 730-3, 730-4 . . . ), and a plurality of ports (e.g., the ports 740-1, 740-2, . . . ). The plurality of channels 720 is disposed between the second surface 712 and the third surface 714, and includes a first channel (e.g., the channel 720-2). The plurality of holes 730 is open to the second surface 712 and includes a first hole (e.g., the hole 730-3) in fluid communication with a first end portion of the first channel (e.g., the channel 720-2) and a second hole (e.g., the hole 730-4) in fluid communication with a second end portion of the first channel (e.g., the channel 720-2). The plurality of ports 740 is open to the third surface 714 and includes a first port (e.g., the port 740-2) in fluid communication with the first hole (e.g., the hole 730-3), the second hole (e.g., the hole 730-4), and the first channel (e.g., the channel 720-2).

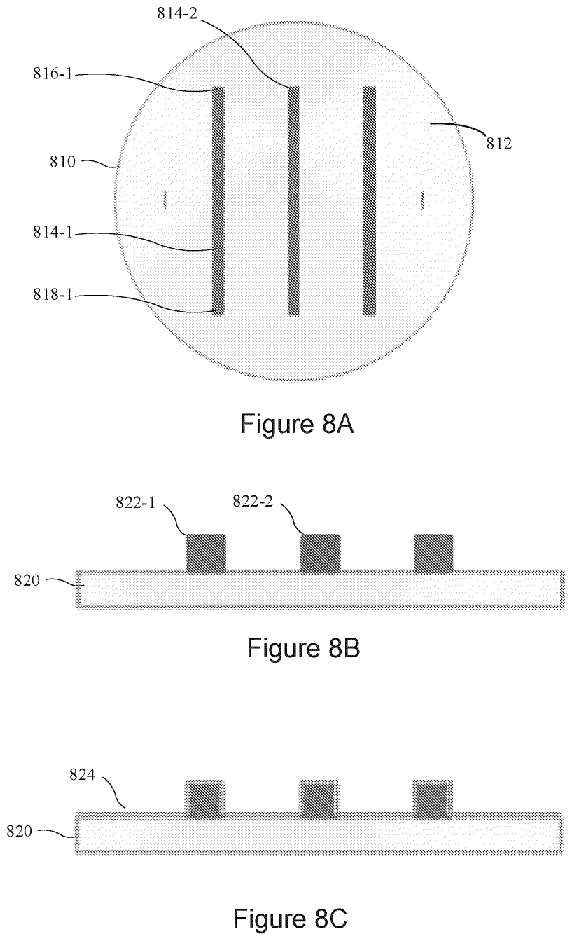

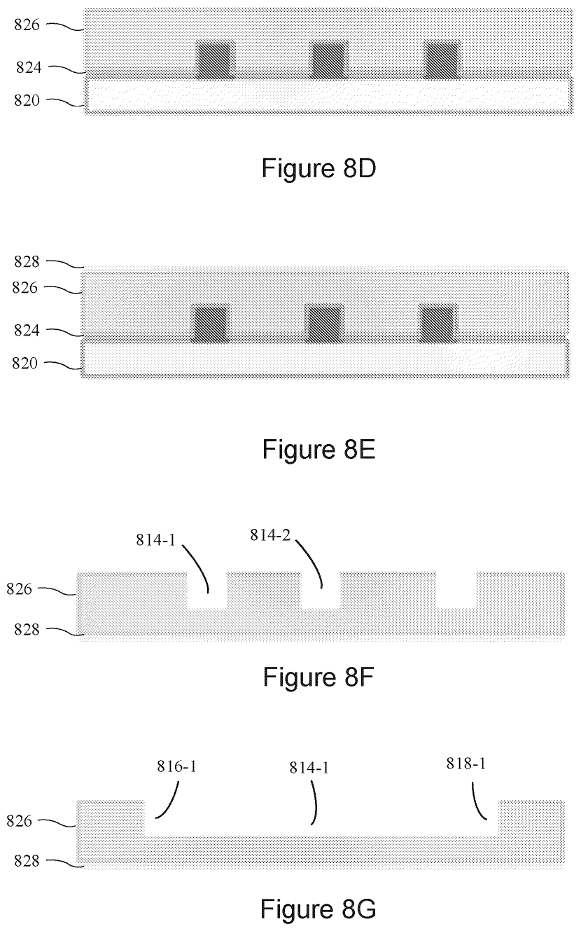

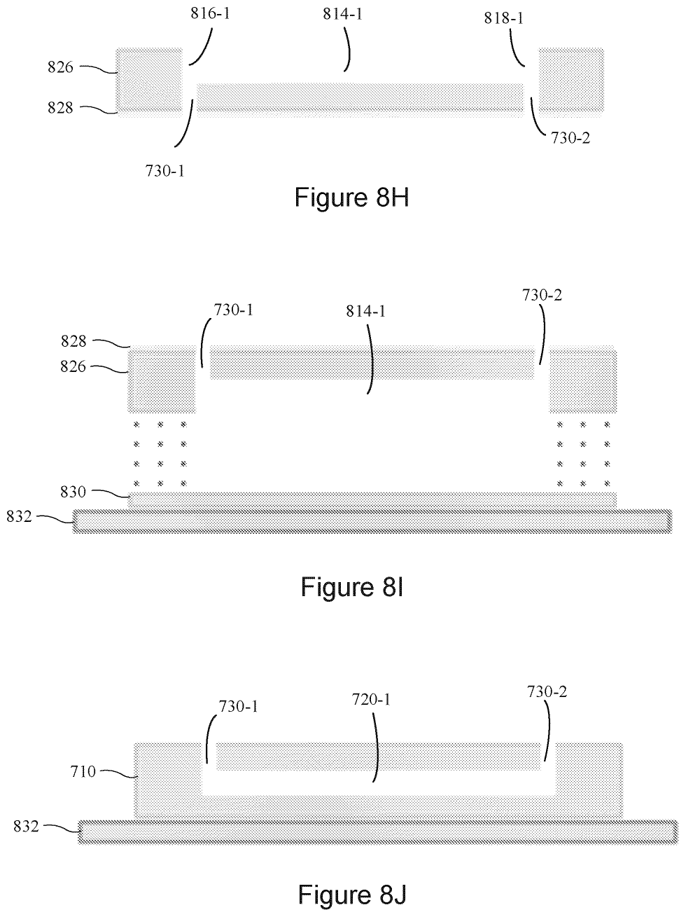

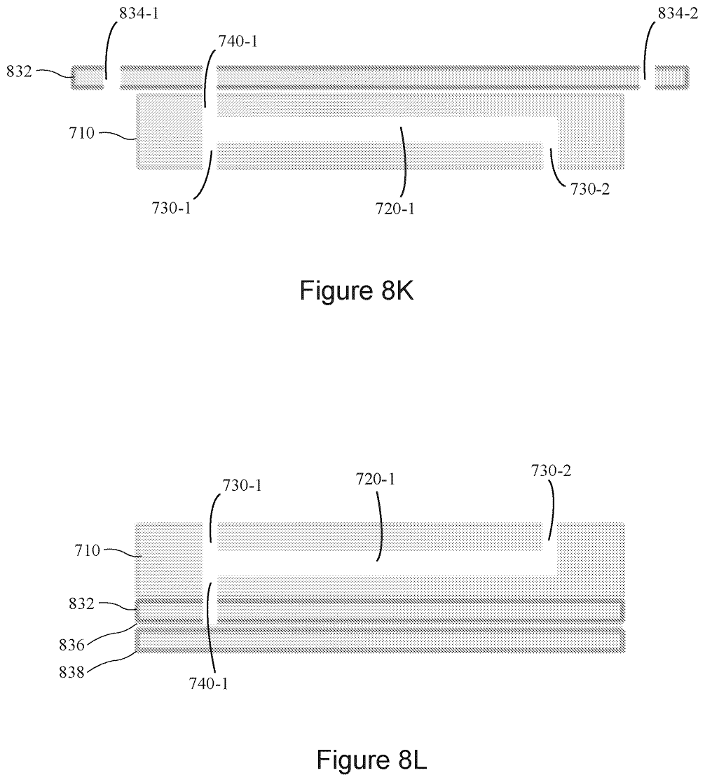

In some embodiments, the second substrate 710 is made by the method 500, such as exemplary processes disclosed in blocks 518-547 and FIGS. 8A-8K. However, the present disclosure is not limited thereto.

Block 518. Referring to block 518 of FIG. 5B, in some embodiments, the obtaining B) of a second substrate (e.g., the second substrate 710) includes B.1) obtaining a third layer including a first groove formed on a first side of the third layer, where the first groove includes a first end and a second end. For instance, as a non-limiting example, FIG. 8A illustrates a third layer 810 obtained by the method 500. The third layer 810 includes a first groove 814-1 formed on a first side 812 of the third layer 810. The first groove 814-1 includes a first end 816-1 and a second end 818-1. In some embodiments, the third layer 810 includes a plurality of grooves (e.g., grooves 814-1, 814-2, . . . ) formed on the first side 812 of the first layer 810.

In some embodiments, the third layer 810 is formed by the method 500, such as exemplary processes presented in blocks 520-530 and FIGS. 8B-8G. However, the present disclosure is not limited thereto.

Block 520. Referring to block 520 of FIG. 5B, in some embodiments, the obtaining B.1) of a third layer (e.g., the third layer 810) includes B.1.1) obtaining a mold including a first ridge on a first side of the mold for creating the first groove. For instance, as a non-limiting example, FIG. 8B illustrates a cross-sectional view of a mold 820 obtained by the method. The mold 820 includes a first ridge 822-1 on a first side of the mold for creating the first groove 814-1. In some embodiments, the mold 820 includes a plurality of ridges (e.g., ridges 822-1, 822-2, . . . ) on the first side of the mold for creating a plurality of grooves (e.g., grooves 814-1, 814-2, . . . ).

In some embodiments, the mold 820 is a master mold, such as an SU-8 master mold, with ridges or channels. Additional details and information regarding the SU-8 mold technique is found at Elveflow, “How to Make an Expoxy Su-8 M old? The SU-8 mold fabrication process: Tips and Tricks,” Elveflow, available at elveflow.com/microfluidic-reviews/soft-lithography-microfabrication/su-8-mold-lithography/(accessed Sep. 27, 2023), which is hereby incorporated by reference in its entirety.

Block 522. Referring to block 522 of FIG. 5B, in some embodiments, the obtaining B.1) of a third layer (e.g., the third layer 810) includes B.1.2) applying a release layer on the first side of the mold. For instance, as a non-limiting example, FIG. 8C illustrates a release layer 824 applied on the first side of the mold 820 that covers the plurality of ridges (e.g., ridges 822-1, 822-2, . . . ). The release layer may be a low surface energy coating configured to facilitate the separation of a patterned layer. In some embodiments, the release layer is configured to allow for clean pattern replications.

Block 524. Referring to block 524 of FIG. 5B, in some embodiments, the obtaining B.1) of a third layer (e.g., the third layer 810) includes B.1.3) includes applying a coating layer on the release layer. For instance, as a non-limiting example, FIG. 8D illustrates a coating layer 826 applied on the release layer 824. In some embodiments, the coating layer is made of a material such as silicone. In some embodiments, the coating layer is applied by blade coating silicone on the release layer.

Block 526. Referring to block 526 of FIG. 5B, in some embodiments, the obtaining B.1) of a third layer (e.g., the third layer 810) includes B.1.4) curing, optionally, the coating layer. In an exemplary embodiment, the curing is performed via uninhibited curing. However, the present disclosure is not limited thereto. In some embodiments, after curing, the coating layer has a thickness (e.g., the dimension along the vertical direction in FIG. 8D) of from about 50 μm to about 250 μm, from about 100 μm to about 300 μm, from about 150 μm to about 350 μm, or from about 200 μm to about 400 μm. In some embodiments, after curing, the coating layer has a thickness from about 150 μm to about 250 μm. In an exemplary embodiment, after curing, the coating layer has a thickness of about 200 μm.

Block 528. Referring to block 528 of FIG. 5B, in some embodiments, the obtaining B.1) of a third layer (e.g., the third layer 810) includes B.1.5) applying, optionally, a carrier layer on the cured coating layer. For instance, as a non-limiting example, FIG. 8E illustrates a carrier layer 828 applied on the cured coating layer 826. In some embodiments, the carrier layer includes a single-sided dicing tape. In some embodiments, the carrier layer is disposed on the upper surface of the coating layer after the coating layer is fully cured.

Block 530. Referring to block 530 of FIG. 5C, in some embodiments, the obtaining B.1) of a third layer (e.g., the third layer 810) includes B.1.6) peeling off the coating layer from the mold, thereby producing the third layer with the first groove on the first side of the third layer. For instance, as a non-limiting example, FIG. 8F illustrates a first cross-sectional view (e.g., in a x-z plane) of the coating layer 826 along with the carrier layer 828 that has been peeled off from the mold 820. FIG. 8G illustrates a second cross-sectional view (e.g., in a y-z plane) of the coating layer 826 along with the carrier layer 828 that has been peeled off from the mold 820. As shown, a plurality of grooves (e.g., grooves 814-1, 814-2) is formed at the coating layer 826. In an exemplary embodiment, the coating layer 826 and the carrier layer 828 together serves as the third layer 810. In another exemplary embodiment, the coating layer 826 alone serves as the third layer 810.

Block 532. Referring to block 532 of FIG. 5C, in some embodiments, the obtaining B) of the second substrate includes B.2) forming the first and second holes by drilling first and second end portions of the first groove through a second side of the third layer that is opposite to the first side of the third layer. For instance, as a non-limiting example, FIG. 8H illustrates a first hole 730-1 and a second hole 730-2 formed by drilling the first end portion 816-1 and the second end portion 818-1 of a first groove 814-1 through a second side of the third layer 810 that is opposite to the first side 812 of the third layer 810. The first and second holes are created for forming electric connections such as vias (e.g., vias 342-1, 344-1 of FIG. 3C).

In some embodiments, the drilling is conducted by exposing a portion of the second side of the third layer to a laser pulse (e.g., a picosecond-short laser pulse), for instance, using an LPKF R4 drilling technique. In some embodiments, the laser pulse has a wavelength of about 515 nanometers (nm). In some embodiments, the drilling is conducted using a laser having a laser power of 0.5 W and a pulse frequency of 150 kilohertz (kHz). Additional details and information regarding the drilling technique is found at LPKF, “Specialist for Material-Friendly Processing: LPKF ProtoLaser R4,” LPKF Laser & Electronics, available at lpkf.com/fileadmin/mediafiles/user_upload/products/pdf/DQ/flyer_lpkf_protolaser_r4_en.pdf (accessed Sep. 27, 2023).

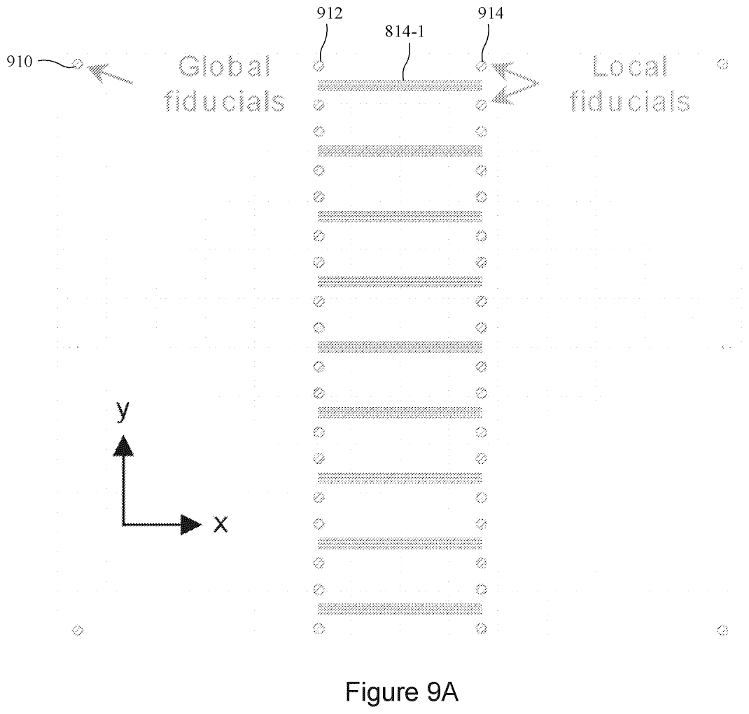

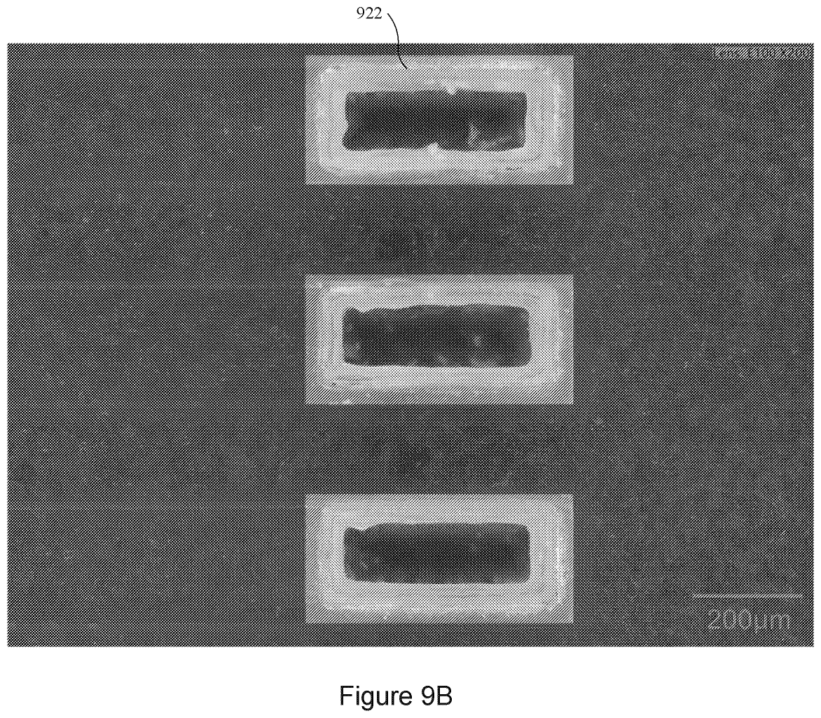

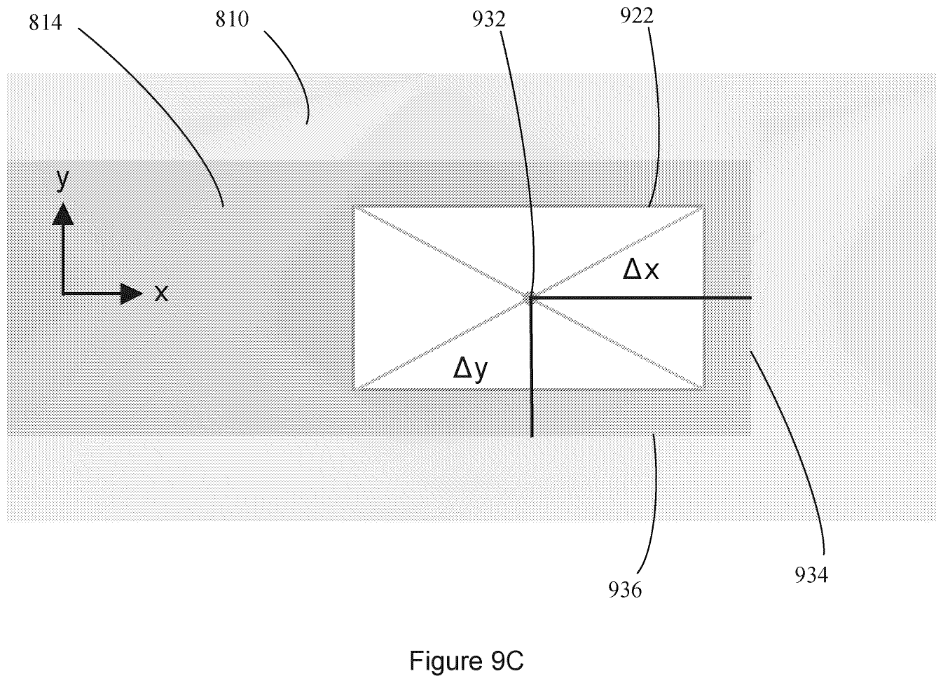

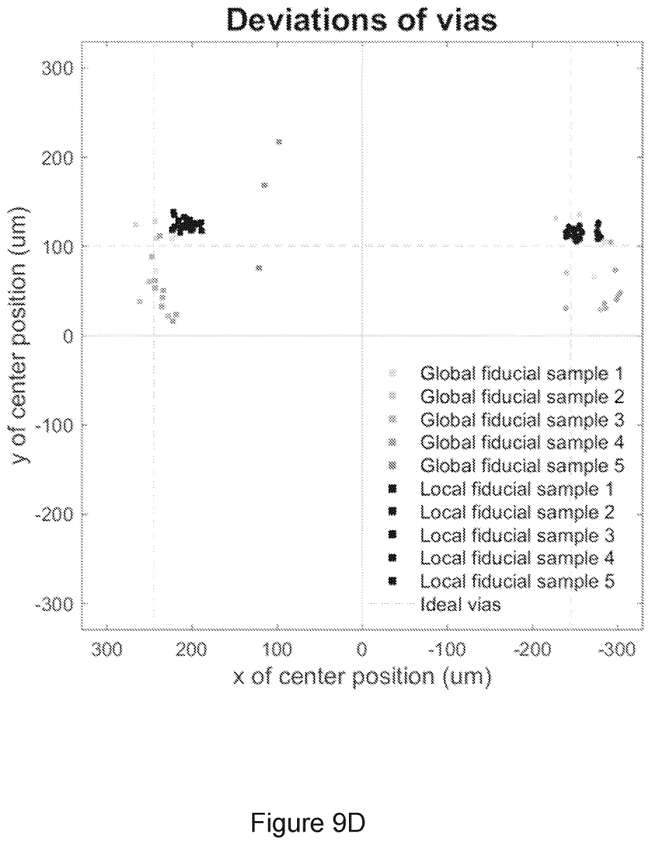

Block 534. Referring to block 534 of FIG. 5C, in some embodiments, the forming B.2) of the first and second holes includes B.2.1) determining a first bounding box corresponding to the first hole and a second bounding box corresponding to the second hole, where the determining of the first bounding box is based at least in part on the one or more global fiducials and the plurality of first local fiducials, and the determining of the second bounding box is based at least in part on the one or more global fiducials and the plurality of second local fiducials. For instance, as a non-limiting example, FIG. 9A illustrates a plurality of global fiducials 910, a plurality of first local fiducials 912 adjacent to a first end portion of a groove (e.g., the groove 814-1), and a plurality of second local fiducials 914 adjacent to a second end portion of a groove (e.g., the groove 814-1). As a non-limiting example, FIG. 9B illustrates exemplary bounding boxes 922 (e.g., the first or second bounding box) that have been determined based at least in part on the one or more global fiducials and the plurality of first or second local fiducials.

Block 536. Referring to block 536 of FIG. 5C, in some embodiments, the forming B.2) of the first and second holes includes B.2.2) determining a first center point of the first bounding box and a second center point of the second bounding box. For instance, as a non-limiting example, FIG. 9C illustrates the determination of a center point 932 of a bounding box 922 (e.g., the first or second bounding box).

Block 538. Referring to block 538 of FIG. 5C, in some embodiments, the forming B.2) of the first and second holes includes B.2.3) measuring one or more first distances from the first center point of the first bounding box to one or more edges of the first end portion of the first groove, and one or more second distances from the second center point of the second bounding box to one or more edges of the second end portion of the first groove. In some embodiments, the one or more first distances include a distance in a first direction measured from the first center point of the first bounding box to a first edge of the first end portion of the first groove and a distance in a second direction measured from the first center point of the first bounding box to a second edge of the first end portion of the first groove. In some embodiments, the one or more second distances include a distance in the first direction measured from the second center point of the second bounding box to a first edge of the second end portion of the first groove and a distance in the second direction measured from the second center point of the first bounding box to a second edge of the second end portion of the first groove. For instance, as a non-limiting example, FIG. 9C illustrates a distance Ax and a distance Ay measured from the center point 932 of the bounding box 922 (e.g., the first or second bounding box) to the edge 934 and the edge 936, respectively, of the end portion of a groove (e.g., the first end portion 816-1 or the second end portion 818-1 of the groove 814-1).

Block 540. Referring to block 540 of FIG. 5D, in some embodiments, the forming B.2) of the first and second holes includes B.2.4) quantifying alignment of the first hole with respect to the first groove based on the one or more first distances and alignment of the second hole with respect to the first groove based on the one or more second distances. For instance, as a non-limiting example, FIG. 9D illustrates exemplary deviations of vias (e.g., vias formed by filling the first and second holes with a liquid metal material) based on the positions of the center points 932 and the distances Δx and Δy measured from the center points to corresponding edges of corresponding grooves.

Block 542. Referring to block 542 of FIG. 5D, in some embodiments, the obtaining B) of the second substrate includes B.3) forming the first channel by placing a fourth layer on the first side of the third layer to seal the first groove formed on the first side of the third layer. For instance, as a non-limiting example, FIGS. 8I and 8J illustrate that a channel (e.g., the channel 720-1) is formed by placing a fourth layer 830 on the first side of the third layer 826 to seal a groove (e.g., the groove 814-1) formed on the first side of the third layer. In some embodiments, the fourth layer is made of a material such as silicon (e.g., inhibited silicon). In some embodiments, the fourth layer is disposed (e.g., overlays) on a fifth layer 832. In some embodiments, the fifth layer is a PET film.

In some embodiments, the fourth layer 830 is cured, for instance, by disposing the stack in an oven for a period of time at a predetermined temperature. In some embodiments, the period of time is from about 5 minutes to about 25 minutes, from about 10 minutes to about 30 minutes, from about 15 minutes to about 35 minutes, or from about 20 minutes to about 40 minutes. In an exemplary embodiment, the period of time is about 20 minutes. In some embodiments, the predetermined temperature is from about 80° C. to about 100° C., about 90° C. to about 110° C., or about 100° C. to about 120° C. In an exemplary embodiment, the predetermined temperature is about 100° C.

In some embodiments, after the fourth layer 830 is cured, the carrier layer 828 (e.g., the single sided dicing tape) is removed from the stack. In some embodiments, after the fourth layer 830 is cured, the third layer 826 and the fourth layer 830 collectively form the second substrate 710.

Block 544. Referring to block 544 of FIG. 5D, in some embodiments, the obtaining B) of the second substrate includes B.4) forming the first port by drilling a hole through the fourth layer. For instance, as a non-limiting example, FIG. 8K illustrates a port (e.g., the port 740-1) formed by drilling a hole through the fourth layer (e.g., the upper portion of the second substrate 710 in FIG. 8K). In some embodiments, the drilling of the port is conducted using a drilling technique, such as the LPKF R4 drilling technique. In some embodiments, the drilling of the port is conducted using the same drilling technique as the drilling of the holes 730.

The port (e.g., the port 740-1) is configured to receive a liquid metal material for filling a corresponding channel (e.g., the channel 720-1) and corresponding holes (e.g., the holes 730-1 and 730-2) with the liquid metal material to form a corresponding interconnect (e.g., the deformable interconnect 340-1).

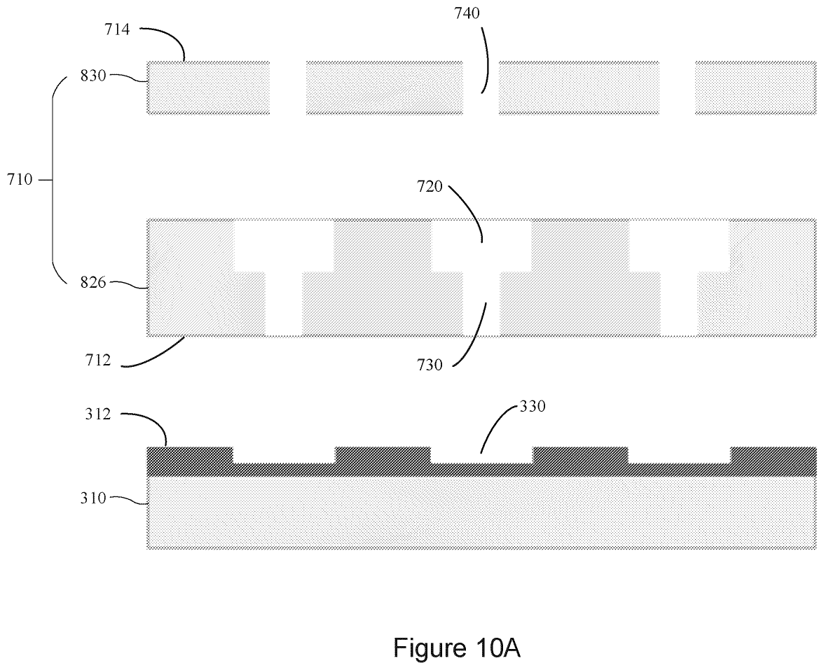

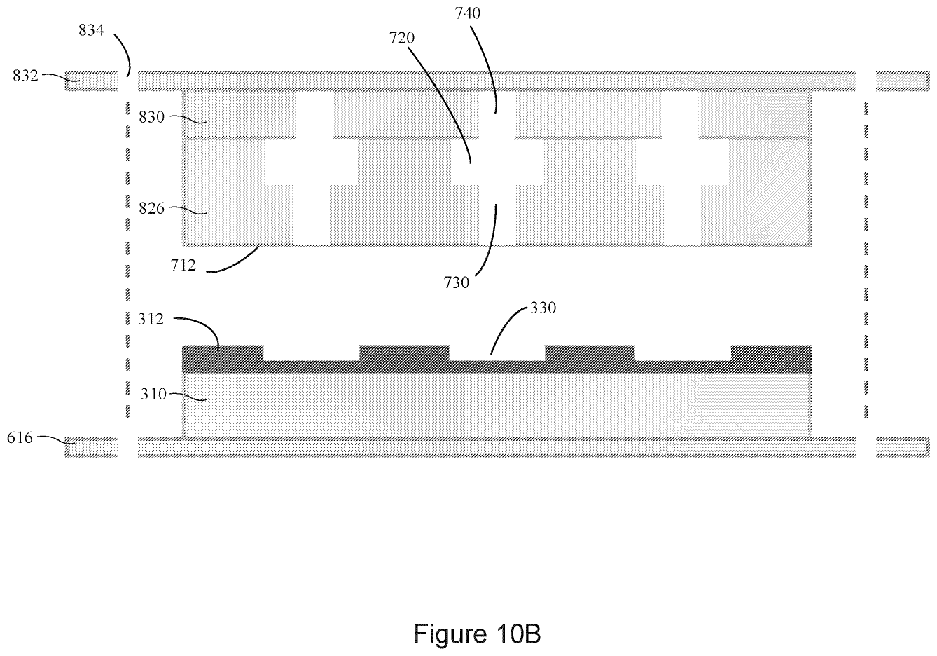

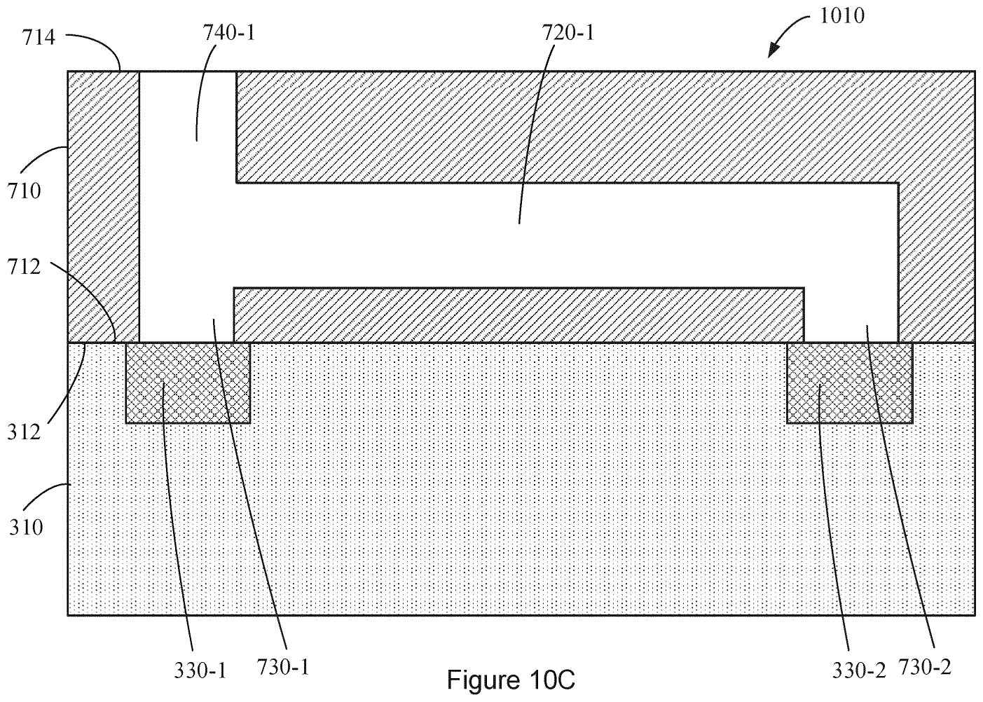

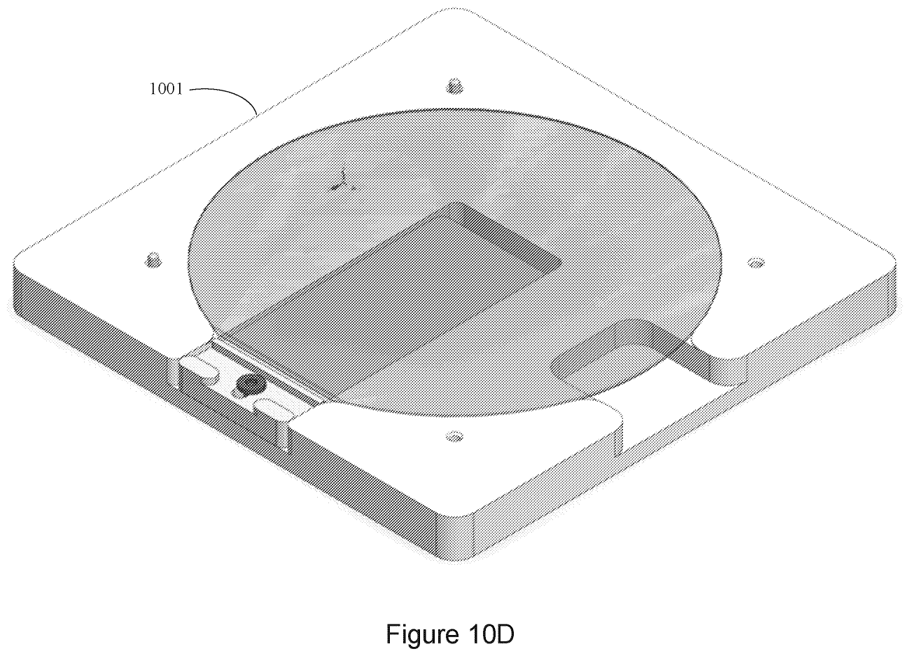

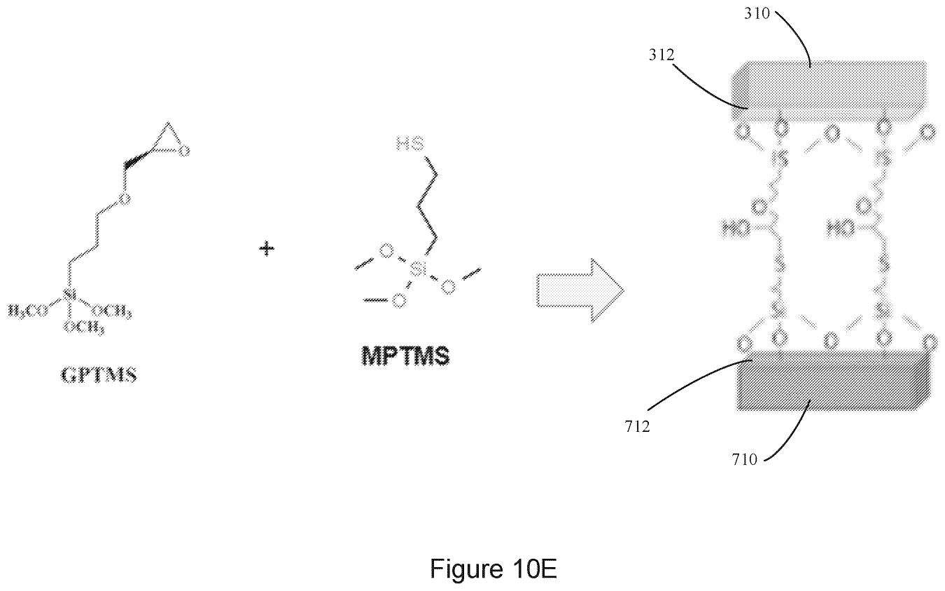

Block 546. Referring to block 546 of FIG. 5D, in some embodiments, the obtaining B) of the second substrate includes B.5) creating one or more posts on the fifth layer for use as a mechanical jig or fixture. For instance, as a non-limiting example, FIG. 8K illustrates the posts 834-1 and 834-2 created on the fifth layer 832 (e.g., a PET film) for use as fixtures in a mechanical jig such as the mechanical jig 1001 illustrated in FIG. 10D.

In some embodiments, as illustrated in FIG. 8L, once the ports and/or posts are formed, the second substrate 710 along with the fifth layer 832 (e.g., the PET film) is transferred to a double-sided dicing tape 836 and/or a wafer 838 (e.g., a glass wafer) using, for instance, the mechanical jig 1001 of FIG. 10D. In some embodiments, the fifth layer 832 is trimmed to remove excessive material such that the fifth layer 832 is shaped and/or sized similarly to the wafer 838.

Block 547. Referring to block 547 of FIG. 5D, in some embodiments, the obtaining B) of the second substrate includes B.6) applying, prior to the forming B.3), a first metal material to form a wetting layer that overlays at least a portion of a wall of the first hole, a portion of a wall of the second hole, a portion of an interior surface of the first groove, or any combination thereof. For instance, in some embodiments, prior to placing the fourth layer 830 on the first side of the third layer 826 to seal the groove 814-1 to form the channel 720-1 as illustrated in FIGS. 8I and 8J, a first metal material is applied to the stack illustrated in FIG. 8H to form a wetting layer that overlays at least a portion of a wall of the hole 730-1, a portion of a wall of the hole 730-2, a portion of an interior surface of the groove 814-1, or any combination thereof. In some embodiments, the wetting layer overlays substantially the entire wall of the first hole, the entire wall of the second hole and the entire interior surface of the first groove.

In some embodiments, the first metal material for the wetting layer is selected to attract the liquid metal material, thereby assisting in the formation of the deformable interconnects 340. Examples of such a first metal material include but are not limited to copper, gold, nickel, silver, platinum, or a combination thereof.

Block 548. Referring to block 548 of FIG. 5E, the method 500 includes C) assembling the first and second substrates to form a stack, where (i) the first surface of the first substrate and the second surface of the second substrate are adjacent to each other, (ii) the first circuit component of the first substrate and the first hole of the second substrate are aligned with each other, and (iii) the second circuit component of the first substrate and the second hole of the second substrate are aligned with each other. For instance, as a non-limiting example, FIGS. 10A-10C illustrate assembling the first substrate 310 and the second substrate 710 (including the cured coating layer 826 and the cured fourth layer 830) to form a stack 1010. In assembling these two substrates, the first surface 312 of the first substrate 310 and the second surface 712 of the second substrate 710 are placed adjacent to each other. Also, at least some circuit components 330 of the first substrate 310 are aligned with some holes 730 of the second substrate 710. In some embodiments, each respective circuit component 330 of the first substrate 310 is aligned with a corresponding hole 730 of the second substrate 710, and/or vice versa. For instance, as a non-limiting example, FIG. 10C illustrates that the first circuit component (e.g., the circuit component 330-1) of the first substrate and the first hole (e.g., the hole 730-1) of the second substrate are aligned with each other, and the second circuit component (e.g., the circuit component 330-2) of the first substrate and the second hole (e.g., the hole 730-2) of the second substrate are aligned with each other.

In some embodiments, the cured coating layer 826 of the second substrate 710 has a thickness (e.g., the vertical dimension of the cured coating layer 826 in FIG. 10A) of from about 20 μm to about 120 μm, from about 50 μm to about 150 μm, or from about 100 μm to about 200 μm. In some embodiments, the cured fourth layer 830 of the second substrate 710 has a thickness (e.g., the vertical dimension of the cured fourth layer 830 in FIG. 10A) of from about 100 μm to about 300 μm, from about 150 μm to about 350 μm, or from about 200 μm to about 400 μm. In some embodiments, the first substrate 310 has a thickness (e.g., the vertical dimension of the first substrate 310 in FIG. 10A) of from about 100 μm to about 300 μm, from about 150 μm to about 350 μm, or from about 200 μm to about 400 μm. In an exemplary embodiment, the cured coating layer 826 of the second substrate 710 has a thickness of about 110 μm, the cured fourth layer 830 of the second substrate 710 has a thickness of about 210 μm, and/or the first substrate 310 has a thickness of about 200 μm. However, the present disclosure is not limited thereto.

In some embodiments, the first and second substrates are assembled, for instance, using a mechanical jig such as the mechanical jig 1001 of FIG. 10D. In some embodiments, to aid the assembling and/or alignment, the first substrate or the second substrate is disposed on a layer (e.g., a PET film) having one or more fixtures (e.g., the post 834). For instance, as a non-limiting example, FIG. 10B illustrates that the first substrate is disposed on the layer 616 and the second substrate is disposed on the layer 832. The layer 616 and the layer 832 can be but do not have to be the same.

Block 550. Referring to block 550 of FIG. 5E, in some embodiments, the assembling C) of the first and second substrates includes C.1) exposing, optionally, the first substrate to a second plasma at a second wattage for a fourth period of time. For instance, in some embodiments, prior to creating the stack 1010, the first substrate 310 or a portion of it (e.g., a layer or a surface) is exposed to a second plasma at a second wattage for a fourth period of time, for instance, using a plasma oven mechanism configured to expel the second plasma at the second wattage. In some embodiments, the second wattage is from about 100 W to about 250 W, or from about 150 W to about 300 W. In some embodiments, the second wattage is from about 150 W to about 250 W. In an exemplary embodiment, the second wattage is about 200 W. In some embodiments, the fourth period of time is from about 10 seconds to about 5 minutes, or from about 1 minute to about 10 minutes. In some embodiments, the fourth period of time is from about 2 minutes to about 4 minutes. In an exemplary embodiment, the fourth period of time is about 3 minutes. In some embodiments, the plasma includes oxygen (O2). In an exemplary embodiment, the first substrate 310 is exposed to the plasma including O2 at about 200 W for about 3 minutes.

Block 552. Referring to block 552 of FIG. 5E, in some embodiments, the assembling C) of the first and second substrates includes C.2) salinizing, optionally, the first substrate to improve a surface functionality of the first surface of the first substrate. For instance, in some embodiments, prior to creating the stack 1010, the first substrate 310 or a portion of it (e.g., a layer or a surface) is salinized to improve a surface functionality of the first surface 312 of the first substrate. In some embodiments, salinization is conducted by submerging the first substrate 310 or a portion of it (e.g., a layer or a surface) in a solution for a period of time. In some embodiments, the solution includes (3-mercaptopropyl) trimethoxysilane (MPTMS) as illustrated in FIG. 10E. In some embodiments, the solution includes about 1% concentration of MPTMS. In some embodiments, the first substrate 310 or a portion of it (e.g., a layer or a surface) is submerged in a solution for about several minutes to about several hours. In some embodiments, the first substrate 310 or a portion of it (e.g., a layer or a surface) is submerged in a solution for about 0.5 hours to about 1.5 hours. In an exemplary embodiment, the first substrate 310 or a portion of it (e.g., a layer or a surface) is submerged in a solution for about an hour.

Block 554. Referring to block 554 of FIG. 5E, in some embodiments, the assembling C) of the first and second substrates includes C.3) exposing, optionally, the second substrate to a third plasma at a third wattage for a fifth period of time. For instance, in some embodiments, prior to creating the stack 1010, the second substrate 710 or a portion of it (e.g., a layer or a surface) is exposed to a third plasma at a third wattage for a fifth period of time, for instance, using a plasma oven mechanism configured to expel the third plasma at the third wattage. In some embodiments, the third wattage is from about 10 W to about 75 W, from about 25 W to about 75 W, or from about 25 W to about 100 W. In an exemplary embodiment, the second wattage is about 50 W. In some embodiments, the fifth period of time is from about 10 seconds to 2 minutes, or from about 30 seconds to about 5 minutes. In an exemplary embodiment, the fifth period of time is from about 0.5 minutes to about 1.5 minutes, or about 1 minute. In some embodiments, the plasma includes oxygen (O2). In an exemplary embodiment, the second substrate 710 is exposed to the plasma including O2 at about 50 W for about 1 minute.

Block 556. Referring to block 556 of FIG. 5E, in some embodiments, the assembling C) of the first and second substrates includes C.4) salinizing, optionally, the second substrate to improve a surface functionality of the second surface of the second substrate. For instance, in some embodiments, prior to creating the stack 1010, the second substrate 710 or a portion of it (e.g., a layer or a surface) is salinized to improve a surface functionality of the second surface 712 of the second substrate. In some embodiments, salinization is conducted by submerging the second substrate 710 or a portion of it (e.g., a layer or a surface) in a solution for a period of time. In some embodiments, the solution includes (3-mercaptopropyl) trimethoxysilane (MPTMS) as illustrated in FIG. 10E. In some embodiments, the solution includes about between a 0.5% and 3% concentration of (3-Glycidyloxypropyl)trimethoxysilane (GPTMS). In some embodiments, the second substrate 710 or a portion of it (e.g., a layer or a surface) is submerged in a solution for about several minutes to about several hours. In an exemplary embodiment, the second substrate 710 or a portion of it (e.g., a layer or a surface) is submerged in a solution for about 20 minutes to about 60 minutes, or about 40 minutes.

Block 558. Referring to block 558 of FIG. 5E, in some embodiments, the assembling C) of the first and second substrates includes C.5) aligning the first and second substrates with each other. For instance, in some embodiments, after the first and second substrates, the salinized first substrate and the salinized second substrate are disposed on the mechanical jig 1001 of FIG. 10D, which aligns the salinized first substrate and the salinized second substrate so that at least some circuit components 330 of the first substrate 310 are aligned with some holes 730 of the second substrate 710 as illustrated in FIGS. 10A-10C.

Block 559. Referring to block 559 of FIG. 5E, in some embodiments, the assembling C) of the first and second substrates includes C.6) bonding the first and second substrates with each other. For instance, as a non-limiting example, FIG. 10E illustrates the salinized first surface 312 of the first substrate and the salinized second surface 712 of the second substrate are bonded together by chemical reactions.

In some embodiments, the bonding of the first substrate 310 and the second substrate 710 is performed by exposing the first and second substrates to a pressure and a temperature for a period of time, for instance, using a pressure pot. In some embodiments, the pressure is from about 40 pounds per square inch (psi) to about 80 psi. In an exemplary embodiment, the pressure is about 60 psi. In some embodiments, the temperature is from about 60° C. to about 100° C. In an exemplary embodiment, the temperature is about 80° C. In some embodiments, the time period that the first and second substrates are exposed to the pressure and/or temperature is from about 12 hours to about 36 hours. In an exemplary embodiment, the time period that the first and second substrates are exposed to the pressure and/or temperature is about 24 hours.

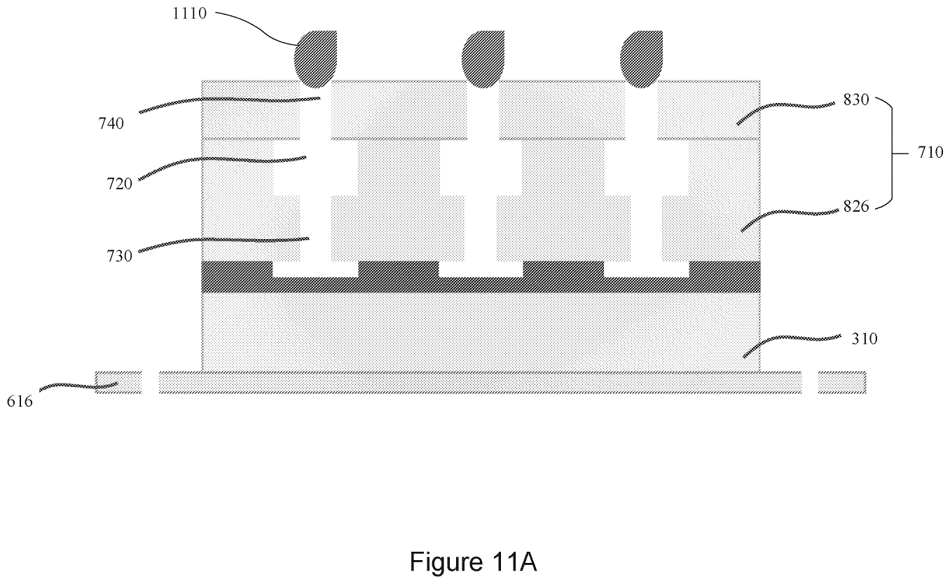

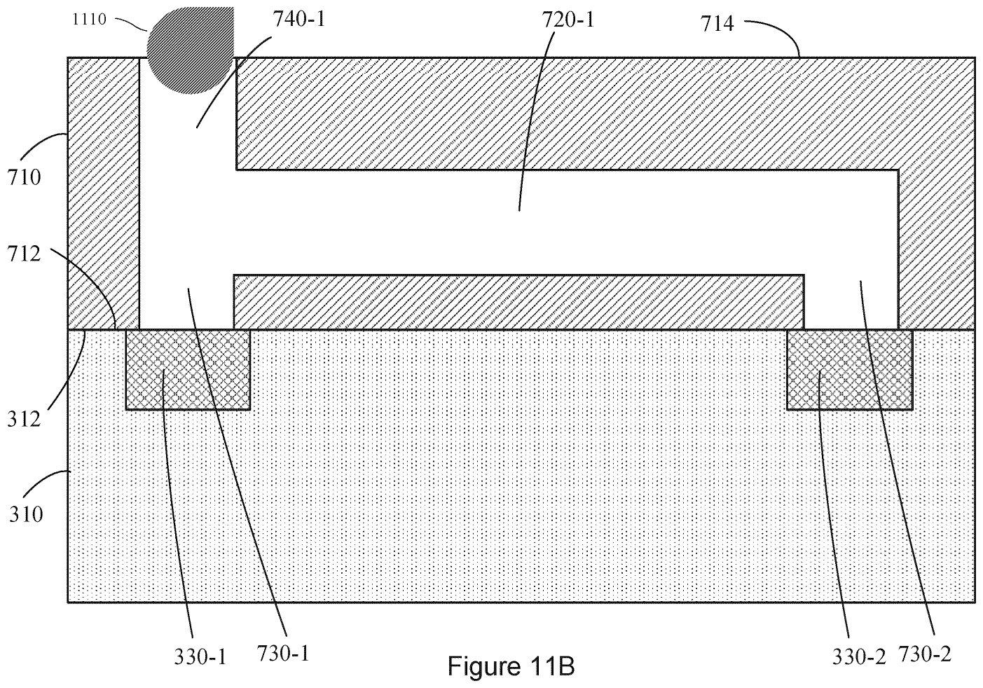

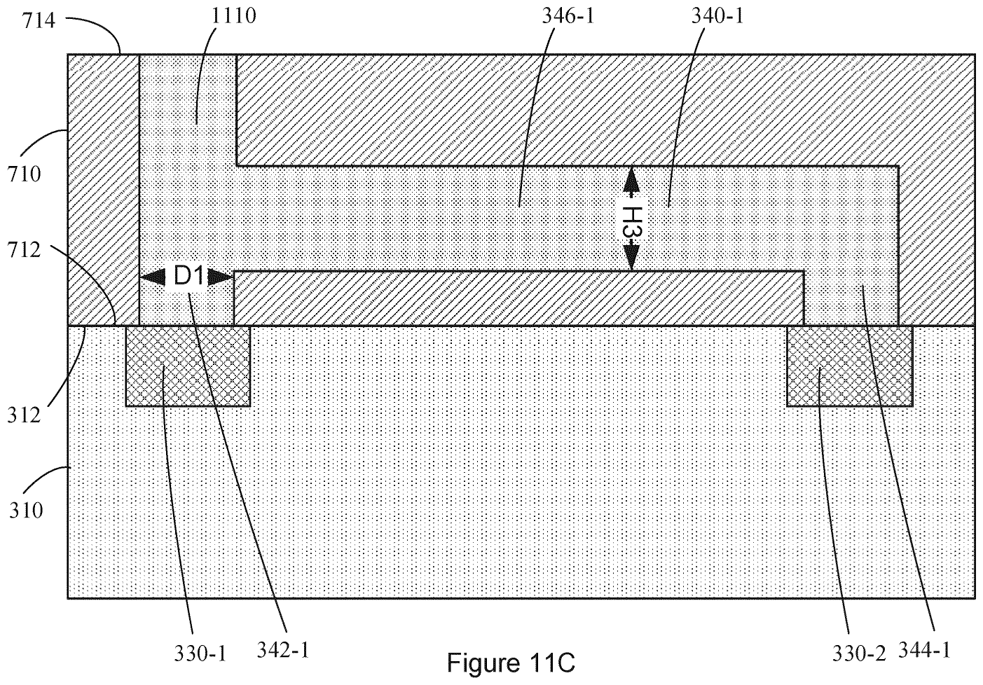

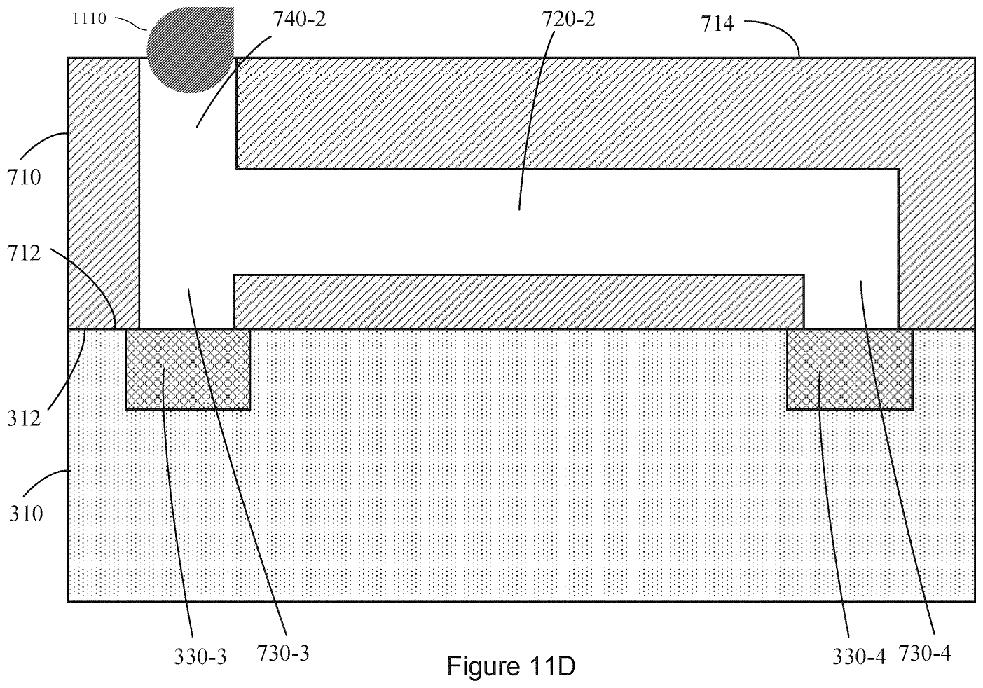

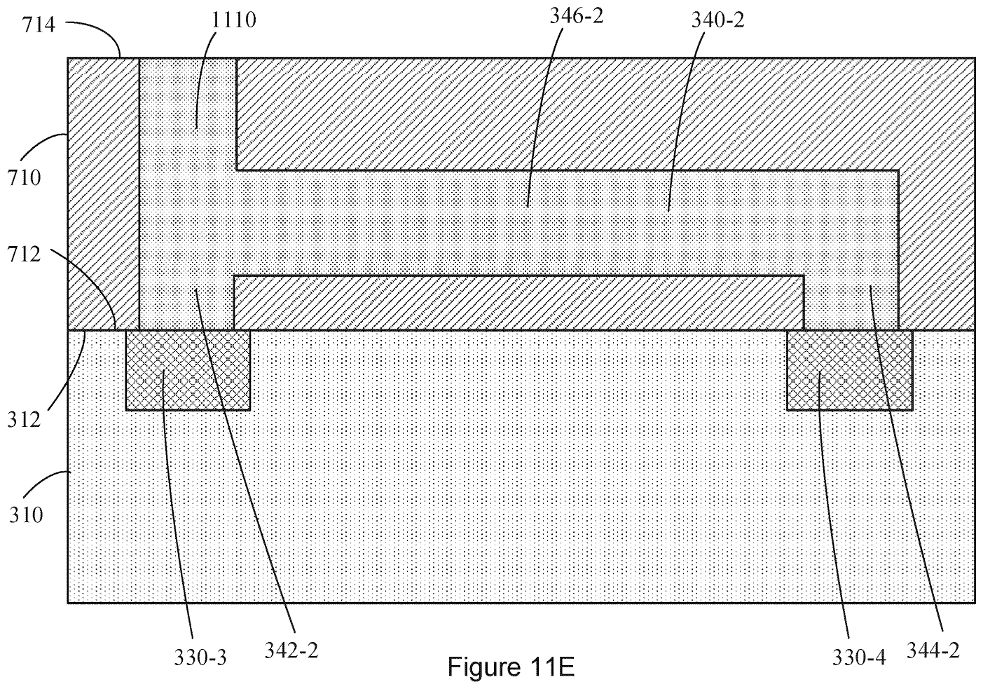

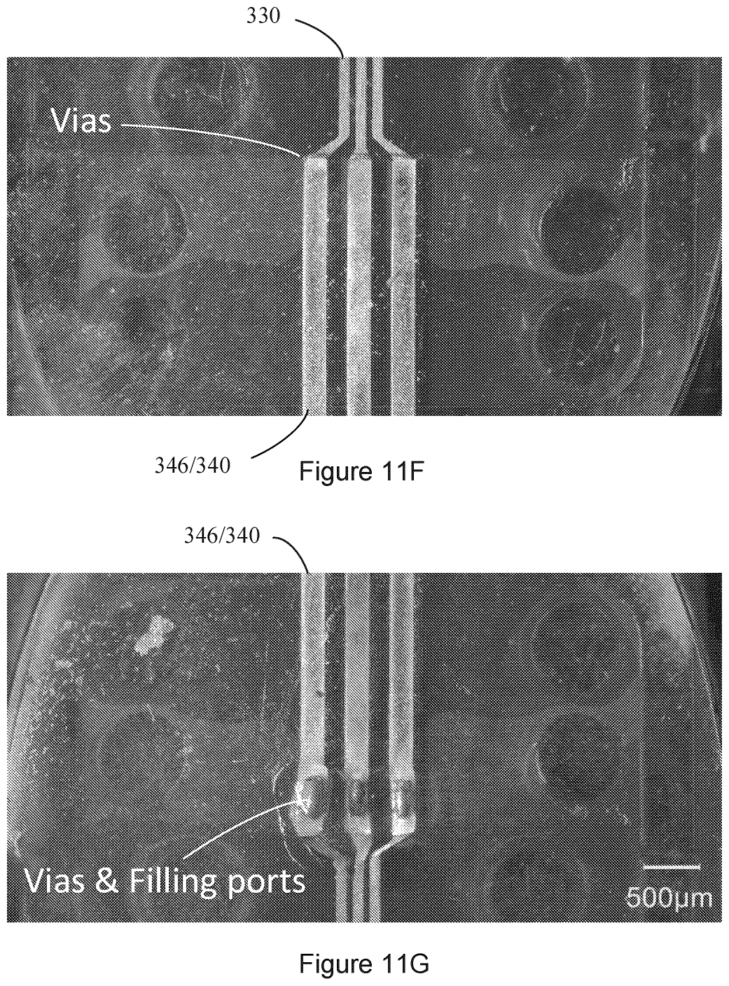

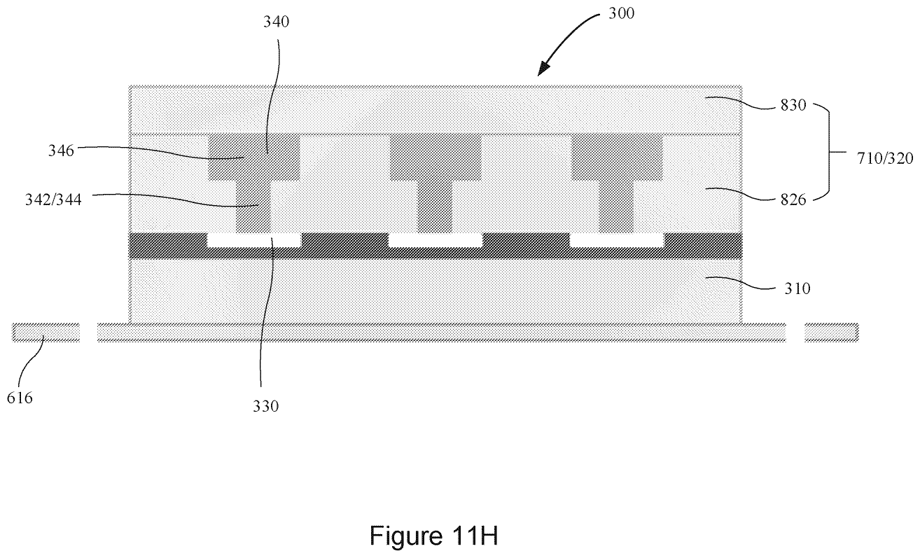

Block 560. Referring to block 560 of FIG. 5F, the method 500 includes D) filling, through the plurality of ports of the second substrate, the plurality of channels and the plurality of holes with a liquid metal material, thereby producing a plurality of deformable interconnects in the stack, where (i) the plurality of deformable interconnects includes a first deformable interconnect produced by filling, through the first port of the second substrate, the first hole, the second hole and the first channel of the second substrate with the liquid metal material, and (ii) the first deformable interconnect electrically connects the first and second circuit components. For instance, as a non-limiting example, FIGS. 11A-11E illustrate filling, through the plurality of ports 740 of the second substrate 710, the plurality of channels 720 and the plurality of holes 730 with a liquid metal material 1110, thereby producing a plurality of deformable interconnects 340 in the stack. In some embodiments, the liquid metal material filled in a hole 730 is referred herein as a via, and the liquid metal material filled in a channel 720 is referred herein as a trace.

Referring in particular to FIGS. 11B and 11C, in some embodiments, a first deformable interconnect (e.g., the deformable interconnect 340-1) is produced by filling, through the first port (e.g., the port 740-1) of the second substrate 710, the first hole (e.g., the hole 730-1), the second hole (e.g., the hole 730-2) and the first channel (e.g., the channel 720-1) of the second substrate 710 with the liquid metal material 1110. The liquid metal material 1110 filled at least partially the hole 730-1 and creates a first portion 342-1 (e.g., a first via) of the deformable interconnect 340-1, which is in contact with (e.g., electrically connected with) a first circuit component (e.g., the circuit component 330-1). The liquid metal material 1110 filled at least partially the hole 730-2 and creates a second portion 344-1 (e.g., a second via) of the deformable interconnect 340-1, which is in contact with a second circuit component (e.g., the circuit component 330-2). The liquid metal material 1110 filled at least partially the channel 720-1 and creates a third portion 346-1 (e.g., a trace) of the deformable interconnect 340-1. As such, the produced deformable interconnect 340-1 electrically connects the circuit component 330-1 and the second circuit component 330-2.

Referring in particular to FIGS. 11D and 11E, in some embodiments, the plurality of circuit components further includes a third circuit component (e.g., the circuit component 330-3) and a fourth circuit component (e.g., the circuit component 330-4) separated from the third circuit component. The plurality of channels further includes a second channel (e.g., the channel 720-2). The plurality of holes includes a third hole (e.g., the hole 730-3) in fluid communication with a first end portion of the second channel and a fourth hole (e.g., the hole 730-4) in fluid communication with a second end portion of the second channel. The plurality of ports further includes a second port (e.g., the port 740-2) in fluid communication with the third hole, the fourth hole, and the second channel. In some such embodiments, the assembling C) produces the stack, in which (i) the third circuit component of the first substrate and the third hole of the second substrate are aligned with each other, and (ii) the fourth circuit component of the first substrate and the fourth hole of the second substrate are aligned with each other. The filling D) produces the plurality of deformable interconnects in the stack, in which (i) the plurality of deformable interconnects further includes a second deformable interconnect produced by filling, through the second port of the second substrate, the third hole, the fourth hole and the second channel of the second substrate with the liquid metal material, and (ii) the second deformable interconnect electrically connects the third and fourth circuit components. For instance, the liquid metal material 1110 filled at least partially the hole 730-3 and creates a first portion 342-2 (e.g., a first via) of the deformable interconnect 340-2, which is in contact with (e.g., electrically connected with) a third circuit component (e.g., the circuit component 330-3). The liquid metal material 1110 filled at least partially the hole 730-4 and creates a second portion 344-2 (e.g., a second via) of the deformable interconnect 340-2, which is in contact with a fourth circuit component (e.g., the circuit component 330-4). The liquid metal material 1110 filled at least partially the channel 720-2 and creates a third portion 346-2 (e.g., a trace) of the deformable interconnect 340-2. As such, the produced deformable interconnect 340-2 electrically connects the circuit component 330-3 and the second circuit component 330-4.

The filling of channels and holes with a liquid metal material through ports to produce deformable interconnects in the stack is also shown in FIGS. 11F and 11G, which are images of portions of a stack made by the method of the present disclosure. Specifically, FIG. 11F is an image showing a portion of the stack adjacent to some vias, and FIG. 11G is an image showing a portion of the stack adjacent to some ports (which has been filled with the liquid metal material) with some vias below the ports.

The liquid metal material 1110 can be of any suitable liquid metal material, including but not limited to those disclosed herein. For instance, in some embodiments, the liquid metal material includes a gallium-based low-melting-point alloy. In an exemplary embodiment, the gallium-based low-melting-point alloy is gallium-indium eutectic (EGaIn).

In some embodiments, a hole (e.g., the hole 730-1, 730-2, 730-3, or 730-4) or a channel (e.g., the channel 720-1 or 720-2) is filled substantially completely by the liquid metal material, e.g., 90% or more of its volume is being filled by the liquid metal material. In some embodiments, only a percentage of the hole or the channel is filled by the liquid metal material. The percentage of a hole or a channel filled by the liquid metal material may be at least about 50%, at least about 60%, at least about 70%, or at least about 80% of its volume.

In some embodiments, a via (e.g., the via 342-1, 344-1) has a nominal diameter (e.g., “D1” in FIG. 11C) that is less than about 500 μm, less than about 450 μm, less than about 400 μm, less than about 350 μm, less than about 300 μm, less than about 250 μm, less than about 200 μm, less than about 150 μm, less than about 100 μm, or less than about 50 μm. In some embodiments, the nominal diameter of a via is at least 1 μm, at least 5 μm, at least 10 μm, at least 20 μm, at least 30 μm, at least 40 μm, or at least 50 μm. In some embodiments, a trace (e.g., 346-1) has a nominal thickness (e.g., “H3” in FIG. 11C) that is less than about 500 μm, less than about 450 μm, less than about 400 μm, less than about 350 μm, less than about 300 μm, less than about 250 μm, less than about 200 μm, less than about 150 μm, less than about 100 μm, or less than about 50 μm. In some embodiments, the thickness of a trace is at least 1 μm, at least 5 μm, at least 10 μm, at least 20 μm, at least 30 μm, at least 40 μm, or at least 50 μm.

In some embodiments, a deformable interconnect (e.g., the deformable interconnect 340-1 or 340-2) is flexible, bendable, and/or stretchable. In some embodiments, the deformable interconnect has a stretchability of at least 25% (e.g., the length or width of the deformable interconnect can be stretched to 1.25 times its original length or width), at least 50%, at least 75%, or at least 100%. In some embodiments, the deformable interconnect is free of degradation in conductivity when the first and second substrates are bent around a cylinder that has a radius of between 2 cm and 10 cm for a period of time between 10 seconds and 5 minutes and then released.

In some embodiments, deformable interconnects in at least a subset of the plurality of deformable interconnects are formed substantially concurrently. For instance, in some embodiments, the second deformable interconnect (e.g., the deformable interconnect 340-2) is formed substantially concurrently as the first deformable interconnect (e.g., the deformable interconnect 340-1). In some embodiments, one or more deformable interconnects in the plurality of deformable interconnects are formed sequentially.

In some embodiments, deformable interconnects in at least a subset of the plurality of deformable interconnects have a same dimension (e.g., length, width, height, diameter, etc.). For instance, in an embodiment, the second deformable interconnect (e.g., the deformable interconnect 340-2) has a dimension (e.g., length) substantially the same as the first deformable interconnect (e.g., the deformable interconnect 340-1). In some embodiments, deformable interconnects in at least a subset of the plurality of deformable interconnects have a same dimension or have different dimensions. For instance, in an embodiment, the second deformable interconnect has a dimension (e.g., width) different than the first deformable interconnect.

Block 562. Referring to block 562 of FIG. 5F, in some embodiments, the filling D) of the method 500 includes D.1) placing a droplet of the liquid metal material on top of the first port of the second substrate. For instance, as a non-limiting example, FIG. 11B illustrates a droplet of the liquid metal material 1110 placed on top of the port 740-1 of the second substrate 710. As another non-limiting example, FIG. 11D illustrates a droplet of the liquid metal material 1110 placed on top of the port 740-2 of the second substrate 710. As a further non-limiting example, FIG. 11A illustrates a droplet of the liquid metal material 1110 placed on top of each port in the plurality of ports 740 of the second substrate 710.

Blocks 564-568. Referring to blocks 564-568 of FIG. 5F, in some embodiments, the filling D) of the method 500 includes D.2) degassing the first hole, the second hole, and the first channel of the second substrate to allow the liquid metal material to fill the first hole, the second hole, and the first channel. For instance, in some embodiments, the degassing D.2) includes D.2.1) placing the assembled first and second substrates with the droplet of the liquid metal material on top of the first port of the second substrate in a chamber at a second pressure that is below about 1 psi for a ninth period of time, thereby removing gas from the first hole, the second hole, and the first channel of the second substrate. In some embodiments, the chamber is a vacuum chamber. In some embodiments, the second pressure is less than about 0.5 psi, less than about 0.4 psi, less than about 0.3 psi, less than about 0.2 psi, less than about 0.1 psi, less than about 0.05 psi, or less than 0.01 psi. In some embodiments, the ninth period of time is from about several minutes or several hours. In some embodiments, the ninth period of time is about 10 minutes to about 40 minutes, about 20 minutes to about 50 minutes, or about 30 minutes to about 60 minutes.

The degassing D.2) also includes D.2.2) exposing, subsequent to the placing D.2.1), the assembled first and second substrates with the droplet of the liquid metal material on top of the first port of the second substrate to a third pressure that is higher than the second pressure, thereby pushing the liquid metal material to fill the first hole, the second hole, and the first channel of the second substrate. In some embodiments, the third pressure is about 1 psi.

In some embodiments, the assembled first and second substrates with the droplet of the liquid metal material on top of the first port of the second substrate is placed in a vacuum chamber (e.g., a chamber with a pressure less than 0.1 psi, 0.05 psi, or 0.01 psi). After about 20 minutes, gas is removed from the first hole, the second hole, and the first channel of the second substrate. The assembled first and second substrates with the droplet of the liquid metal material on top of the first port of the second substrate are then exposed to an ambient pressure (e.g., about 1 psi), for instance, by opening the vacuum chamber to the environment.

Blocks 570-572. Referring to blocks 570-572 of FIG. 5G, in some embodiments, the filling D) of the method 500 includes D.3) cleaning, optionally, excess liquid metal material, and/or D.4) sealing, optionally, the first port. For instance, as a non-limiting example, FIG. 11H illustrates excess liquid metal material, if any, cleaned (e.g., removed from the stack) and the ports are sealed. In some embodiments, the ports are sealed with silicone (e.g., Bluesil™ from Elkem Silicones), for instance, using a dispensing flat tip (e.g., a 200 μm dispensing flat tip). This produces a deformable electronic device 300 having the first substrate 310, the second substrate 710 (which is now equivalent to the second substrate 320), a plurality of circuit components 330 and a plurality of deformable interconnects 340, in which the plurality of deformable interconnects electrically connects at least some circuit components in the plurality of circuit components to form one or more circuits.

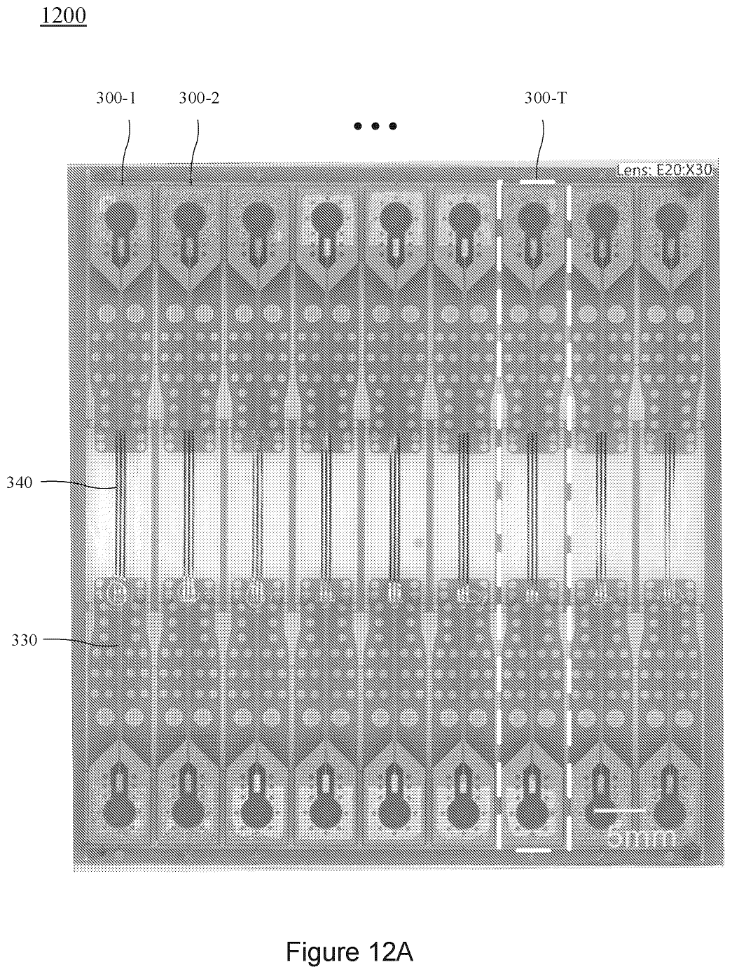

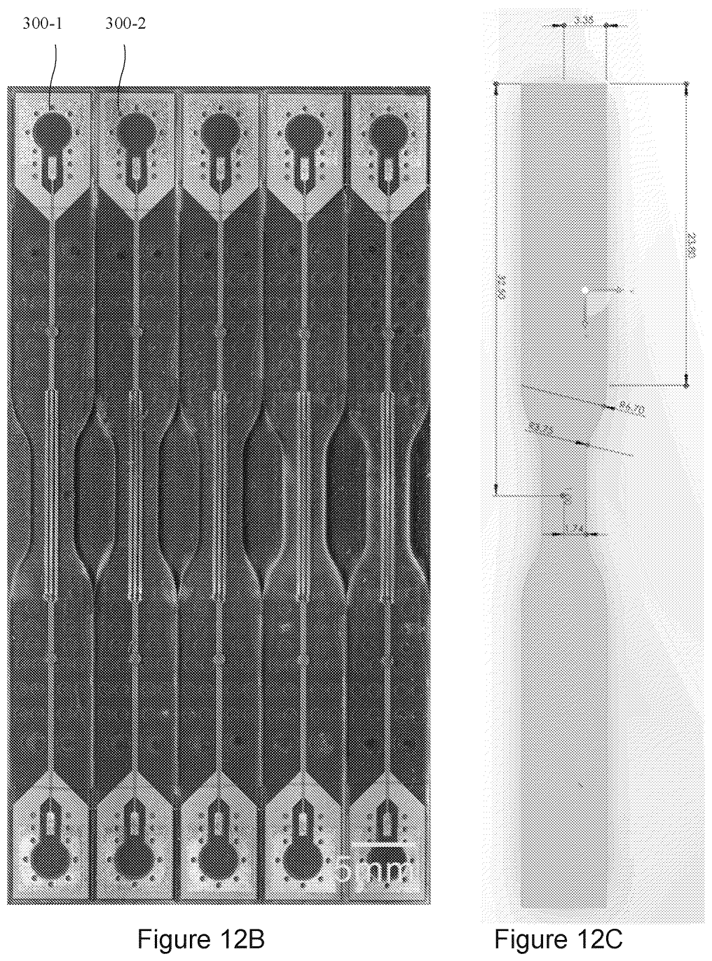

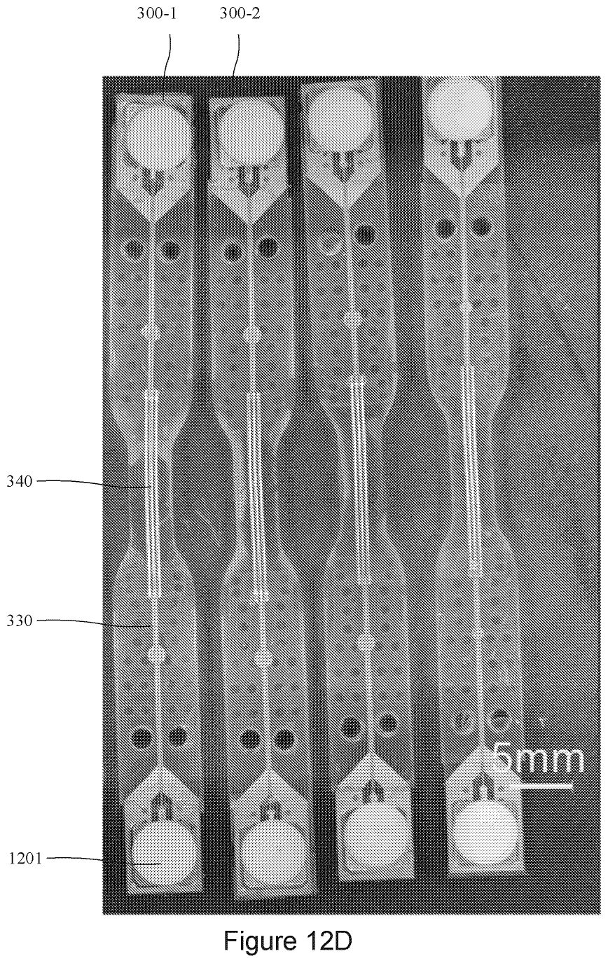

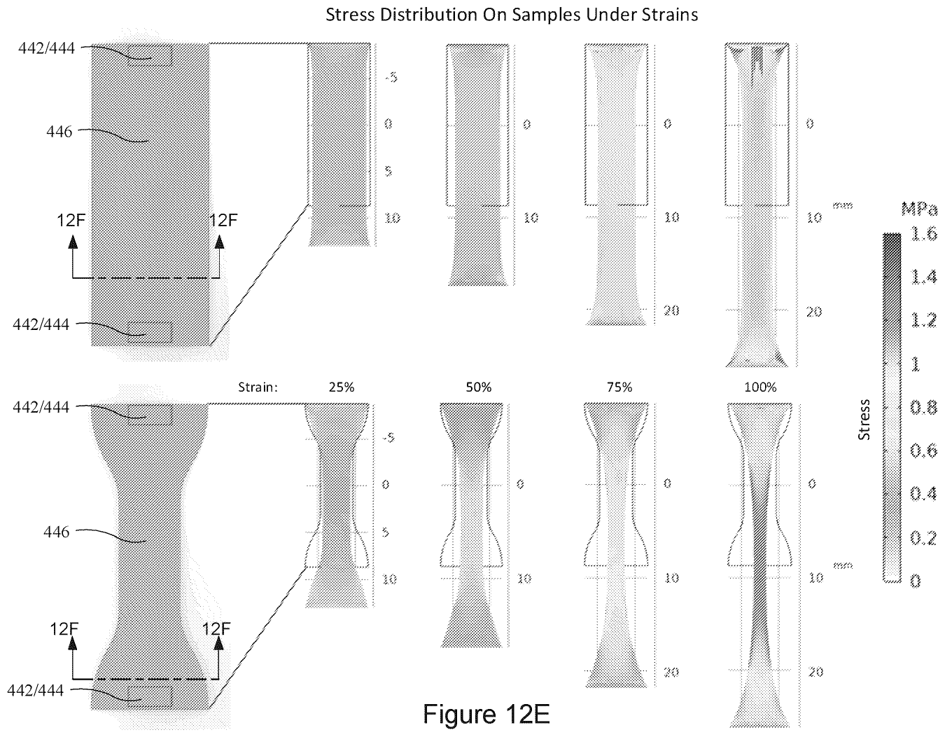

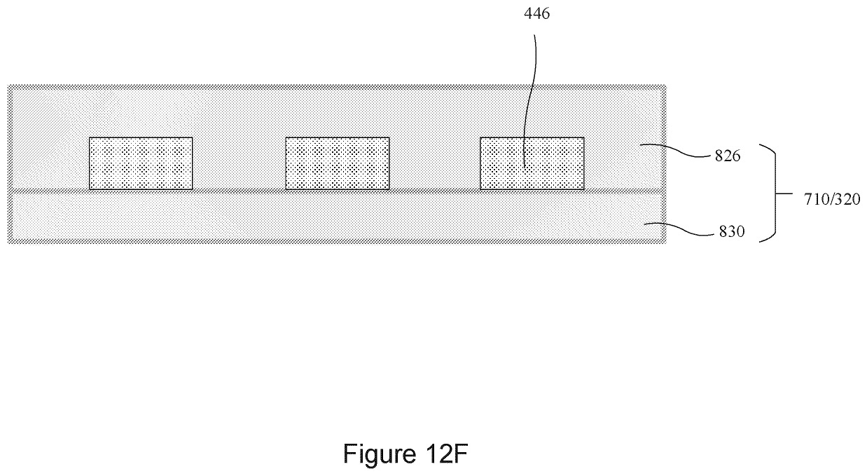

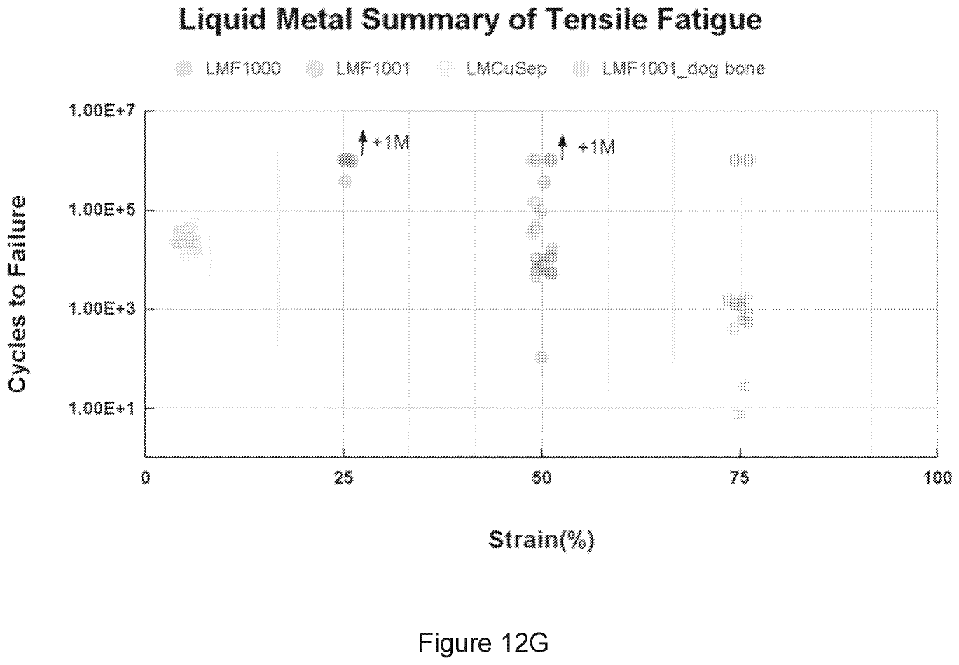

Block 574. Referring to block 574 of FIG. 5G, in some embodiments, the method 500 includes E) adding one or more connectors to the stack, where each connector is electrically connected to a circuit component in the plurality of circuit components, a deformable interconnect in the one or more interconnects, or both. For instance, as a non-limiting example, FIG. 12D illustrates that one or more connectors 1201 are added to the stack, with each connector electrically connected to a circuit component 330 and/or a deformable interconnect 340. In some embodiments, the one or more connectors are added to the stack by low temperature soldering.

### 5. TEST EXAMPLES

FIG. 12A illustrates an exemplary stack 1200 made by the method 500 in accordance with some embodiments of the present disclosure. The stack 1200 includes a plurality of deformable electronic devices (e.g., devices 300-1, 300-2, . . . ). To make test samples, some of the deformable electronic devices (e.g., devices 300-1, 300-2) are cut into a dog-bone shape as shown in FIGS. 12B-12D. Some of the deformable electronic devices (e.g., devices 300-T) are cut into a rectangular shape as indicated by the dash line in FIG. 12A.

FIG. 12E presents simulation results showing the effects of sample shapes (e.g., rectangular shape vs. dog-bone shape) on stress distribution under various strains (e.g., 25%, 50%, 75% and 100% strains). FIG. 12F shows a cross-sectional view taken along the line 12F-12F in FIG. 12E, where the layer 826 of about 200 μm thick and the layer 830 of about 100 μm thick are made of silicone. As can be seen, the dog-bone shape helps reduce mechanical stress around vias (e.g., vias 442, 444).

FIG. 12G presents testing results showing the effects of liquid metal materials (e.g., deformable interconnects of different samples made of different liquid metal materials) and sample shapes (e.g., rectangular shape vs. dog-bone shape) on a tensile fatigue of test samples. The test samples include (i) samples LMF1000 with deformable interconnects made of a first liquid metal material, (ii) samples LMF1001 with deformable interconnects made of a second liquid metal material, (iii) samples LM CuSep with deformable interconnects made of a third liquid metal material, and (iv) samples LMF1001_dog bone with deformable interconnects made of the second liquid metal material (the same as LMF1001) but in a dog-bone shape shown in FIGS. 12B-12D.

The test samples are subject to various strain cycles (e.g., 5% strain cycle, 25% strain cycle, 50% strain cycle, and 75% strain cycle). The number of cycles to failure are recorded and presented in the chart. As can be seen, both liquid metal materials and sample shapes can affect the tensile failure of test samples. For instance, the number of cycles to failure of samples LMF1001 and LMF1001_dog bone are generally higher than those of LMF1000 and samples LM CuSep, indicating that the second liquid metal material may be better for making deformable interconnects. Also, the numbers of cycles to failure of samples LMF1001_dog bone are generally higher than those of samples LMF1001, indicating that a deformable electronic device may achieve higher performance if it (or a portion of it adjacent to deformable interconnects) is in the dog-bone shape rather than in the rectangular shape.

### Clauses

According to some aspects, the subject technology is directed to a method for fabricating a deformable electronic device, the method includes: A) obtaining a first substrate including: a first surface; and a number of circuit components disposed at the first surface, wherein the circuit components includes a first circuit component and a second circuit component separated from the first circuit component; B) obtaining a second substrate including: a second surface; a third surface; several channels disposed between the second and third surfaces, wherein the channels includes a first channel; a number of holes open to the second surface, wherein the holes includes a first hole in fluid communication with a first end portion of the first channel, and a second hole in fluid communication with a second end portion of the first channel; and several ports open to the third surface, wherein the ports includes a first port in fluid communication with the first hole, the second hole, and the first channel; C) assembling the first and second substrates to form a stack, wherein: the first surface of the first substrate and the second surface of the second substrate are adjacent to each other; the first circuit component of the first substrate and the first hole of the second substrate are aligned with each other; and the second circuit component of the first substrate and the second hole of the second substrate are aligned with each other; and D) filling, through the ports of the second substrate, the channels and the holes with a liquid metal material, thereby producing a number of deformable interconnects in the stack, wherein: the deformable interconnects includes a first deformable interconnect produced by filling, through the first port of the second substrate, the first hole, the second hole and the first channel of the second substrate with the liquid metal material; and the first deformable interconnect electrically connects the first and second circuit components.

In some embodiments, the first substrate is deformable.

In some embodiments, the first substrate includes a first layer and the circuit components is disposed on a first side of the first layer.

In some embodiments, the first layer includes a polyimide (Pi) film.

In some embodiments, the first layer is laminated on a second layer.

In some embodiments, the second layer includes a polyethylene terephthalate (PET) film.

In some embodiments, the first layer is laminated on the second layer using a double-sided dicing tape.

In some embodiments, the first or second circuit component is a contact pad.

In some embodiments, the liquid metal material includes a gallium-based low-melting-point alloy.

In some embodiments, the gallium-based low-melting-point alloy is gallium-indium eutectic (EGaIn).

In some embodiments, the first hole, the second hole, or the first channel is filled substantially completely by the liquid metal material.

In some embodiments, the liquid metal material filled in the first hole or the second hole forms a via; and the liquid metal material filled in the first channel forms a trace.

In some embodiments, the via has a nominal diameter less than 300 μm; and the trace has a nominal thickness less than 200 μm.

In some embodiments, the first deformable interconnect is stretchable.

In some embodiments, the first deformable interconnect has a stretchability of at least 25%, at least 50%, at least 75%, or at least 100%.

In some embodiments, the first deformable interconnect is free of degradation in conductivity when the first and second substrates are bent around a cylinder that has a radius of between 2 cm and 10 cm for a period of time between 10 seconds and 5 minutes and then released.

In some embodiments, the circuit components further includes a third circuit component and a fourth circuit component separated from the third circuit component; the channels further includes a second channel; the holes includes a third hole in fluid communication with a first end portion of the second channel and a fourth hole in fluid communication with a second end portion of the second channel; the ports further includes a second port in fluid communication with the third hole, the fourth hole, and the second channel; the assembling C) produces the stack, wherein (i) the third circuit component of the first substrate and the third hole of the second substrate are aligned with each other, and (ii) the fourth circuit component of the first substrate and the fourth hole of the second substrate are aligned with each other; and the filling D) produces the deformable interconnects in the stack, wherein (i) the deformable interconnects further includes a second deformable interconnect produced by filling, through the second port of the second substrate, the third hole, the fourth hole and the second channel of the second substrate with the liquid metal material, and (ii) the second deformable interconnect electrically connects the third and fourth circuit components.

In some embodiments, the third hole, the fourth hole, or the second channel is filled substantially completely by the liquid metal material.

In some embodiments, the second deformable interconnect is stretchable.

In some embodiments, the second deformable interconnect has a stretchability of at least 25%, at least 50%, at least 75%, or at least 100%.

In some embodiments, the second deformable interconnect is formed substantially concurrently as the first deformable interconnect.

In some embodiments, the second deformable interconnect has a dimension substantially the same as the first deformable interconnect.

In some embodiments, the second deformable interconnect has a dimension different than the first deformable interconnect.

In some embodiments, the obtaining A) includes: A.1) obtaining a first initial substrate including a first layer with the circuit components disposed on a first side of the first layer; A.2) dehydrating, optionally, the first layer; A.3) cleaning, optionally, the first initial substrate; A.4) salinizing, optionally, the first layer to improve a surface functionality of a second side of the first layer, wherein the second side is opposite to the first side of the first layer; A.5) laminating, optionally, the first initial substrate on a second layer with the second side of the first layer facing the second layer; A.6) applying, optionally, a coating material to at least a portion of the first initial substrate at a first thickness to encapsulate at least the portion of the first initial substrate; and A.7) curing, optionally, the coating material.

In some embodiments, the first layer includes a polyimide (Pi) film.

In some embodiments, the dehydrating A.2) is performed at a first temperature for a first period of time.

In some embodiments, the first temperature is from about 110° C. to about 130° C.; and the first period of time is from about 10 minutes to about 30 minutes. The method of claim 26, wherein the cleaning A.3) includes exposing the first initial substrate to a first plasma at a first wattage for a second period of time.

In some embodiments, the first wattage is from about 200 watt (W) to about 300 W; and the second period of time is from about 10 minutes to about 30 minutes.

In some embodiments, the first plasma includes oxygen (O2) plasma flown at about 12 standard cubic centimeters per minute (SCCM), tetrafluoromethane (CF4) flown at about 3 SCCM, or a combination thereof.

In some embodiments, the salinizing A.4) includes exposing at least the second side of the first layer to a first solution for a third period of time.

In some embodiments, the first solution includes 1% (3-mercaptopropyl) trimethoxysilane (MPTMS); and the third period of time is from about 40 minutes to about 60 minutes.

In some embodiments, the coating material includes silicone; and the first thickness is from about 50 μm to about 150 μm.

In some embodiments, the curing A.7) is performed at a room temperature.

In some embodiments, the obtaining B) includes B.1) obtaining a third layer including a first groove formed on a first side tape of the third layer, wherein the first groove includes a first end and a second end; B.2) forming the first and second holes by drilling first and second end portions of the first groove through a second side of the third layer that is opposite to the first side of the third layer; B.3) forming the first channel by placing a fourth layer on the first side of the third layer to seal the first groove formed on the first side of the third layer; and B.4) forming the first port by drilling a hole through the fourth layer.

In some embodiments, the obtaining B.1) includes B.1.1) obtaining a mold including a first ridge on a first side of the mold for creating the first groove; B.1.2) applying a release layer on the first side of the mold; B.1.3) applying a coating layer on the release layer;

B.1.4) curing, optionally, the coating layer; B.1.5) applying, optionally, a carrier layer on the cured coating layer; and B.1.6) peeling off the coating layer from the mold, thereby producing the third layer with the first groove on the first side of the third layer.

In some embodiments, the mold is an SU-8 master mold.

In some embodiments, the coating layer is applied by blade coating silicone on the release layer.

In some embodiments, the coating layer has a thickness from about 150 μm to about 250 μm.

In some embodiments, the carrier layer is a single-sided dicing tape.

In some embodiments, the third layer further includes one or more global fiducials, a number of first local fiducials adjacent to the first end portion of the first groove, and a number of second local fiducials adjacent to the second end portion of the first groove; and the forming B.2) includes: B.2.1) determining a first bounding box corresponding to the first hole and a second bounding box corresponding to the second hole, wherein the determining of the first bounding box is based at least in part on the one or more global fiducials and the first local fiducials, and the determining of the second bounding box is based at least in part on the one or more global fiducials and the second local fiducials; B.2.2) determining a first center point of the first bounding box and a second center point of the second bounding box; B.2.3) measuring one or more first distances from the first center point of the first bounding box to one or more edges of the first end portion of the first groove, and one or more second distances from the second center point of the second bounding box to one or more edges of the second end portion of the first groove; and B.2.4) quantifying alignment of the first hole with respect to the first groove based on the one or more first distances and alignment of the second hole with respect to the first groove based on the one or more second distances.

In some embodiments, the one or more first distances include a distance in a first direction measured from the first center point of the first bounding box to a first edge of the first end portion of the first groove and a distance in a second direction measured from the first center point of the first bounding box to a second edge of the first end portion of the first groove; and the one or more second distances include a distance in the first direction measured from the second center point of the second bounding box to a first edge of the second end portion of the first groove and a distance in the second direction measured from the second center point of the first bounding box to a second edge of the second end portion of the first groove.

In some embodiments, the forming B.2) or the forming B.4) is performed using a laser.

In some embodiments, the fourth layer overlays on a fifth layer.

In some embodiments, the fourth layer is a silicone layer.

In some embodiments, the fifth layer is a PET film.

In some embodiments, the obtaining B) further includes: B.5) creating one or more posts on the fifth layer for use as a mechanical jig or fixture.

In some embodiments, the obtaining B) further includes: B.6) applying, prior to the forming B.3), at least one of a first metal material to form a wetting layer that overlays at least a portion of a wall of the first hole, a portion of a wall of the second hole, or a portion of an interior surface of the first groove.

In some embodiments, the first metal material includes at least one of copper, gold, nickel, silver, or platinum.

In some embodiments, the assembling C) includes: C.1) exposing, optionally, the first substrate to a second plasma at a second wattage for a fourth period of time; C.2) salinizing, optionally, the first substrate to improve a surface functionality of the first surface of the first substrate; C.3) exposing, optionally, the second substrate to a third plasma at a third wattage for a fifth period of time; C.4) salinizing, optionally, the second substrate to improve a surface functionality of the second surface of the second substrate; C.5) aligning the first and second substrates with each other; and C.6) bonding the first and second substrates with each other.

In some embodiments, the second plasma includes O2 plasma; the second wattage is from about 150 W to about 250 W; and the fourth period of time is from about 2 minutes to about 4 minutes.

In some embodiments, the first substrate is salinized in a 1% MPTMS bath for about a sixth period of time.

In some embodiments, the sixth period of time is from about 0.5 hours to about 1.5 hours.

In some embodiments, the third plasma includes O2 plasma; the third wattage is from about 25 W to about 75 W; and the fifth period of time is from about 0.5 minutes to about 1.5 minutes.

In some embodiments, the second substrate is salinized in a 1% (3-Glycidyloxypropyl)trimethoxysilane (GPTMS) bath for a seventh period of time.

In some embodiments, the seventh period of time is from about 20 minutes to about 60 minutes.

In some embodiments, the first and second substrates are aligned with each other using one or more mechanical jigs or fixtures.

In some embodiments, the first and second substrates are bonded in a pressure pot at a second temperature and a first pressure for an eighth period of time.

In some embodiments, the second temperature is from about 60° C. to about 100° C.; the first pressure is from about 40 pounds per square inch (psi) to about 80 psi; and the eighth period of time is from about 12 hours to about 36 hours.

In some embodiments, the filling D) includes: D.1) placing a droplet of the liquid metal material on top of the first port of the second substrate; D.2) degassing the first hole, the second hole, and the first channel of the second substrate to allow the liquid metal material to fill the first hole, the second hole, and the first channel; D.3) cleaning, optionally, excess liquid metal material; and D.4) sealing, optionally, the first port.

In some embodiments, the degassing D.2) includes: D.2.1) placing the assembled first and second substrates with the droplet of the liquid metal material on top of the first port of the second substrate in a chamber at a second pressure that is below about 1 psi for a ninth period of time, thereby removing gas from the first hole, the second hole, and the first channel of the second substrate; and D.2.2) exposing, subsequent to the placing D.2.1), the assembled first and second substrates with the droplet of the liquid metal material on top of the first port of the second substrate to a third pressure that is higher than the second pressure, thereby pushing the liquid metal material to fill the first hole, the second hole, and the first channel of the second substrate.

In some embodiments, the chamber is a vacuum chamber; and the D.2.2) exposing includes opening the vacuum chamber to expose the assembled first and second substrates with the droplet of the liquid metal material on top of the first port of the second substrate to an ambient pressure.

In some embodiments, the first port is sealed with silicone.

In some embodiments, the method further includes: E) adding one or more connectors to the stack, wherein each connector is electrically connected to a circuit component in the circuit components, a deformable interconnect in the one or more interconnects, or both.

In some embodiments, the adding E) is performed by low temperature soldering.

Some aspect of the subject technology is directed to a deformable electronic device, including: a first substrate including: a first surface; and a number of circuit components disposed at the first surface, wherein the circuit components includes a first circuit component and a second circuit component separated from the first circuit component; and a second substrate bonded with the first substrate and including a number of deformable interconnects made of a liquid metal material, wherein the deformable interconnects includes a first deformable interconnect that electrically connects the first and second circuit components.

In some embodiments, the first deformable interconnect is stretchable.

In some embodiments, the first deformable interconnect is free of degradation in conductivity when the first and second substrates are bent around a cylinder that has a radius of between 2 cm and 10 cm for a period of time between 10 seconds and 5 minutes and then released.

In some embodiments, the second substrate includes a second surface adjacent to the first surface of the first substrate, and a third surface away from the first surface of the first substrate; and the first deformable interconnect includes: a first trace disposed between the second and third surfaces; a first via electrically connecting the first circuit component with a first end portion of the first trace; and a second via electrically connecting the second circuit component with a second end portion of the first trace.

In some embodiments, the circuit components further includes a third circuit component and a fourth circuit component separated from the third circuit component; and the deformable interconnects further includes a second deformable interconnect that electrically connects the third and fourth circuit components.

In some embodiments, the liquid metal material includes a gallium-based low-melting-point alloy.

In some embodiments, the deformable electronic device further includes one or more connectors, each electrically connected to a circuit component in the circuit components, a deformable interconnect in the deformable interconnects, or both.

### References Cited and Alternative Embodiments

All references cited herein are incorporated herein by reference in their entirety and for all purposes to the same extent as if each individual publication or patent or patent application was specifically and individually indicated to be incorporated by reference in its entirety for all purposes.

The present invention can be implemented as a computer program product that includes a computer program mechanism embedded in a non-transitory computer-readable storage medium. For instance, the computer program product could contain instructions for operating the user interfaces described with respect to FIG. 2. These program modules can be stored on a CD-ROM, DVD, magnetic disk storage product, USB key, or any other non-transitory computer-readable data or program storage product.

Many modifications and variations of this invention can be made without departing from its spirit and scope, as will be apparent to those skilled in the art. The specific embodiments described herein are offered by way of example only. The embodiments were chosen and described in order to best explain the principles of the invention and its practical applications, to thereby enable others skilled in the art to best utilize the invention and various embodiments with various modifications as are suited to the particular use contemplated. The invention is to be limited only by the terms of the appended claims, along with the full scope of equivalents to which such claims are entitled.

What is claimed is:

1. A method for fabricating a deformable electronic device, the method comprising:
A) obtaining a first substrate comprising:
a first surface; and
a plurality of circuit components disposed at the first surface, wherein the plurality of circuit components comprises a first circuit component and a second circuit component separated from the first circuit component;
B) obtaining a second substrate comprising:
a second surface;
a third surface;
a plurality of channels disposed between the second and third surfaces, wherein the plurality of channels comprises a first channel;
a plurality of holes open to the second surface, wherein the plurality of holes comprises a first hole in fluid communication with a first end portion of the first channel, and a second hole in fluid communication with a second end portion of the first channel; and
a plurality of ports open to the third surface, wherein the plurality of ports comprises a first port in fluid communication with the first hole, the second hole, and the first channel;
C) assembling the first and second substrates to form a stack, wherein:
the first surface of the first substrate and the second surface of the second substrate are adjacent to each other;
the first circuit component of the first substrate and the first hole of the second substrate are aligned with each other; and
the second circuit component of the first substrate and the second hole of the second substrate are aligned with each other; and
D) filling, through the plurality of ports of the second substrate, the plurality of channels and the plurality of holes with a liquid metal material, thereby producing a plurality of deformable interconnects in the stack, wherein:
the plurality of deformable interconnects comprises a first deformable interconnect produced by filling, through the first port of the second substrate, the first hole, the second hole and the first channel of the second substrate with the liquid metal material; and
the first deformable interconnect electrically connects the first and second circuit components.

2. The method of claim 1, wherein the first substrate is deformable and comprises a first layer and the plurality of circuit components is disposed on a first side of the first layer.

3. The method of claim 2, wherein the first layer comprises a polyimide (Pi) film and is laminated on a second layer, wherein the second layer comprises a polyethylene terephthalate (PET) film, and wherein the first layer is laminated on the second layer using a double-sided dicing tape.

4. The method of claim 1, wherein the first or second circuit component is a contact pad, wherein the liquid metal material comprises a gallium-based low-melting-point alloy including gallium-indium eutectic (EGaIn).

5. The method of claim 1, wherein the first hole, the second hole, or the first channel is filled substantially completely by the liquid metal material, and wherein the liquid metal material filled in the first hole or the second hole forms a via, and the liquid metal material filled in the first channel forms a trace.

6. The method of claim 5, wherein the via has a nominal diameter less than 300 μm; and the trace has a nominal thickness less than 200 μm.

7. The method of claim 1, wherein the first deformable interconnect is stretchable with a stretchability of at least 25%, at least 50%, at least 75%, or at least 100% and is free of degradation in conductivity when the first and second substrates are bent around a cylinder that has a radius of between 2 cm and 10 cm for a period of time between 10 seconds and 5 minutes and then released.

8. The method of claim 1, wherein:
the plurality of circuit components further comprises a third circuit component and a fourth circuit component separated from the third circuit component;
the plurality of channels further comprises a second channel;
the plurality of holes comprises a third hole in fluid communication with a first end portion of the second channel and a fourth hole in fluid communication with a second end portion of the second channel;
the plurality of ports further comprises a second port in fluid communication with the third hole, the fourth hole, and the second channel;
the assembling C) produces the stack, wherein (i) the third circuit component of the first substrate and the third hole of the second substrate are aligned with each other, and (ii) the fourth circuit component of the first substrate and the fourth hole of the second substrate are aligned with each other; and
the filling D) produces the plurality of deformable interconnects in the stack, wherein (i) the plurality of deformable interconnects further comprises a second deformable interconnect produced by filling, through the second port of the second substrate, the third hole, the fourth hole and the second channel of the second substrate with the liquid metal material, and (ii) the second deformable interconnect electrically connects the third and fourth circuit components.

9. The method of claim 8, wherein:
the third hole, the fourth hole, or the second channel is filled substantially completely by the liquid metal material,
the second deformable interconnect is stretchable with a stretchability of at least 25%, at least 50%, at least 75%, or at least 100%,
the second deformable interconnect is formed substantially concurrently as the first deformable interconnect and has a dimension substantially the same as the first deformable interconnect.

10. The method of claim 1, wherein the obtaining A) comprises:
A.1) obtaining a first initial substrate comprising a first layer with the plurality of circuit components disposed on a first side of the first layer;
A.2) dehydrating, optionally, the first layer;
A.3) cleaning, optionally, the first initial substrate;
A.4) salinizing, optionally, the first layer to improve a surface functionality of a second side of the first layer, wherein the second side is opposite to the first side of the first layer;
A.5) laminating, optionally, the first initial substrate on a second layer with the second side of the first layer facing the second layer;
A.6) applying, optionally, a coating material to at least a portion of the first initial substrate at a first thickness to encapsulate at least the portion of the first initial substrate; and
A.7) curing, optionally, the coating material.

11. The method of claim 10, wherein the first layer comprises a polyimide (Pi) film, wherein the dehydrating A.2) is performed at a first temperature for a first period of time, wherein the first temperature is from about 110° C. to about 130° C., and the first period of time is from about 10 minutes to about 30 minutes.

12. The method of claim 10, wherein the cleaning A.3) comprises exposing the first initial substrate to a first plasma at a first wattage for a second period of time, wherein the first wattage is from about 200 watt (W) to about 300 W, the second period of time is from about 10 minutes to about 30 minutes, and wherein the first plasma comprises oxygen (O₂) plasma flown at about 12 standard cubic centimeters per minute (SCCM), tetrafluoromethane (CF₄) flown at about 3 SCCM, or a combination thereof.

13. The method of claim 11, wherein the salinizing A.4) comprises exposing at least the second side of the first layer to a first solution for a third period of time, wherein the first solution comprises 1% (3-mercaptopropyl) trimethoxysilane (MPTMS); and the third period of time is from about 40 minutes to about 60 minutes.

14. A deformable electronic device, comprising:
a first substrate comprising:
a first surface; and
a plurality of circuit components disposed at the first surface, wherein the plurality of circuit components comprises a first circuit component and a second circuit component separated from the first circuit component; and
a second substrate bonded with the first substrate and comprising a plurality of deformable interconnects made of a liquid metal material, wherein the plurality of deformable interconnects comprises a first deformable interconnect that electrically connects the first and second circuit components.

15. The deformable electronic device of claim 14, wherein the first deformable interconnect is stretchable.

16. The deformable electronic device of claim 14, wherein the first deformable interconnect is free of degradation in conductivity when the first and second substrates are bent around a cylinder that has a radius of between 2 cm and 10 cm for a period of time between 10 seconds and 5 minutes and then released.

17. The deformable electronic device of claim 14, wherein:
the second substrate comprises a second surface adjacent to the first surface of the first substrate, and a third surface away from the first surface of the first substrate; and
the first deformable interconnect comprises:
a first trace disposed between the second and third surfaces;
a first via electrically connecting the first circuit component with a first end portion of the first trace; and
a second via electrically connecting the second circuit component with a second end portion of the first trace.

18. The deformable electronic device of claim 14, wherein:
the plurality of circuit components further comprises a third circuit component and a fourth circuit component separated from the third circuit component; and
the plurality of deformable interconnects further comprises a second deformable interconnect that electrically connects the third and fourth circuit components.

19. The deformable electronic device of claim 14, wherein the liquid metal material comprises a gallium-based low-melting-point alloy.

20. The deformable electronic device of claim 14, further comprising one or more connectors, each electrically connected to a circuit component in the plurality of circuit components, a deformable interconnect in the plurality of deformable interconnects, or both.
